(19) United States
(12) Patent Application Publication
(10) Pub. No.: US 2026/0059938 A1
(43) Pub. Date: Feb. 26, 2026

(54) ORGANIC EL ELEMENT, DISPLAY DEVICE, AND ILLUMINATION DEVICE

(71) Applicant: Toray Industries, Inc., Chuo-ku, Tokyo (JP)

(72) Inventors: Takashi TOKUDA, Otsu-shi, Shiga (JP); Kazumasa NAGAO, Otsu-shi, Shiga (JP); Ryota KOTANI, Otsu-shi, Shiga (JP); Kazuki KOBAYASHI, Otsu-shi, Shiga (JP)

(73) Assignee: Toray Industries, Inc., Chuo-ku, Tokyo (JP)

(21) Appl. No.: 18/996,219

(22) PCT Filed: Aug. 1, 2023
(86) PCT No.: PCT/JP2023/028103

§ 371 Date: Jan. 17, 2025

(30) Foreign Application Priority Data
Aug. 22, 2022 (JP) 2022-131588

(51) Int. Cl. H10K 50/19; C09K 11/06; H10K 50/12; H10K 50/15; H10K 50/16; H10K 85/30; H10K 85/40; H10K 85/60; H10K 101/20

(52) U.S. Cl. CPC H10K 50/19; C09K 11/06; H10K 50/12; H10K 50/15; H10K 50/16; H10K 85/342; H10K 85/346; H10K 85/40; H10K 85/622; H10K 85/626; H10K 85/633; H10K 85/636; H10K 85/654; H10K 85/6572; H10K 85/6574; H10K 85/658; C09K 2211/1044; H10K 2101/20

(57) ABSTRACT

An organic EL element is provided which has excellent luminous efficiency and durability life and which comprises: a positive electrode; a negative electrode; two or more light emitting units which are held between the positive electrode and the negative electrode, where each comprises a hole transport layer, an electron transport layer and a light emitting layer; and a charge generation layer, where the charge generation layer is composed of an n-type charge generation layer and a p-type charge generation layer, where the n-type charge generation layer contains a compound represented by general formula (1) and the p-type charge generation layer contains either a compound represented by general formula (2) or a compound represented by general formula (4)

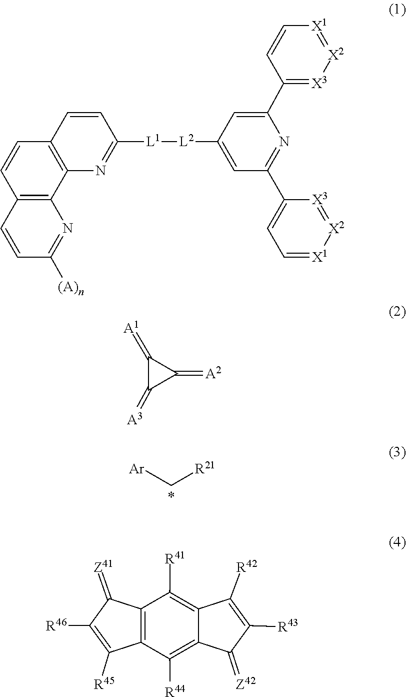

where X¹ to X³, L¹, L², A, n, A¹ to A³, *, Ar, R²¹, R⁴¹ to R⁴⁶, Z⁴¹ and Z⁴² are as defined.

### CROSS REFERENCE TO RELATED APPLICATIONS

This application is the U.S. National Phase of PCT/JP2023/028103, filed Aug. 1, 2023, which claims priority to Japanese Patent Application No. 2022-131588, filed Aug. 22, 2022, the disclosures of these applications being incorporated herein by reference in its entireties for all purposes.

### FIELD OF THE INVENTION

The present invention relates to an organic EL element, a display device, and an illumination device using a compound having a specific structure in a charge generation layer.

### BACKGROUND OF THE INVENTION

In recent years, organic EL elements (organic electroluminescent elements) have been steadily put into practical use, such as being employed in displays of televisions and smartphones. However, existing organic EL elements still have many technical problems. In particular, to attain both obtaining highly efficient light emission and prolonging the life of an organic EL element is a great problem.

To solve these problems, a tandem type organic EL element has been proposed in which a plurality of light-emitting units including an organic layer having a hole transporting layer, an electron transporting layer, and an emissive layer is disposed between an anode and a cathode in an overlapping manner with a charge generation layer interposed therebetween.

The charge generation layer is composed of an n-type charge generation layer and a p-type charge generation layer, and phenanthroline derivatives having a terpyridine skeleton and substituted with a specific aryl group (see, for example, Patent Document 1), phenanthroline derivatives having a pyrene skeleton (see, for example, Patent Document 2), phenanthroline derivatives having a dibenzofuran skeleton (see, for example, Patent Document 3), phenanthroline derivatives having a specific arylene group and a specific heteroaryl group (see, for example, Patent Documents 4 and 5), and the like have been developed as compounds to be used for the n-type charge generation layer.

As compounds to be used for the p-type charge generation layer, triarylamine derivatives (see, for example, Patent Document 1), HAT-CN (see, for example, Patent Documents 3 and 5), and NPD doped with F4-TCNQ (see, for example, Patent Document 4) are disclosed.

### PATENT DOCUMENTS

Patent Document 1: WO 2016/121597 A
Patent Document 2: KR 10-2020-0064423 A
Patent Document 3: WO 2020/218648 A
Patent Document 4: EP 2983227 A
Patent Document 5: KR 10-2019-0053562 A

### SUMMARY OF THE INVENTION

According to Patent Documents 1 to 5, by use of a phenanthroline derivative in which a terpyridine skeleton, a pyrene skeleton, a dibenzofuran skeleton, a specific aryl group, an arylene group, or a heteroaryl group is linked for an n-type charge generation layer, and use of NPD doped with a triarylamine derivative, HAT-CN, or F4-TCNQ for a p-type charge generation layer, an organic EL element that has enhanced luminous efficiency, can be driven at a low voltage, and is superior in durability can be obtained. However, in recent years, luminous efficiency and durability required for organic EL elements have been increasingly increased, and a technique for achieving both higher luminous efficiency and durable life has been required.

In view of the problems of the prior art, an object of the present invention is to provide an organic EL element superior in luminous efficiency and durable life.

In order to solve the above-described problems, the present invention has the following constitution.

[1] An organic EL element comprising: an anode; a cathode; two or more light-emitting units sandwiched between the anode and the cathode and each having a hole transporting layer, an electron transporting layer, and an emissive layer; and a charge generation layer sandwiched between the light-emitting units,
wherein the charge generation layer includes an n-type charge generation layer located on the anode side and a p-type charge generation layer located on the cathode side,
the n-type charge generation layer contains a compound represented by the following general formula (1) and any one of an alkali metal, an alkaline earth metal, and a rare earth metal, and
the p-type charge generation layer contains a compound represented by the following general formula (2) or the following general formula (4),

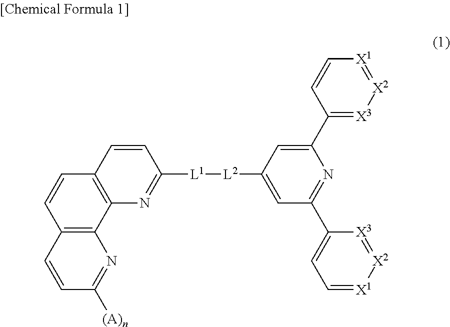

in the general formula (1), one among X¹ to X³ is a nitrogen atom, and the others are each a methine group; L¹ is a substituted or unsubstituted phenylene group, a substituted or unsubstituted naphthylene group, or a substituted or unsubstituted anthrylene group, and L² is a single bond, a substituted or unsubstituted phenylene group, a substituted or unsubstituted naphthylene group, or a substituted or unsubstituted anthrylene group, provided that when L¹ and L² are each substituted, each substituent is an alkyl group or an alkoxy group; A is a substituted or unsubstituted phenyl group or a substituted or unsubstituted pyridyl group, and n is 0 or 1, provided that when A is substituted, the substituent is an alkyl group, an alkoxy group, or a fluorine atom,

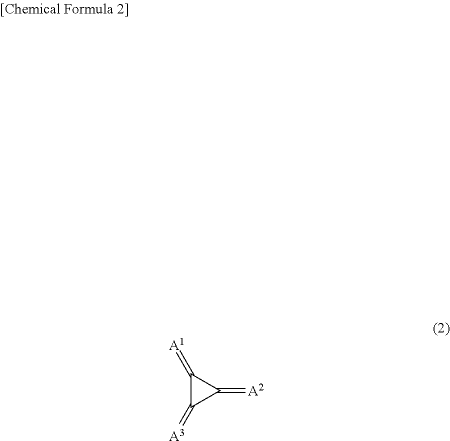

in the general formula (2), A¹ to A³ each independently represent a group represented by the following general formula (3),

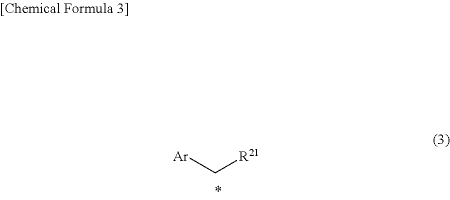

in the general formula (3), * represents a bonding position with A¹ to A³ of the general formula (2) and Z⁴¹ to Z⁴² of the following general formula (4); Ar represents a substituted or unsubstituted aryl group having 6 to 18 carbon atoms, or a substituted or unsubstituted heteroaryl group having 2 to 18 carbon atoms; provided that when these groups are substituted, each substituent is selected from the group consisting of a cyano group, a perfluoroalkyl group, a fluorine atom, and a chlorine atom; R²¹ represents a substituted or unsubstituted aryl group having 6 to 18 carbon atoms, a substituted or unsubstituted heteroaryl group having 2 to 18 carbon atoms, a perfluoroalkyl group having 1 to 8 carbon atoms, a fluorine atom or a cyano group,

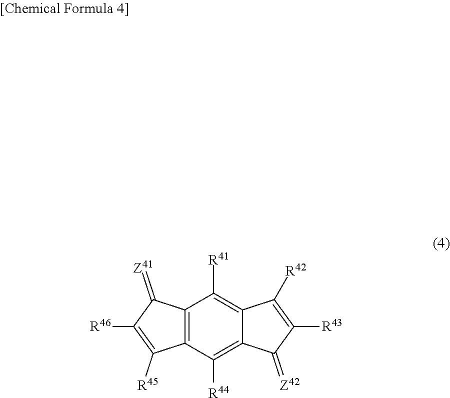

in general formula (4), R⁴¹ to R⁴⁶ are each independently selected from the group consisting of a hydrogen atom, a substituted or unsubstituted aryl group having 6 to 12 carbon atoms, a substituted or unsubstituted heteroaryl group having 1 to 12 carbon atoms, an alkoxy group having 1 to 12 carbon atoms, an ether group having 1 to 12 carbon atoms, a cyano group, a fluorine atom, a trifluoromethyl group, a trifluoromethoxy group, and a trimethylsilyl group, provided that at least one of R⁴¹ to R⁴⁶ has a cyano group; adjacent substituents among R⁴¹ to R⁴⁶ may be fused and form a ring; and Z⁴¹ and Z⁴² are each independently a group represented by the general formula (3).

[2] The organic EL element according to [1], wherein X³ is a nitrogen atom in the general formula (1).

[3] The organic EL element according to [1] or [2], wherein n is 1, and A is a phenyl group in the general formula (1).

[4] The organic EL element according to any one of [1] to [3], wherein n is 1, and L2 is a single bond in the general formula (1).

[5] The organic EL element according to any one of [1] to [4], wherein n is 0 in the general formula (1).

[6] The organic EL element according to any one of [1] to [5], wherein L¹ is a phenylene group, and L² is a single bond in the general formula (1).

[7] The organic EL element according to any one of [1] to [6], wherein the rare earth metal is ytterbium.

[8] The organic EL element according to any one of [1] to [7], wherein the electron transporting layer contains a triazine derivative or a pyrimidine derivative.

[9] The organic EL element according to [8], wherein the electron transporting layer contains a triazine derivative or a pyrimidine derivative represented by the following general formula (5),

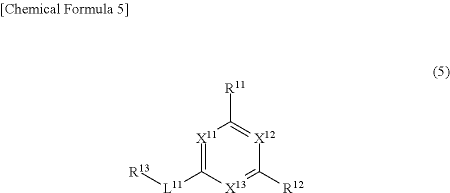

in the general formula (5), at least two of X¹¹ to X¹³ are nitrogen atoms, and each of X¹¹ to X¹³ is a methine group when not being a nitrogen atom; R¹¹ and R¹² are each a substituted or unsubstituted phenyl group, a substituted or unsubstituted biphenyl group, or a substituted or unsubstituted fluorenyl group; L¹¹ is a single bond or an arylene group; and R¹³ is a substituted or unsubstituted heteroaryl group or an aryl group substituted with a cyano group.

[10] The organic EL element according to any one of [1] to [9], comprising a hole inhibition layer between the electron transporting layer and the emissive layer, wherein the hole inhibition layer contains a triazine derivative or a pyrimidine derivative.

[11] The organic EL element according to any one of [1] to [10], wherein the emissive layer contains a thermally activated delayed fluorescence material and a fluorescent dopant.

[12] The organic EL element according to [11], wherein the fluorescent dopant is a compound represented by the following general formula (6),

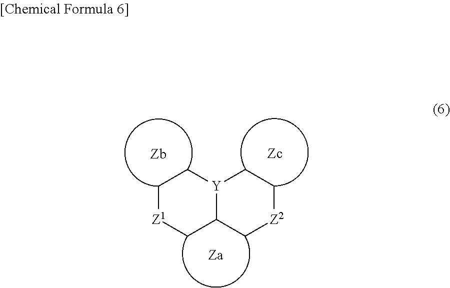

in the general formula (6), ring Za, ring Zb and ring Zc are each independently a substituted or unsubstituted aryl ring having 6 to 30 ring-forming carbon atoms, or a substituted or unsubstituted heteroaryl ring having 5 to 30 ring-forming atoms; Z¹ and Z² are each independently an oxygen atom, NRa (a nitrogen atom having a substituent Ra), or a sulfur atom, provided that when Z¹ is NRa, Z¹ may or may not be bonded to ring Za or ring Zb and form a ring, and when Z² is NRa, Z² may or may not be bonded to ring Zb or ring Zc and form a ring; Ra is independently at each occurrence a substituted or unsubstituted aryl group having 6 to 30 ring-forming carbon atoms, a substituted or unsubstituted heteroaryl group having 5 to 30 ring-forming atoms, or a substituted or unsubstituted alkyl group having 1 to 30 carbon atoms; Y is a boron atom, a phosphorus atom, SiRb (a silicon atom having substituent Rb), P═O, or P═S; Rb is independently at each occurrence selected from among a substituted or unsubstituted aryl group having 6 to 30 ring-forming carbon atoms, a substituted or unsubstituted heteroaryl group having 5 to 30 ring-forming atoms, and a substituted or unsubstituted alkyl group having 1 to 30 carbon atoms.

[13] The organic EL element according to any one of [1] to [12], wherein the emissive layer contains a phosphorescent dopant composed of an iridium complex or a platinum complex.

[14] The organic EL element according to any one of [1] to [13], wherein the hole transporting layer contains a triarylamine derivative having a fluorene skeleton or a carbazole skeleton as a partial structure.

[15]A display device comprising the EL element according to any one of [1] to [14].

[16] An illumination device comprising the EL element according to any one of [1] to [14].

According to the present invention, an organic EL element superior in luminous efficiency and durable life can be provided.

### DETAILED DESCRIPTION OF EMBODIMENTS OF THE INVENTION

Hereinafter, preferred embodiments of an organic EL element, a display device, and an illumination device according to the present invention will be described in detail. However, the present invention is not limited to the following embodiments, and various modifications can be made according to the purpose and the use.

### (Organic EL Element)

The organic EL element according to an embodiment of the present invention comprises: an anode; a cathode; two or more light-emitting units sandwiched between the anode and the cathode and each having a hole transporting layer, an electron transporting layer, and an emissive layer; and a charge generation layer sandwiched between the light-emitting units, and emits light by electrical energy.

Examples of the layer configuration of the light-emitting unit in such an organic EL element include 1) a hole transporting layer/an emissive layer/an electron transporting layer, 2) a hole injection layer/a hole transporting layer/an emissive layer/an electron transporting layer, 3) a hole transporting layer/an emissive layer/an electron transporting layer/an electron injection layer, 4) a hole injection layer/a hole transporting layer/an emissive layer/an electron transporting layer/an electron injection layer, and 5) a hole injection layer/a hole transporting layer/an emissive layer/a hole inhibition layer/an electron transporting layer/an electron injection layer.

Each of the layers described above may be a single layer or may include a plurality of layers, and may be doped. In particular, the electron injection layer and the charge generation layer are preferably metal-doped layers doped with metal, and can improve electron transporting ability and electron injection ability to another layer adjacent thereto. In addition to the layers described above, a protective layer (cap layer) may be further included, and the luminous efficiency can be further improved by an optical interference effect.

In the organic EL element according to an embodiment of the present invention, the anode and the cathode have a role of supplying a sufficient current for light emission of the element, and at least one of the anode and the cathode is desirably transparent or translucent for light extraction. Usually, the anode formed on a substrate is made to be a transparent electrode.

### (Substrate)

The organic EL element is preferably formed on a substrate to maintain the mechanical strength of the organic EL element. Examples of the substrate include a glass substrate such as a soda glass substrate or an alkali-free glass substrate, and a plastic substrate. The thickness of the glass substrate is just required to be a thickness sufficient for maintaining mechanical strength and a thickness of 0.5 mm or more is large enough. Regarding the material of glass, it is preferred that the amount of ions eluted from the glass is small, and alkali-free glass is preferable. Soda lime glass barrier-coated with SiO₂ or the like is commercially available, and can also be used.

### (Anode)

It is preferable that the material to be used for the anode can efficiently inject holes into the organic layer. It is preferable for extraction of light that the material to be used for the anode is transparent or translucent. Examples of the material to be used for the anode include electroconductive metal oxides such as zinc oxide, tin oxide, indium oxide, indium tin oxide (ITO), and indium zinc oxide (IZO), metals such as gold, silver, and chromium, inorganic electroconductive substances such as copper iodide and copper sulfide, or electroconductive polymers such as polythiophene, polypyrrole, and polyaniline. Among them, ITO glass and NESA glass are preferable. These electrode materials may be used singly, or two or more of them may be laminated on or mixed with each other upon use.

### (Cathode)

The material to be used for the cathode is not particularly limited as long as the material can efficiently inject electrons into the emissive layer. Examples of the material to be used for the cathode include metals such as platinum, gold, silver, copper, iron, tin, aluminum, and indium, or alloys of these metals with metals having a low work function such as lithium, sodium, potassium, calcium and magnesium, conductive metal oxides such as indium zinc oxide (IZO), and multilayer laminates thereof. Among them, from the viewpoint of electric resistance value, ease of film formation, stability of film, luminous efficiency, etc., aluminum, silver, and magnesium are preferable as a main component, and it is more preferable that the material to be used for the cathode is composed of magnesium and silver because injection of electrons into the electron transporting layer and the electron injection layer is easy.

### (Protective Layer)

To protect the cathode, the cathode is preferably laminated with a protective layer (cap layer). The material (capping material) to form the protective layer is not particularly limited, and examples of the material include metals such as platinum, gold, silver, copper, iron, tin, aluminum, and indium, alloys in which such a metal is used, inorganic substances such as silica, titania, and silicon nitride, organic polymer compounds such as polyvinyl alcohol, polyvinyl chloride, and hydrocarbon-based polymer compounds, and low-molecular compounds such as triarylamine derivatives. It is noted that when the organic EL element has an element structure in which light is extracted from the cathode side (top emission structure), the capping material preferably has a light transmitting property in a visible light region. The triarylamine derivatives are preferable because the triarylamine derivatives have a light transmitting property in the visible light region and have a high refractive index, so that the light extraction efficiency of the element can be enhanced.

### (Charge Generation Layer)

The charge generation layer in the present invention is generally formed of a double layer, and is used specifically in the form of a p-n junction charge generation layer composed of an n-type charge generation layer located on the anode side and a p-type charge generation layer located on the cathode side. The p-n junction charge generation layer generates a charge or separates a charge into a hole and an electron when a voltage is applied in the organic EL element, and the hole and the electron are injected into the emissive layer via the hole transporting layer and the electron transporting layer. Specifically, in the organic EL element in which the emissive layers are laminated, the p-n junction charge generation layer functions as a charge generation layer that is an intermediate layer. The n-type charge generation layer supplies electrons to the light-emitting unit present on the anode side, and the p-type charge generation layer supplies holes to the light-emitting unit present on the cathode side. Therefore, in the organic EL element in which a plurality of emissive layers are laminated, the luminous efficiency can be further improved, the driving voltage can be reduced, and the durable life of the element can also be improved.

The n-type charge generation layer contains an n-type dopant and an n-type charge generation layer host. The n-type charge generation layer host is preferably a compound represented by the general formula (1). In addition, a phenanthroline multimer can also be preferably used as an n-type charge generation layer host, and therefore, the compound represented by the general formula (1) and the phenanthroline multimer may be co-deposited and used.

As the n-type dopant, one or more selected from the group consisting of alkali metals, alkaline earth metals, Group 11 elements, and rare earth metals can be used. An alkali metal, an alkaline earth metal, or a rare earth metal is preferable as the n-type dopant material. Preferred examples of the n-type dopant material are lithium, silver or ytterbium (Yb), and ytterbium is particularly preferred.

That is, the n-type charge generation layer of the present invention contains a phenanthroline derivative represented by the following general formula (1) and any one of an alkali metal, an alkaline earth metal, and a rare earth metal.

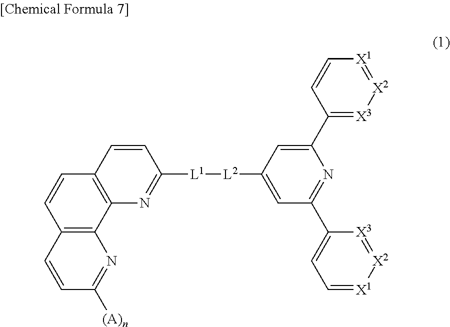

(In the general formula (1), one among X¹ to X³ is a nitrogen atom, and the others are each a methine group; L¹ is a substituted or unsubstituted phenylene group, a substituted or unsubstituted naphthylene group, or a substituted or unsubstituted anthrylene group, and L² is a single bond, a substituted or unsubstituted phenylene group, a substituted or unsubstituted naphthylene group, or a substituted or unsubstituted anthrylene group, provided that when L¹ and L² are each substituted, each substituent is an alkyl group or an alkoxy group; A is a substituted or unsubstituted phenyl group or a substituted or unsubstituted pyridyl group, and n is 0 or 1, provided that when A is substituted, the substituent is an alkyl group, an alkoxy group, or a fluorine atom.)

“Unsubstituted” in the case of “substituted or unsubstituted” means that hydrogen atoms are bonded, and “substituted” means that at least a part of hydrogen atoms is replaced. The hydrogen atom may be a deuterium atom. The above holds true for cases described as “substituted or unsubstituted” in the compounds or partial structures thereof described below.

The alkyl group denotes a saturated aliphatic hydrocarbon group, such as a methyl group, an ethyl group, a n-propyl group, an isopropyl group, a n-butyl group, a sec-butyl group, or a tert-butyl group, and the alkyl group may or may not have a substituent. The number of carbon atoms in the alkyl group is not particularly limited, and is usually in the range of 1 or more and 20 or less, and more preferably 1 or more and 8 or less from the viewpoints of easy availability and cost.

The alkoxy group denotes an alkyl group which is bonded to oxygen, such as a methoxy group, an ethoxy group, an n-propoxy group, an isopropoxy group, an n-butoxy group, a sec-butoxy group, or a tert-butoxy group, and the alkoxy group may or may not have a substituent. The number of carbon atoms in the alkoxy group is not particularly limited, and is usually in the range of 1 or more and 20 or less, and more preferably 1 or more and 8 or less from the viewpoints of easy availability and cost.

As compounds to be used for a conventional n-type charge generation layer, for example, Patent Documents 1 to 5 disclose Compounds V, W, X, Y, and Z represented by the following formulas.

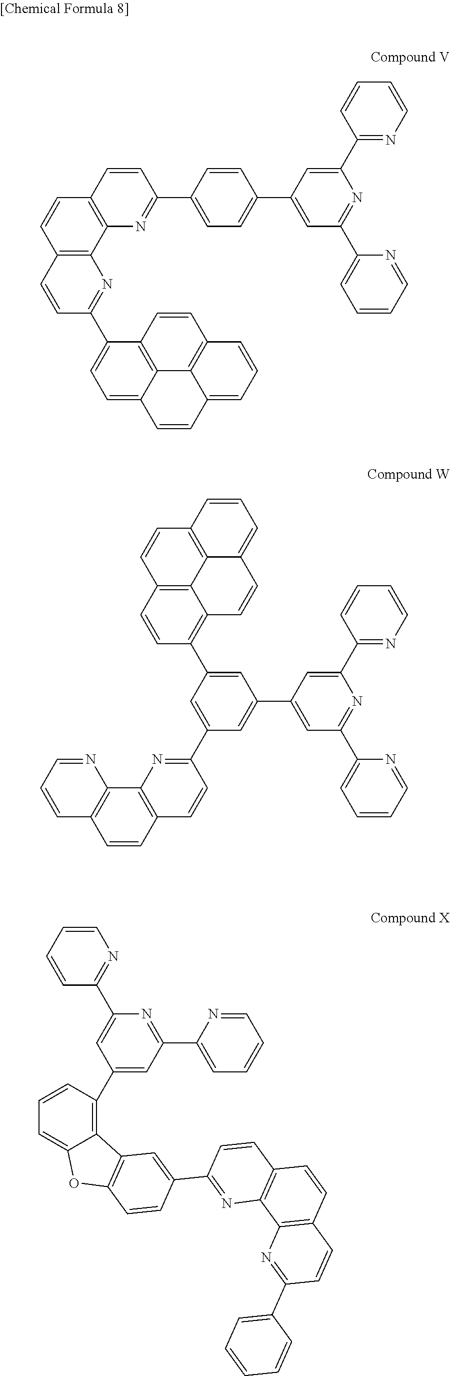 [SMILES: c1ccc(-c2cc(-c3ccc(-c4ccc5ccc6ccc(-c7ccc8ccc9cccc%10ccc7c8c9%10)nc6c5n4)cc3)cc(-c3ccccn3)n2)nc1 ; c1ccc(-c2cc(-c3cc(-c4ccc5ccc6cccnc6c5n4)cc(-c4ccc5ccc6cccc7ccc4c5c67)c3)cc(-c3ccccn3)n2)nc1 ; c1ccc(-c2ccc3ccc4ccc(-c5ccc6oc7cccc(-c8cc(-c9ccccn9)nc(-c9ccccn9)c8)c7c6c5)nc4c3n2)cc1]

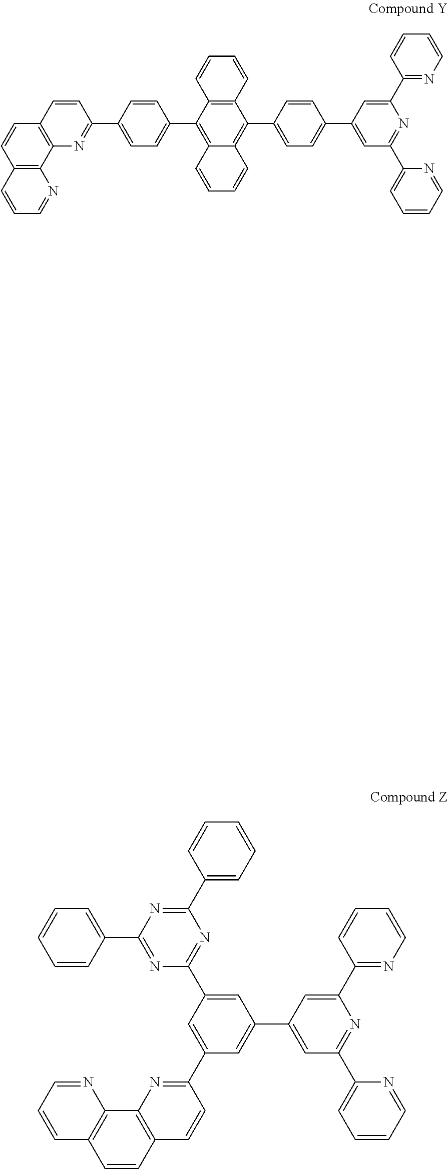 [SMILES: c1ccc(-c2cc(-c3ccc(-c4c5ccccc5c(-c5ccc(-c6ccc7ccc8cccnc8c7n6)cc5)c5ccccc45)cc3)cc(-c3ccccn3)n2)nc1 ; c1ccc(-c2nc(-c3ccccc3)nc(-c3cc(-c4cc(-c5ccccn5)nc(-c5ccccn5)c4)cc(-c4ccc5ccc6cccnc6c5n4)c3)n2)cc1]

However, even in elements using these compounds for a charge generation layer, sufficient performance has not yet been obtained with respect to characteristics required in recent years, and creation of a compound capable of further improving performance in terms of luminous efficiency and durable life is required.

For example, a compound in which a phenanthrolinyl group is substituted with a pyrenyl group like Compound V has a bulky substituent in the vicinity of a nitrogen atom on a phenanthrolinyl group, which has a high coordination property, and therefore, such a compound tends to readily reduce the coordination property of the phenanthrolinyl group to a metal atom. Therefore, there is a problem that the film stability in the case where Compound V is used simultaneously with a metal atom deteriorates, the driving voltage increases, and the luminous efficiency and the durable life decrease.

A compound having a bulky aromatic substituent on a linking group between a terpyridyl group and a phenanthrolinyl group like Compounds W, X, and Z has a reduced effect of improving molecular interaction due to its bulkiness, and therefore leads to a high driving voltage, and still has problems regarding luminous efficiency and durable life.

Similarly, a compound in which a terpyridyl group and a phenanthrolinyl group are linked by three arylene groups like Compound Y has excessively high crystallinity due to its high flatness, and therefore leads to a high driving voltage, and has problems regarding luminous efficiency and durable life.

In the study of improvement thereof, the present inventors have focused on the effect of a phenanthrolinyl group, a terpyridyl group and their linking groups. Both the phenanthrolinyl group and the terpyridyl group are substituents having a large electron transporting property and high coordination property to a metal atom. In the compound represented by the general formula (1), when a phenylene group, a naphthylene group, or an anthrylene group is selected as L¹, and a single bond, a phenylene group, a naphthylene group, or an anthrylene group is selected as L², the phenanthrolinyl group, the terpyridyl group, and the linking groups thereof can be easily conjugated, and the charge transporting property as a compound can be further increased. Therefore, the compound with such configurations can reduce the driving voltage when used for the charge generation layer and can improve the luminous efficiency. In addition, since the coordination property to a metal atom can be enhanced, when the compound represented by the general formula (1) and any one of an alkali metal, an alkaline earth metal, and a rare earth metal are used for an n-type charge generation layer, a stable layer can be formed, and superior performance is exhibited.

When L¹ and L² are each substituted, each substituent is an alkyl group or an alkoxy group. These substituents are preferable because they can improve the stability of the compound without deteriorating the charge transporting property of the compound.

From the viewpoint of enhancing the film quality stability and further improving the luminous efficiency and the durable life, L¹ is preferably a phenylene group. In addition, L² is preferably a single bond. In the general formula (1), it is preferable that L¹ is a phenylene group, and L² is a single bond. In this case, the interaction between the phenanthrolinyl group and the terpyridyl group can be further increased, and the luminous efficiency and the durable life can be further improved.

In the general formula (1), one among X¹ to X³ is a nitrogen atom, and the others are methine groups. X³ is preferably a nitrogen atom from the viewpoint of enhancing the coordination property to a metal atom and forming a more stable layer. Forming a more stably coordinated layer makes driving at a low voltage possible and can further improve the durable life.

In the general formula (1), it is preferable that n is 1, and A is a substituted or unsubstituted phenyl group or a substituted or unsubstituted pyridyl group. In this case, the highly reactive 2- and 9-positions among the substitution positions of phenanthroline can be substituted, so that the stability of the compound can be improved. Furthermore, when a phenyl group or a pyridyl group is selected as A, due to a high coordination property of the nitrogen atoms on the phenanthrolinyl group, the compound exhibits a higher metal coordination property when being used for a metal-doped layer, and a more stable layer can be formed. Therefore, the driving voltage can be further reduced, and the durable life can be improved. In the general formula (1), it is preferable that n is 1, and A is a phenyl group from the viewpoint of further enhancing the stability and the durable life of the element. In addition, in the general formula (1), it is preferable that n is 1, and L² is a single bond.

As another aspect, in the general formula (1), n is preferably 0. In this case, the 9-position of phenanthroline is hydrogen. When n is 0, phenanthroline is three-dimensionally thin, so that the compound exhibits a higher metal coordination property when being used for a metal-doped layer, and a more stable layer can be formed.

The molecular weight of the compound represented by the general formula (1) is preferably 400 or more from the viewpoint of suppressing crystallization and improving the stability of film quality. On the other hand, from the viewpoint of improving processability during sublimation purification and vapor deposition, the molecular weight of the compound represented by the general formula (1) is preferably 640 or less.

Examples of the compound represented by the general formula (1) include the following compounds. The following are examples, and any compound other than the compounds specified herein is preferably used as long as it is represented by the general formula (1).

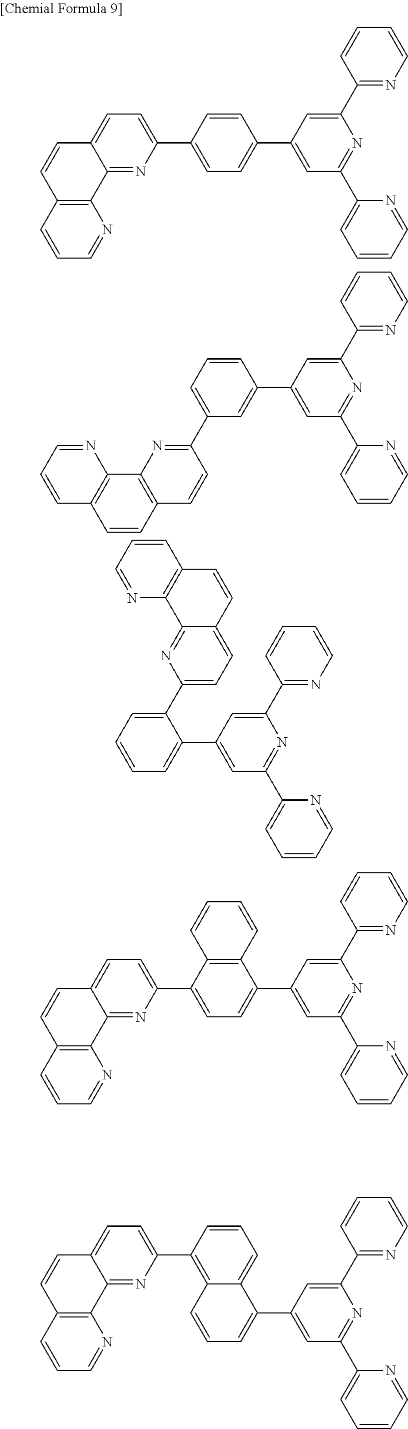

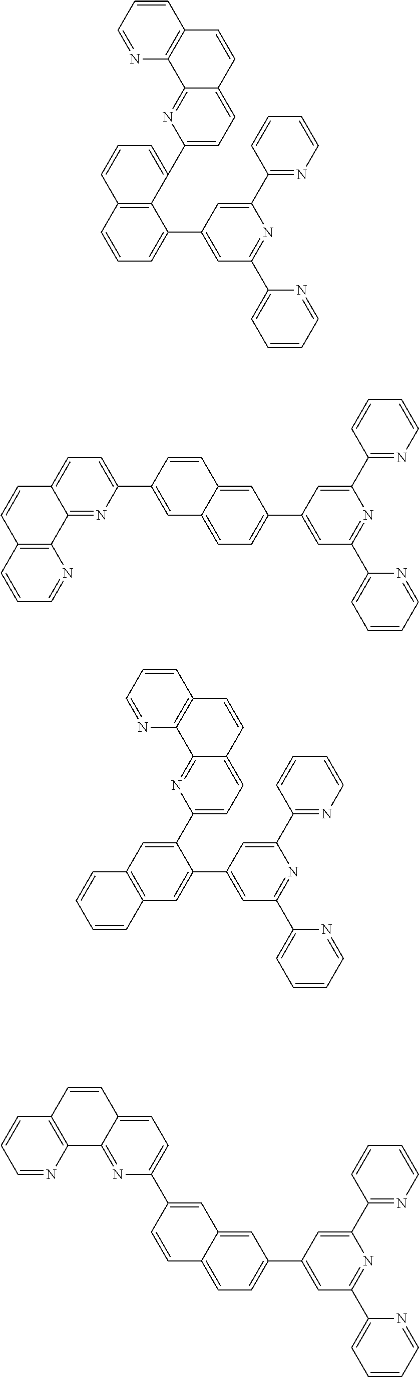

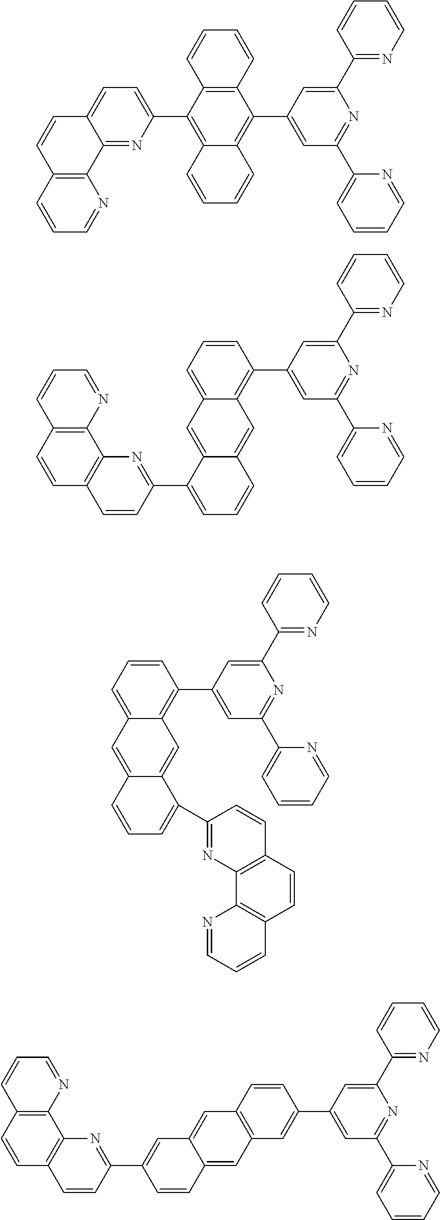

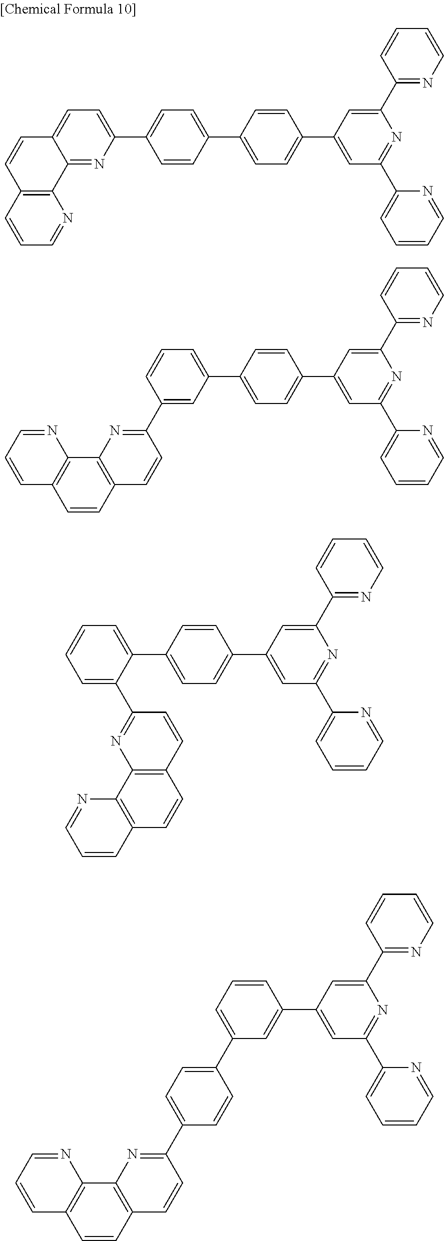

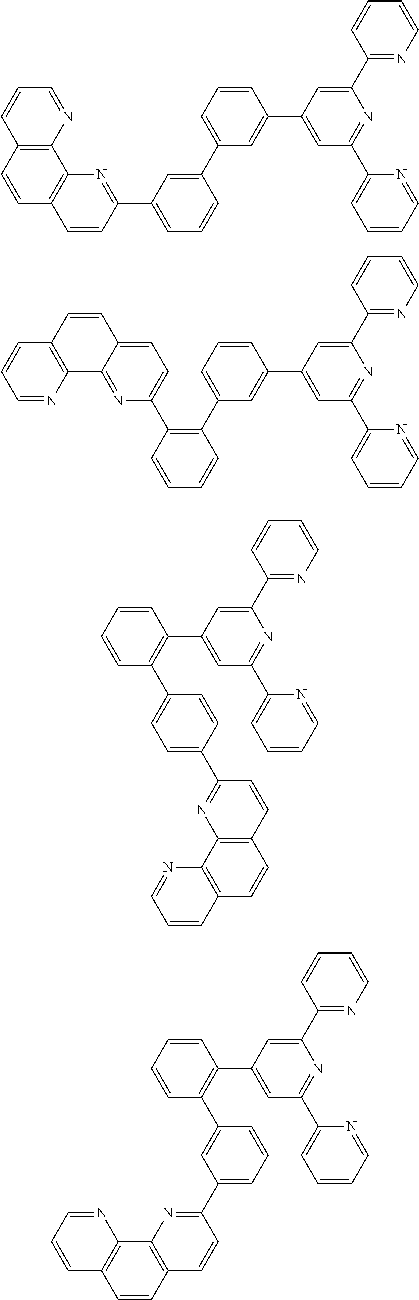

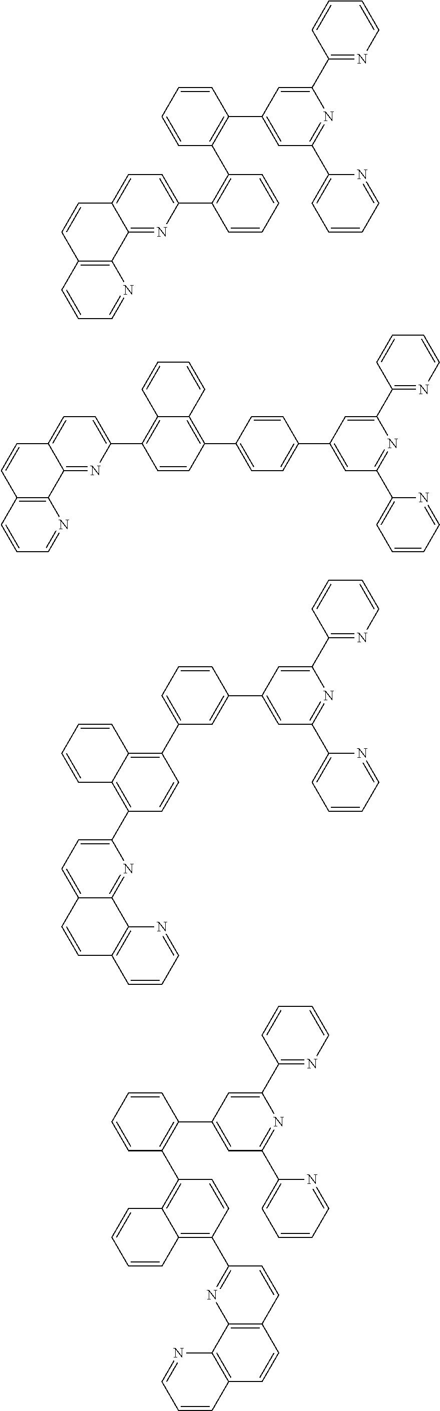

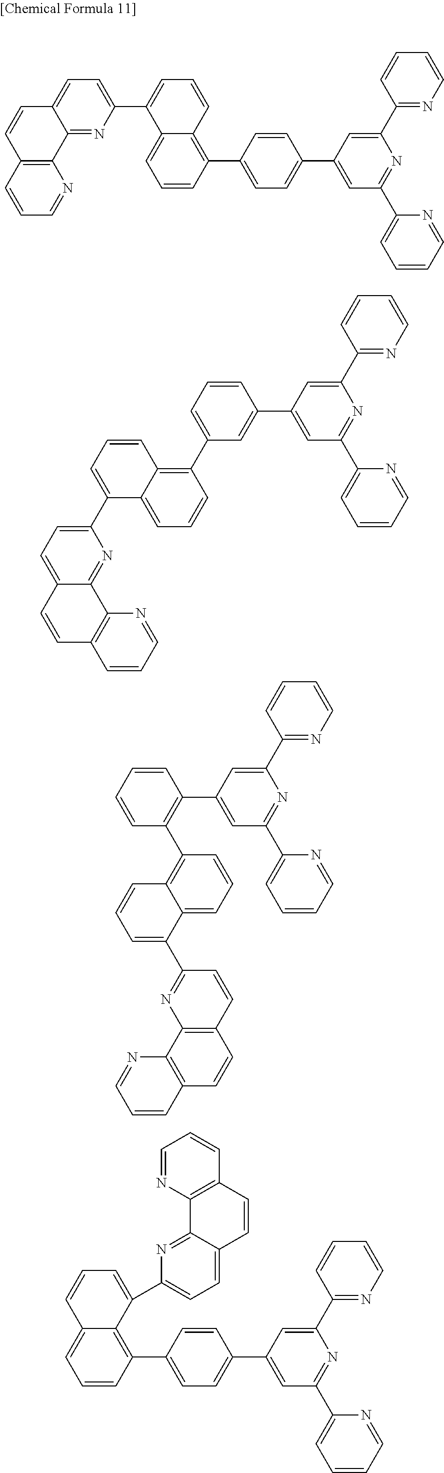

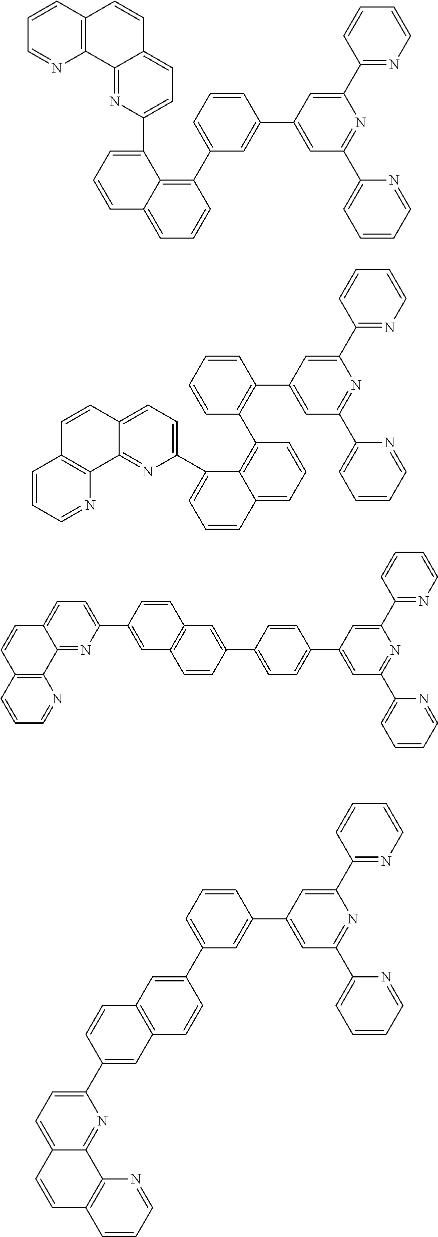

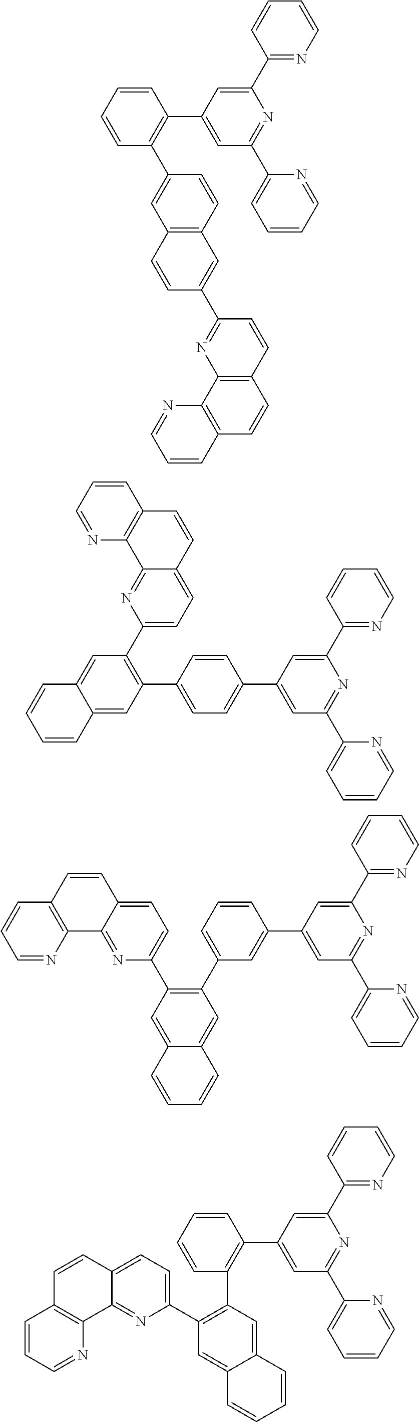

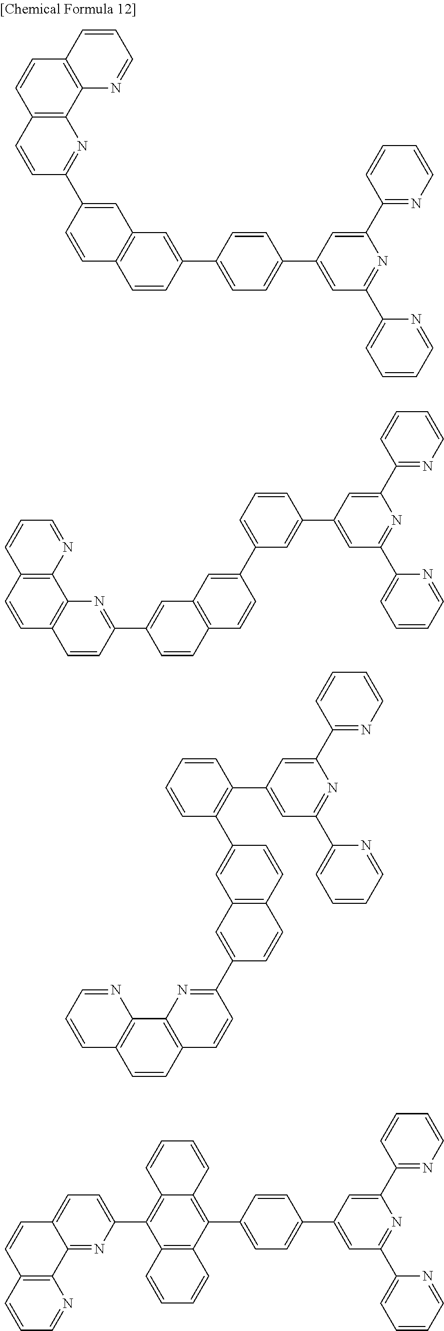

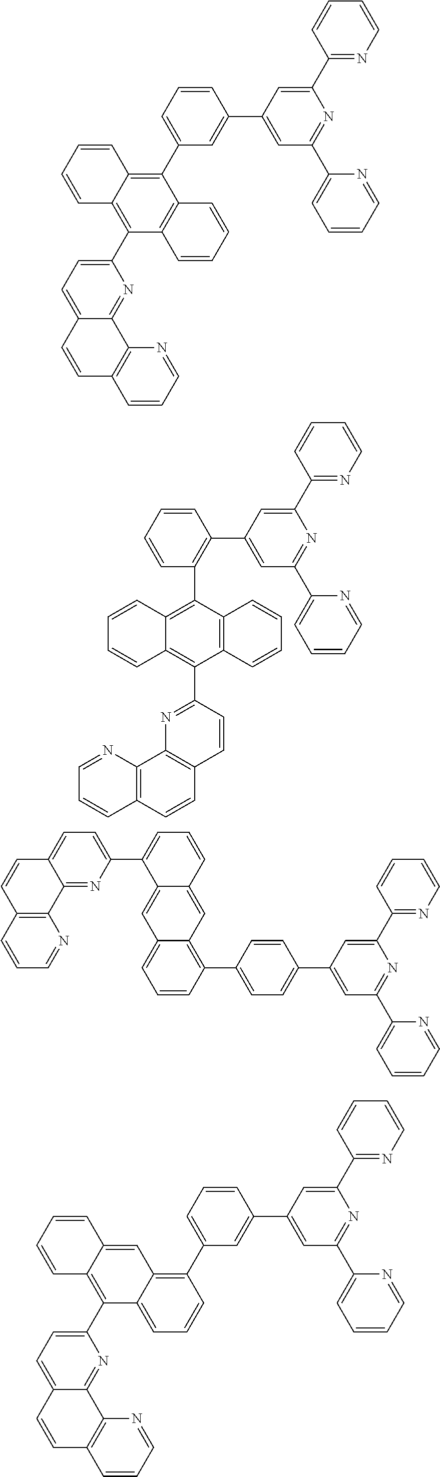

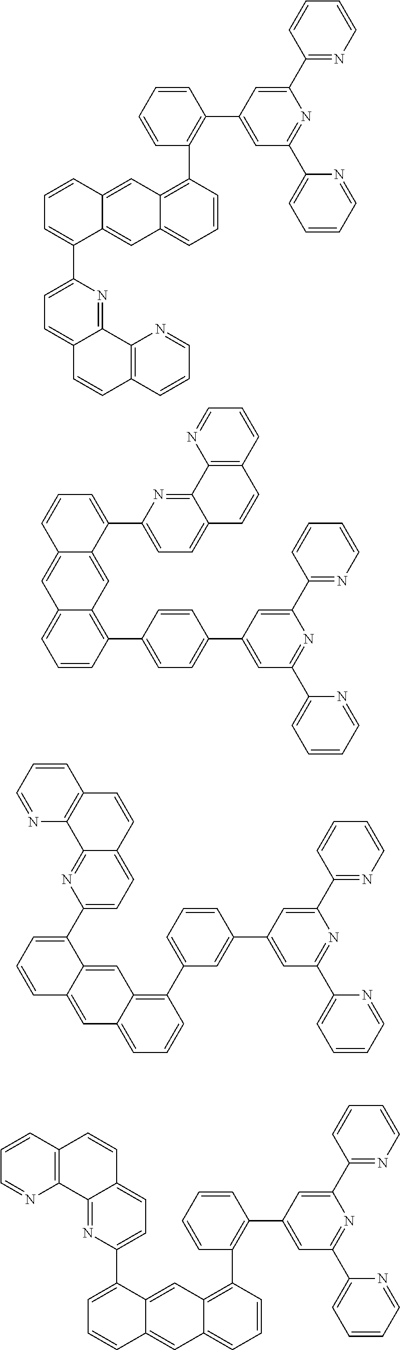

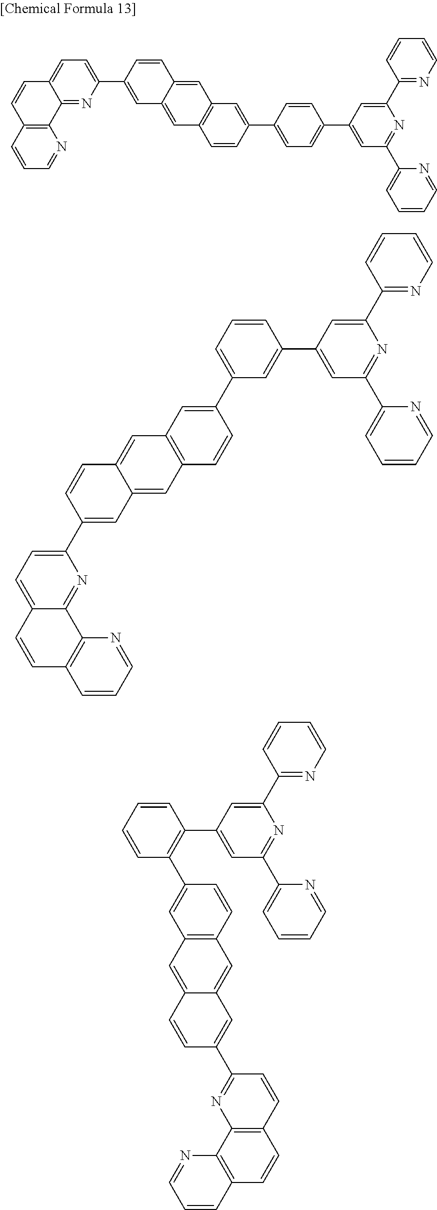

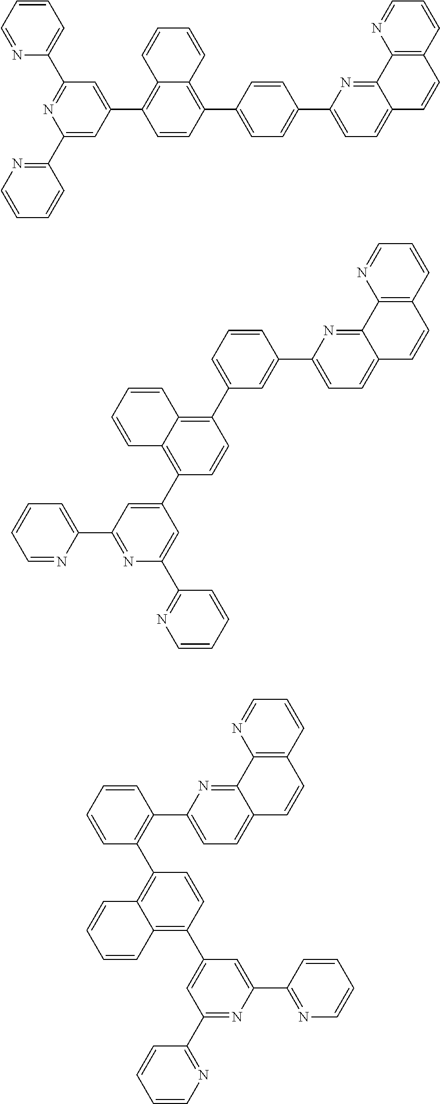

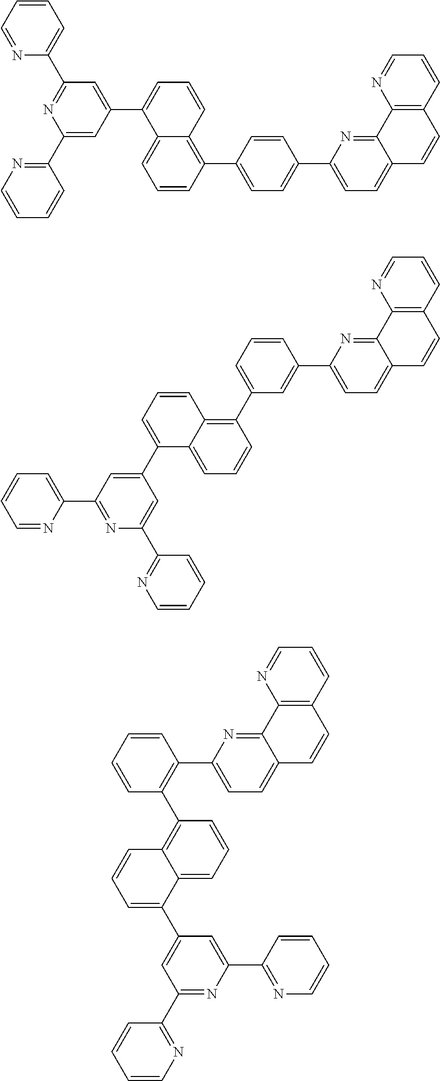

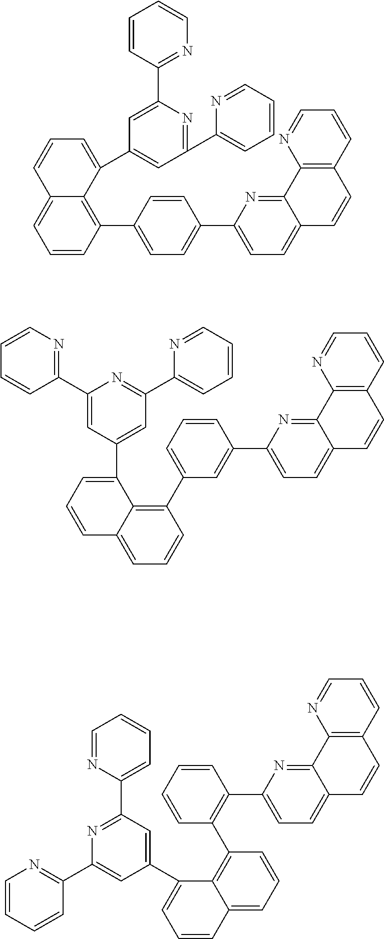

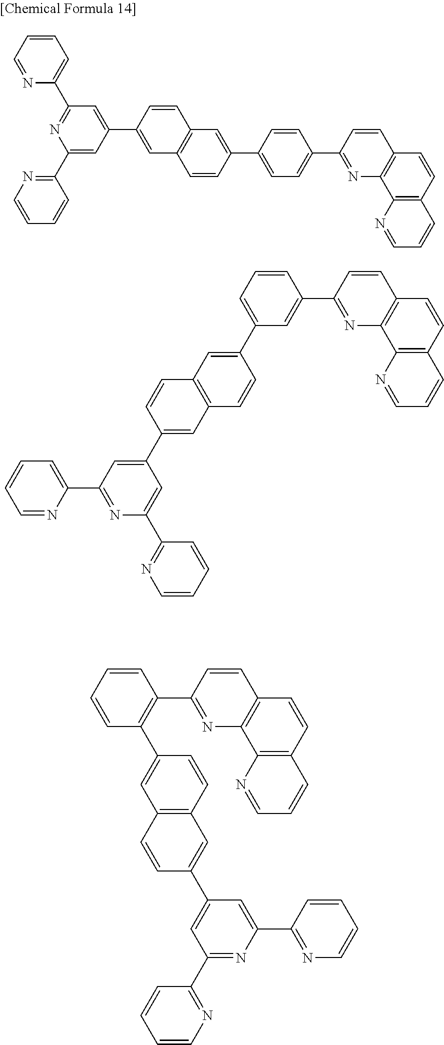

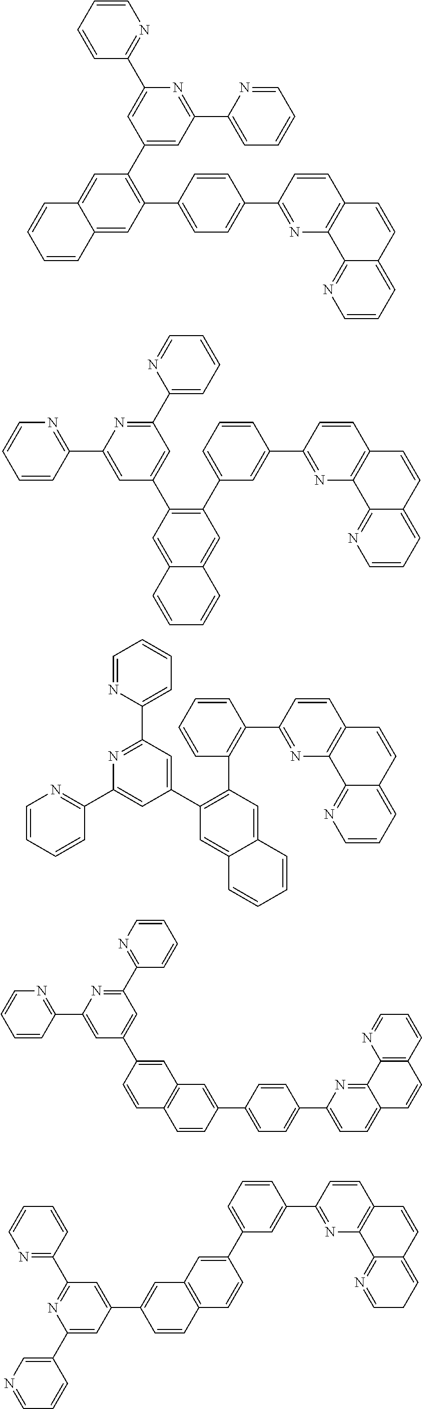

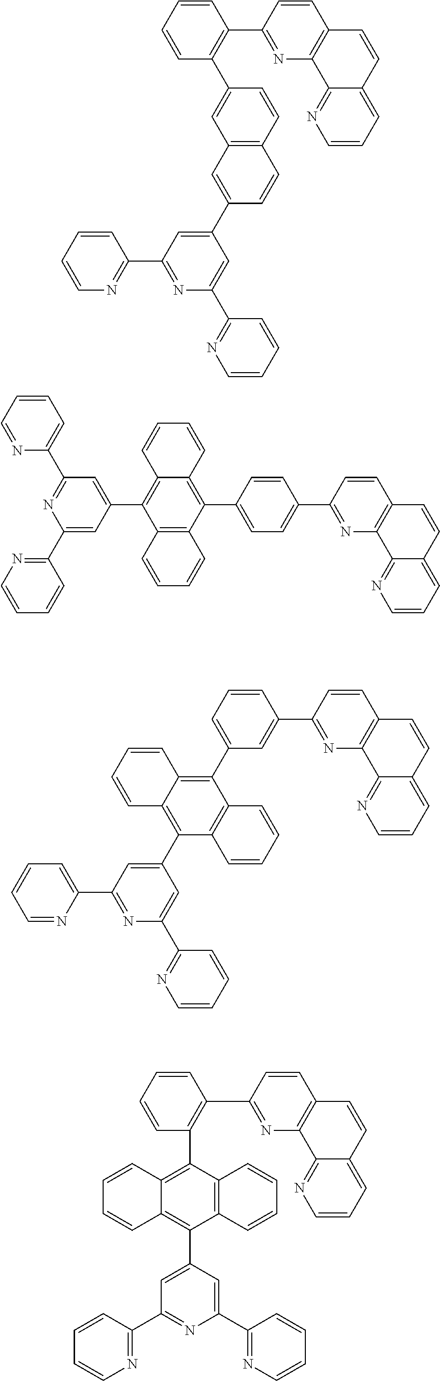

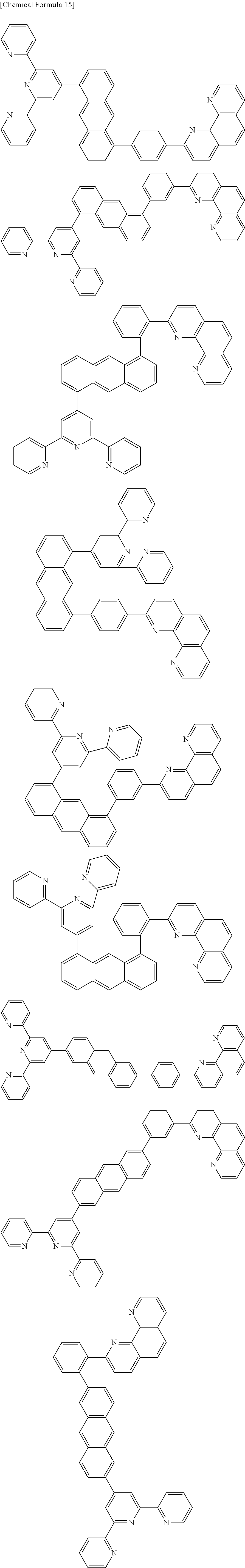

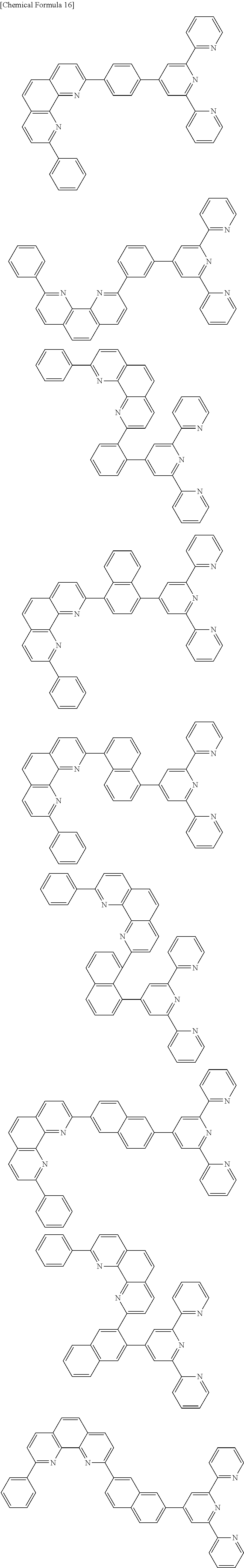

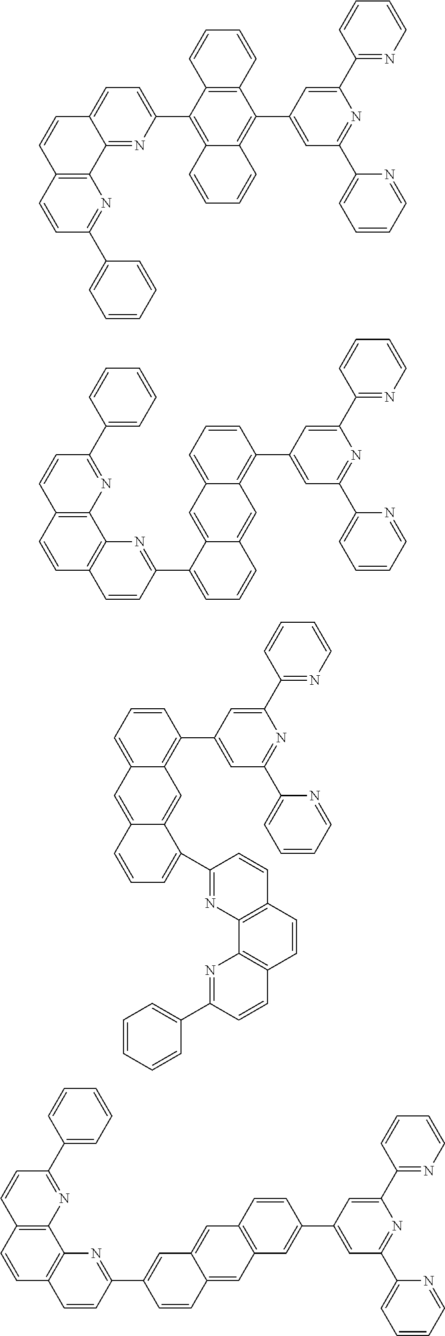

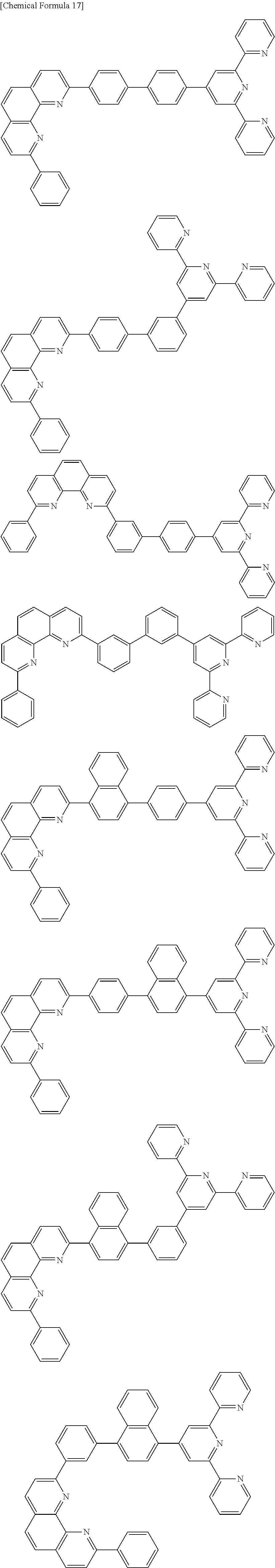

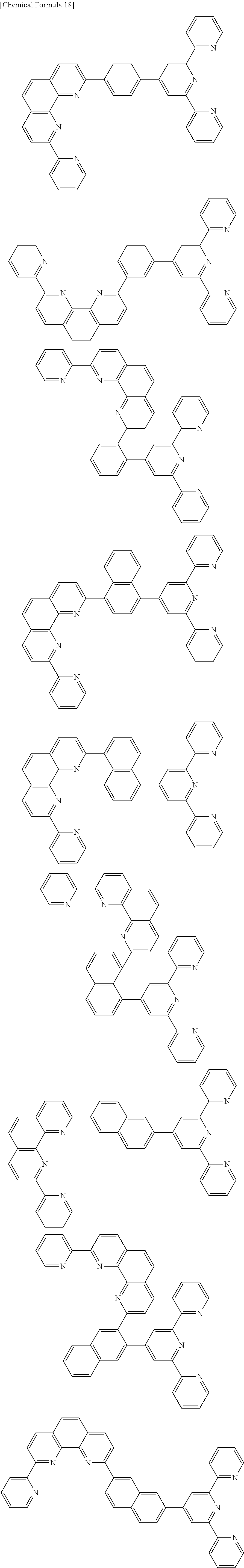

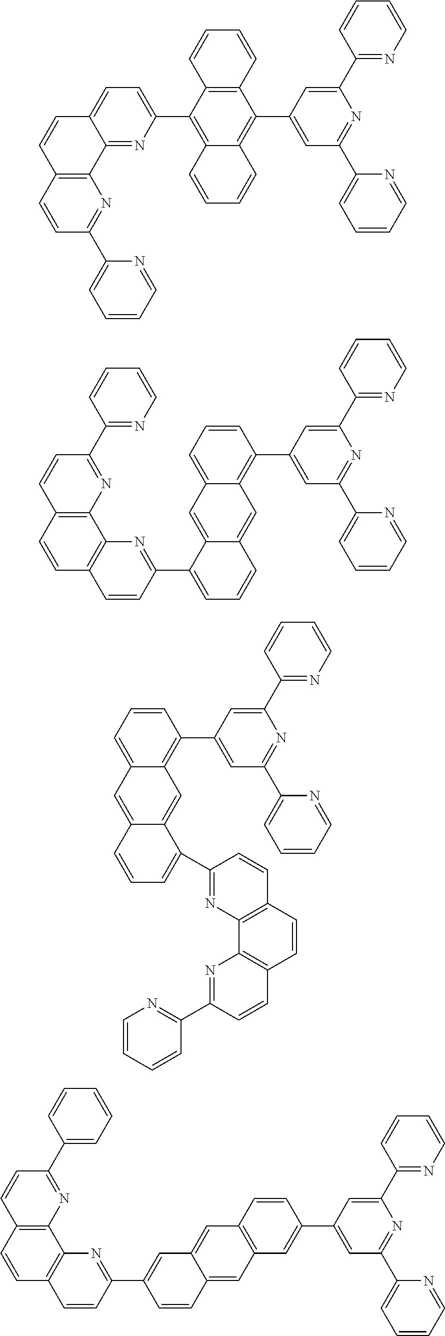

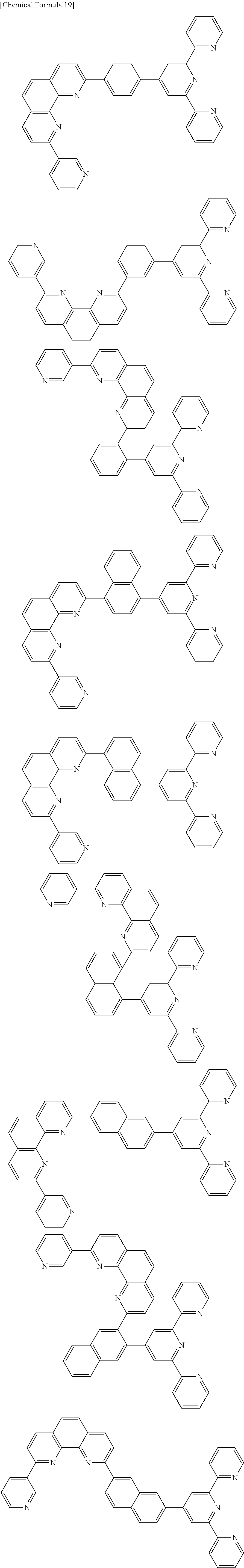

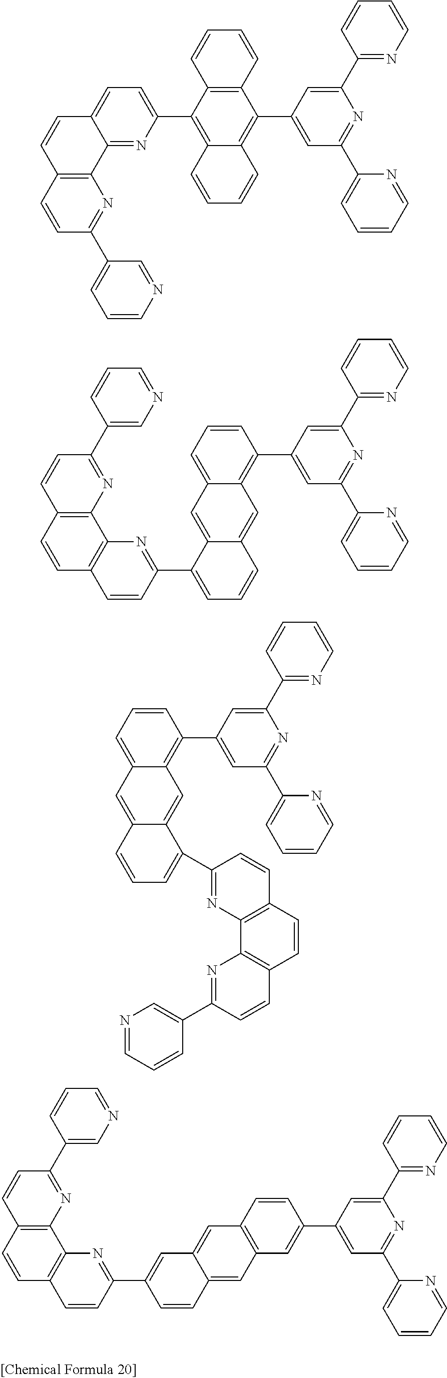

[chemical structure]

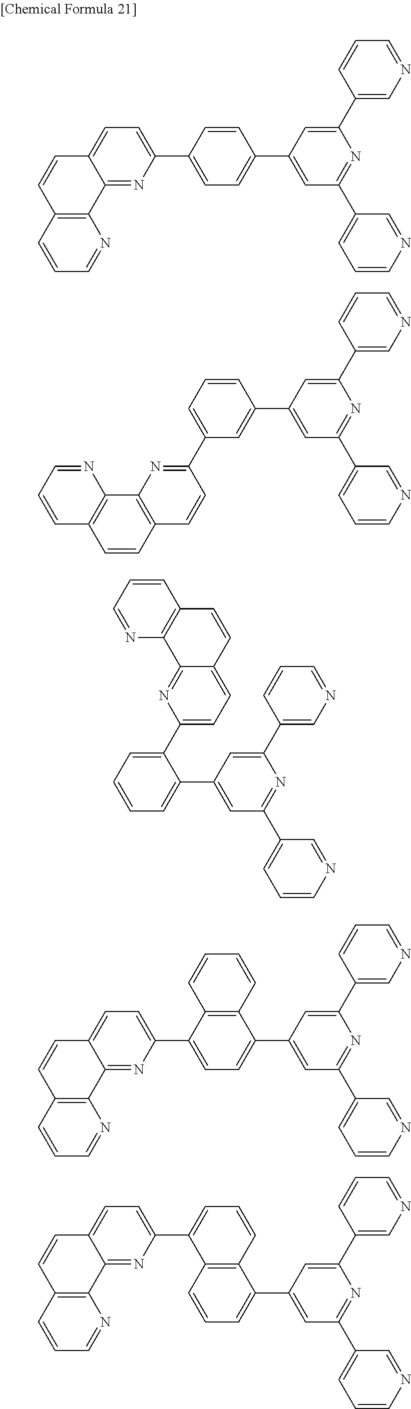

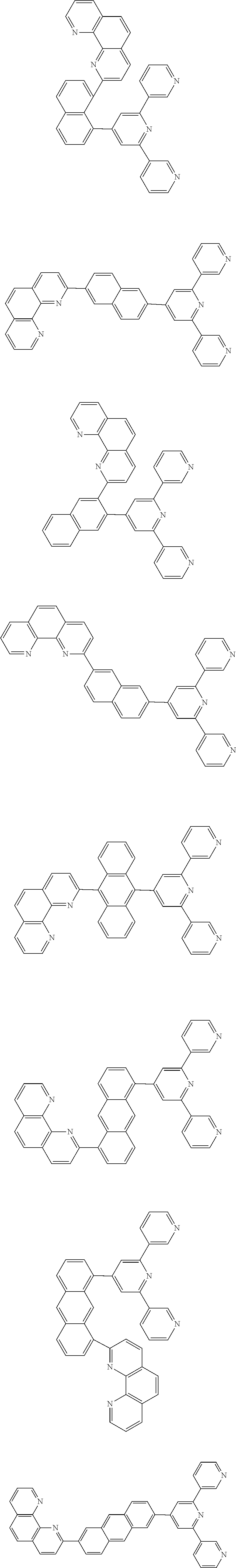

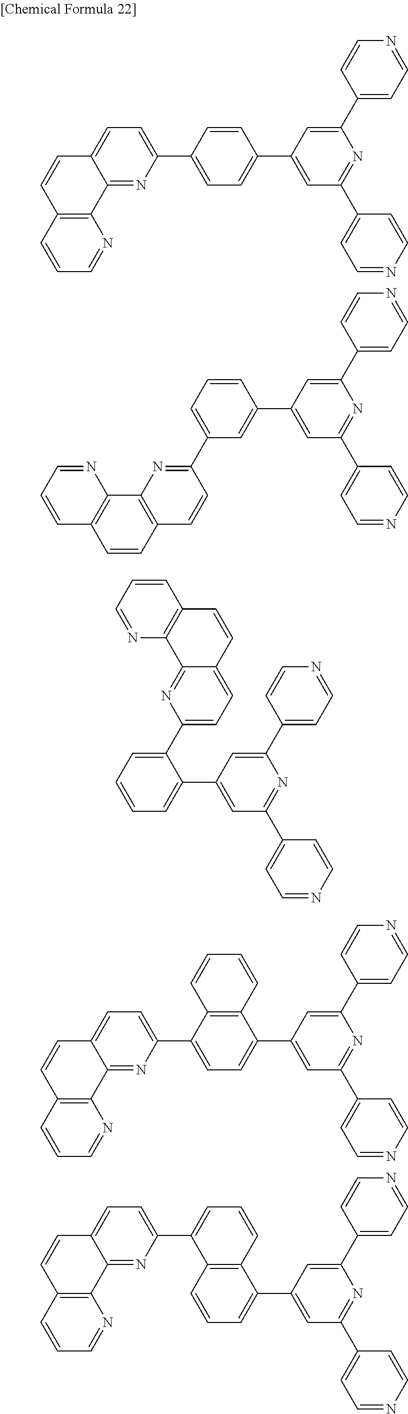

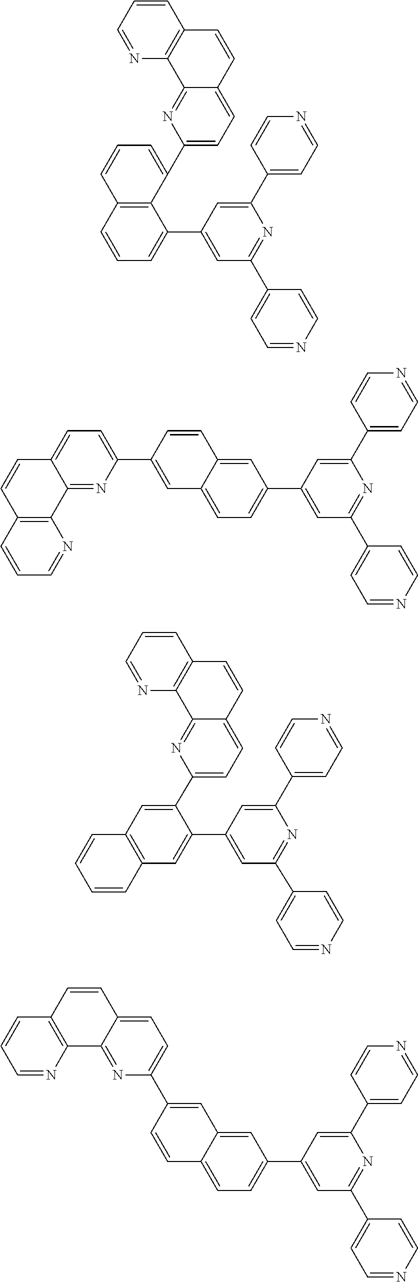

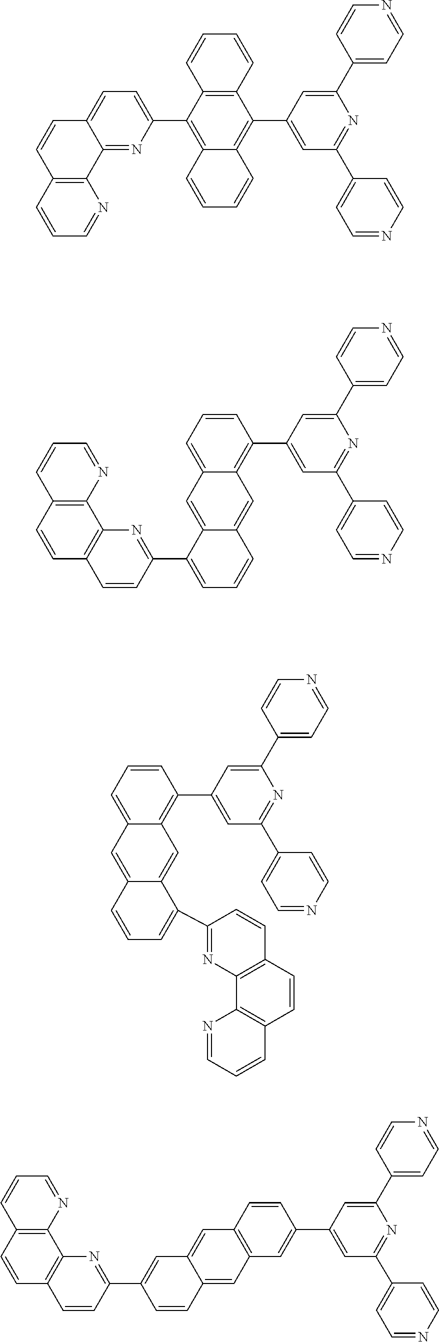

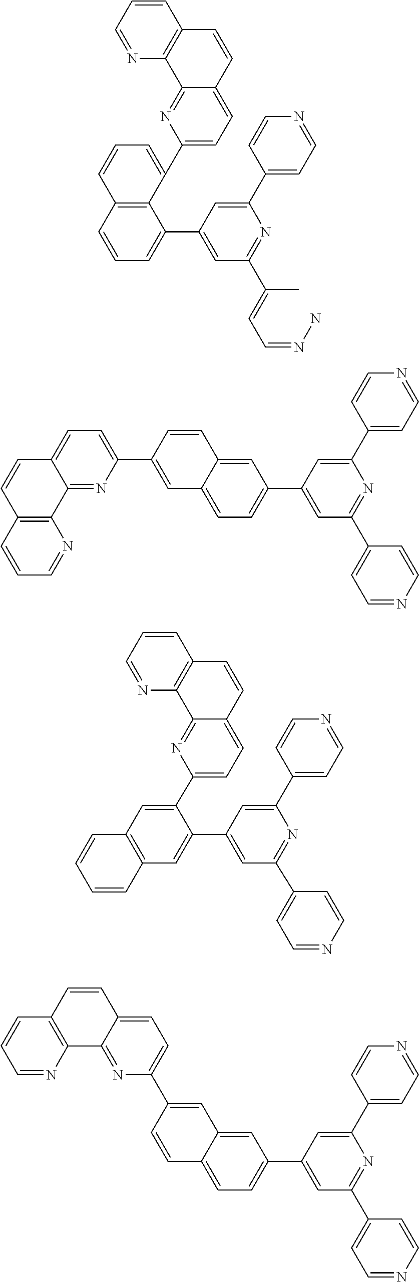

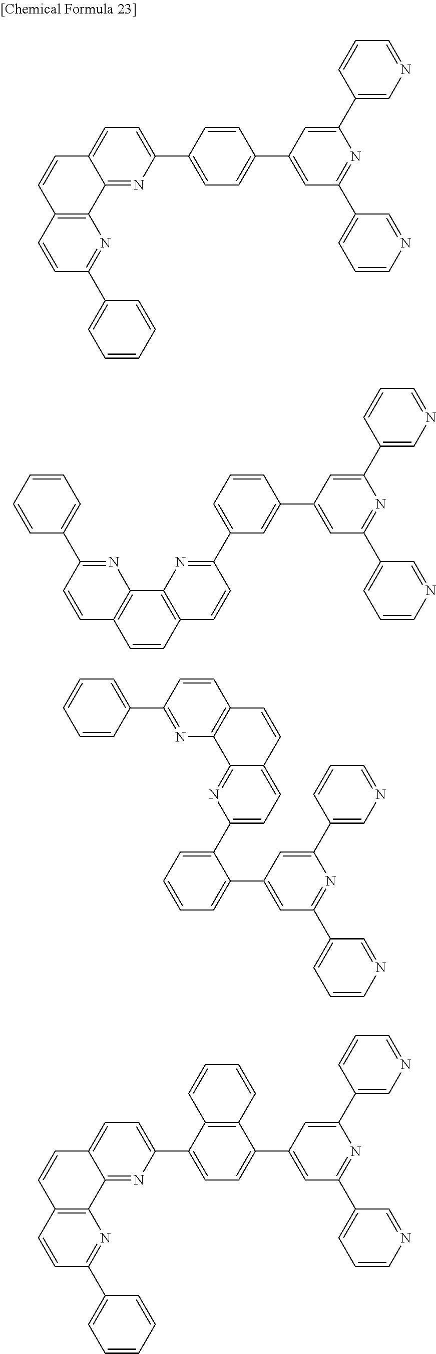

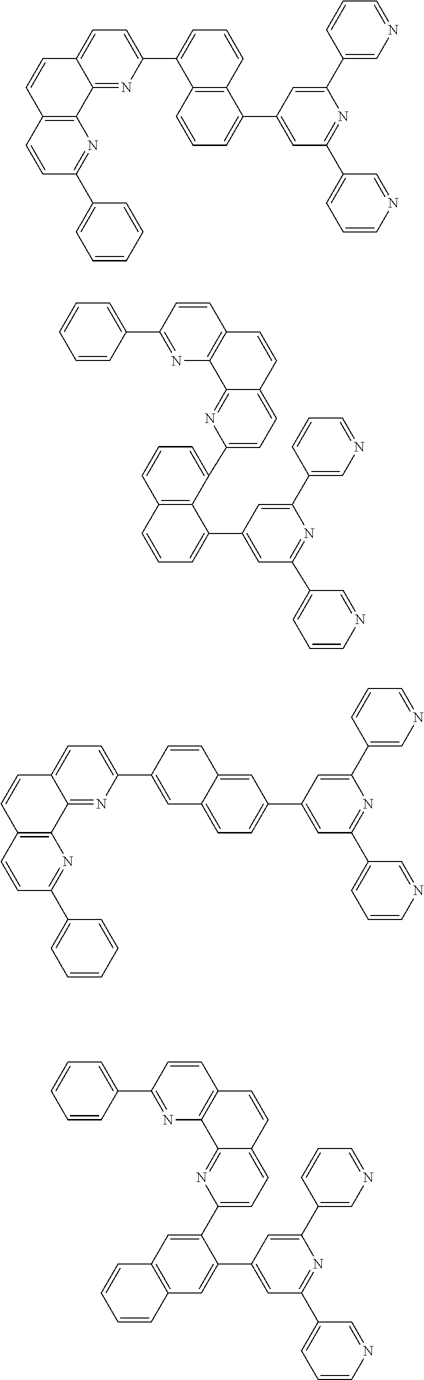

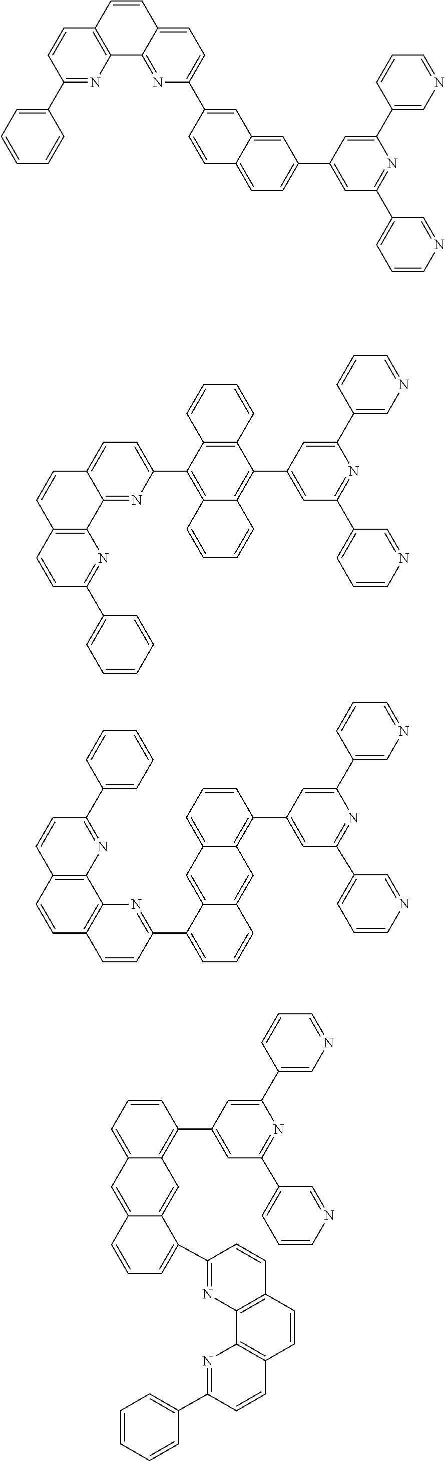

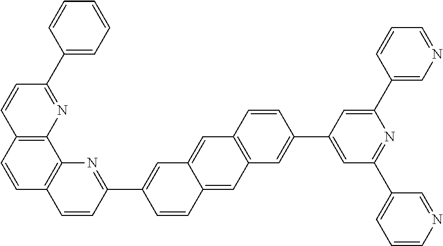

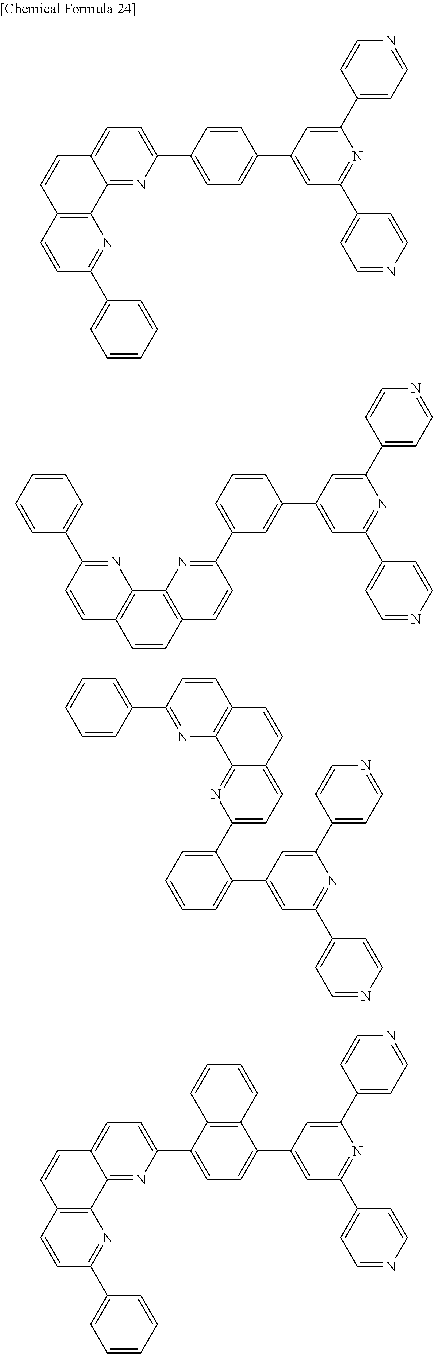

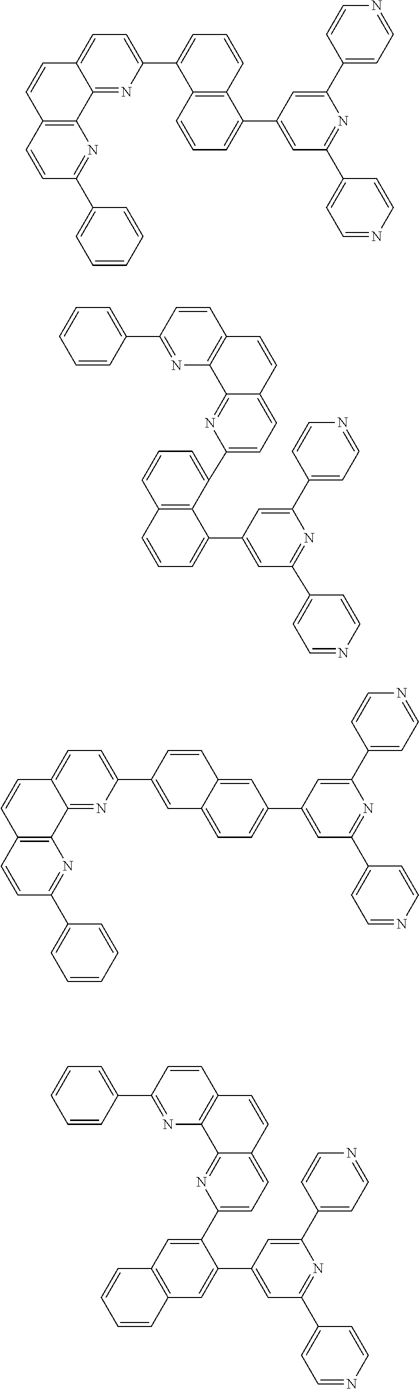

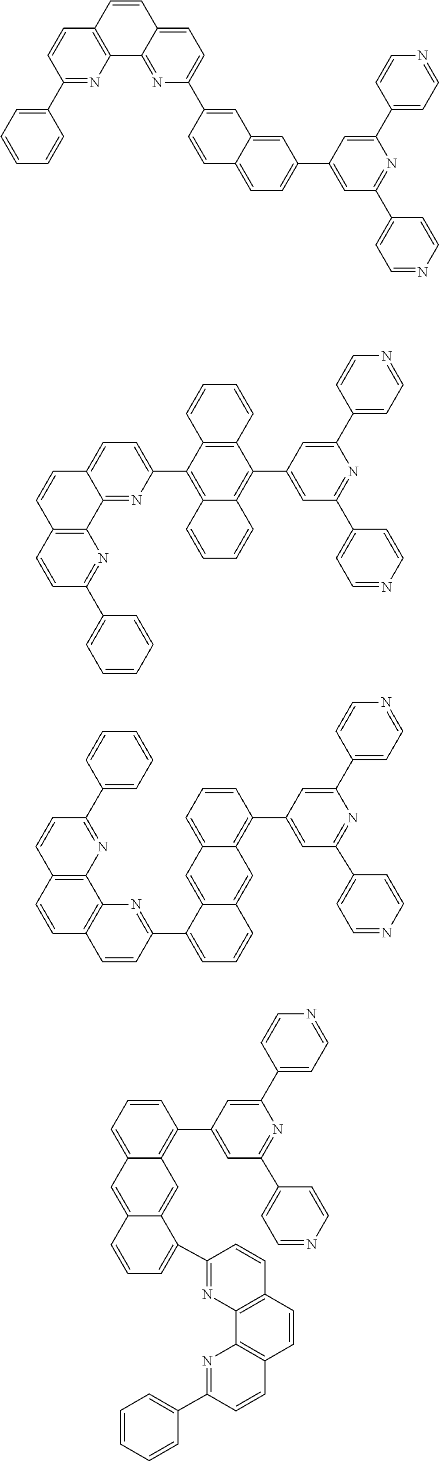

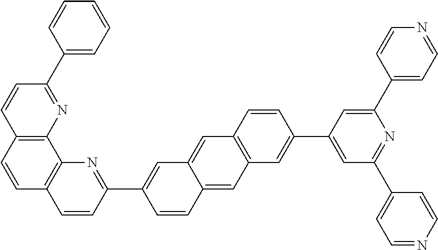

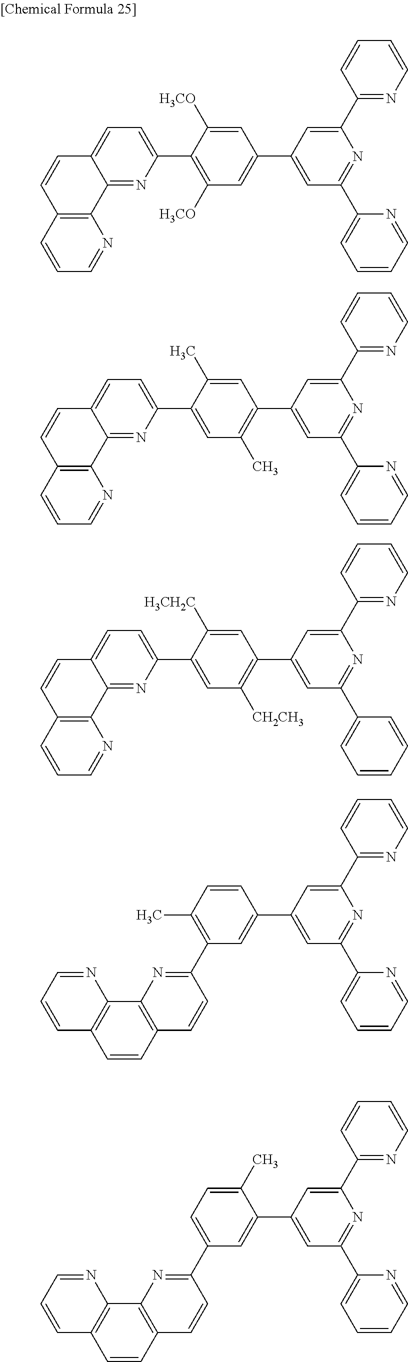

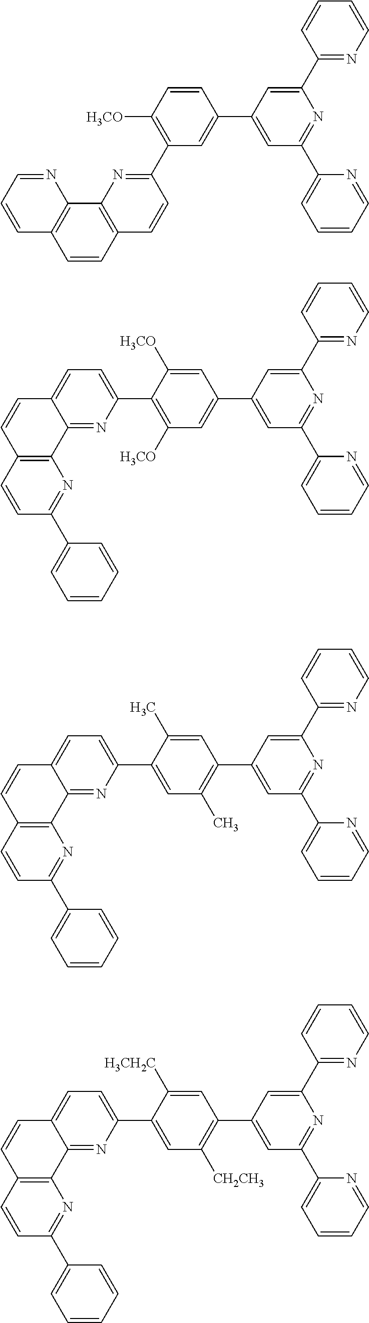

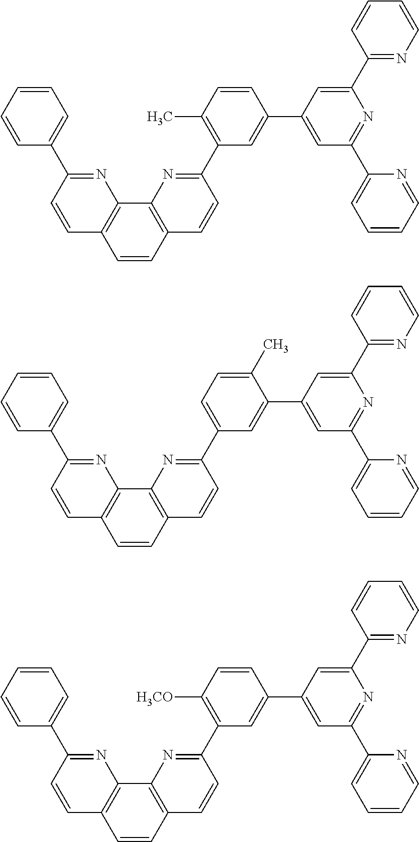

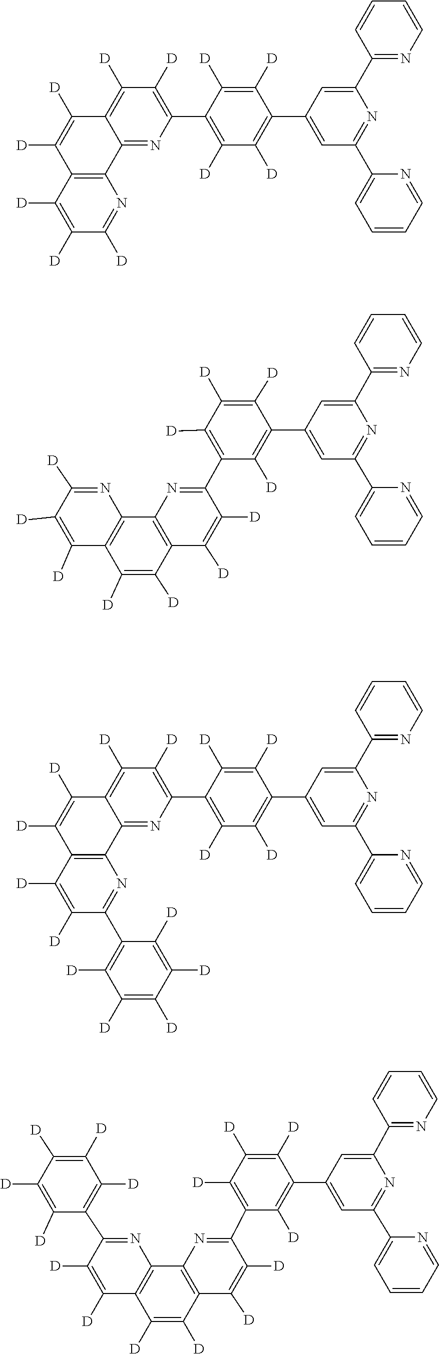

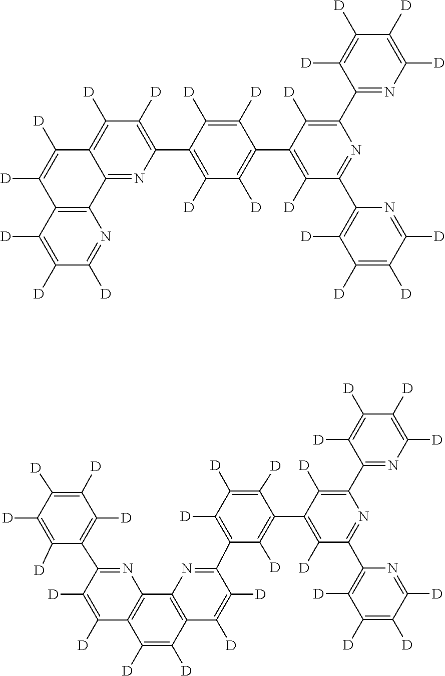

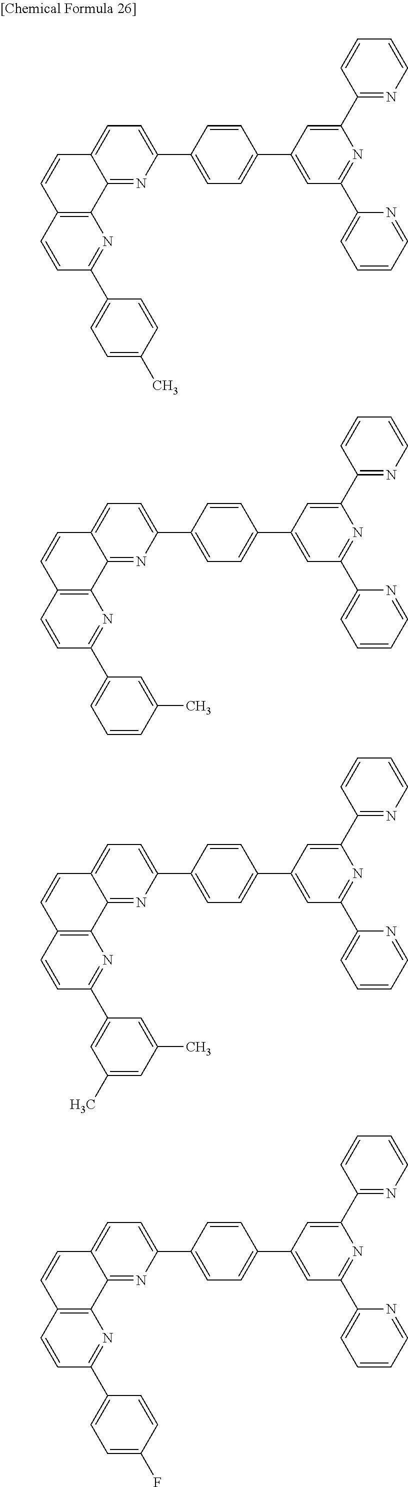

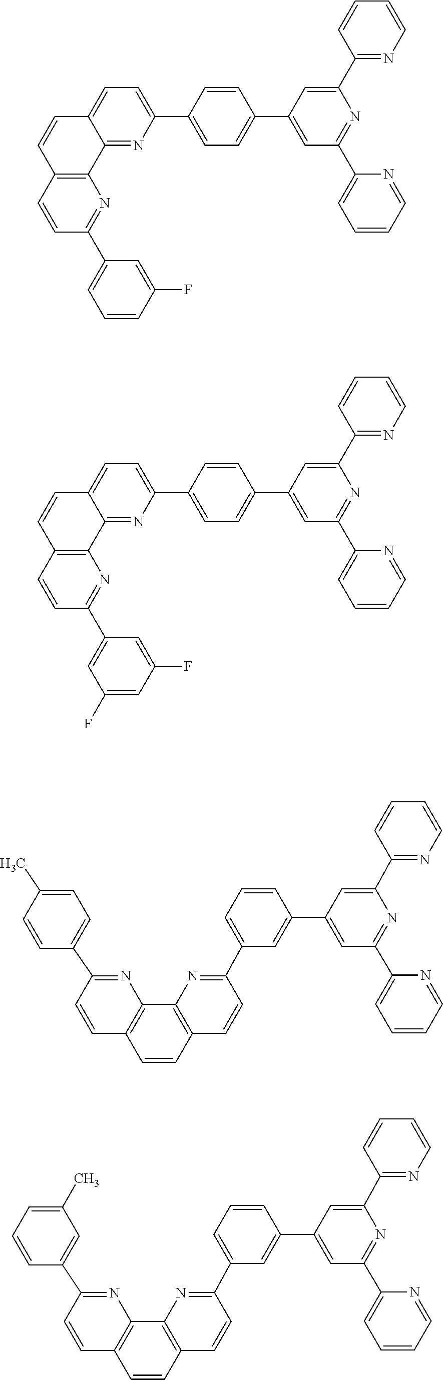

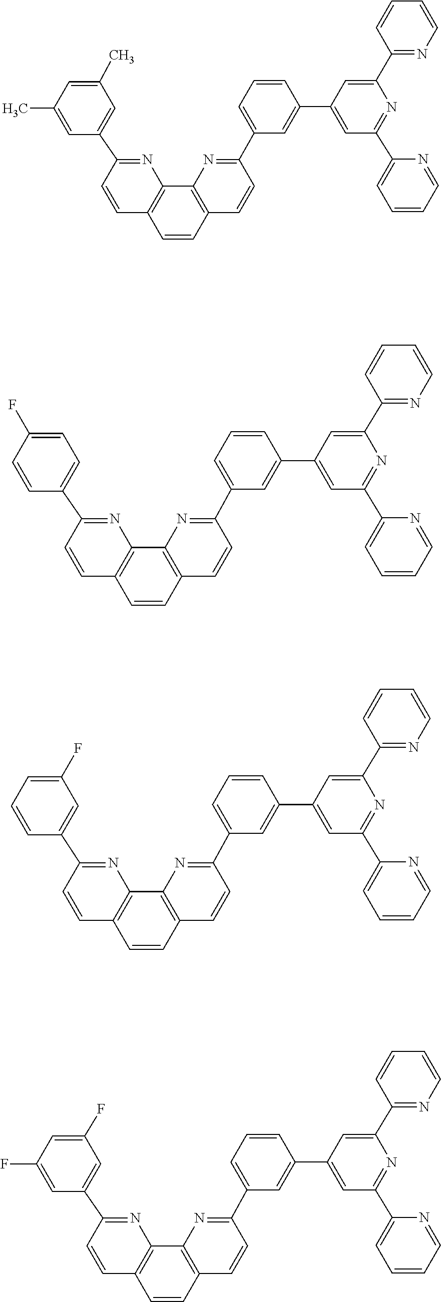

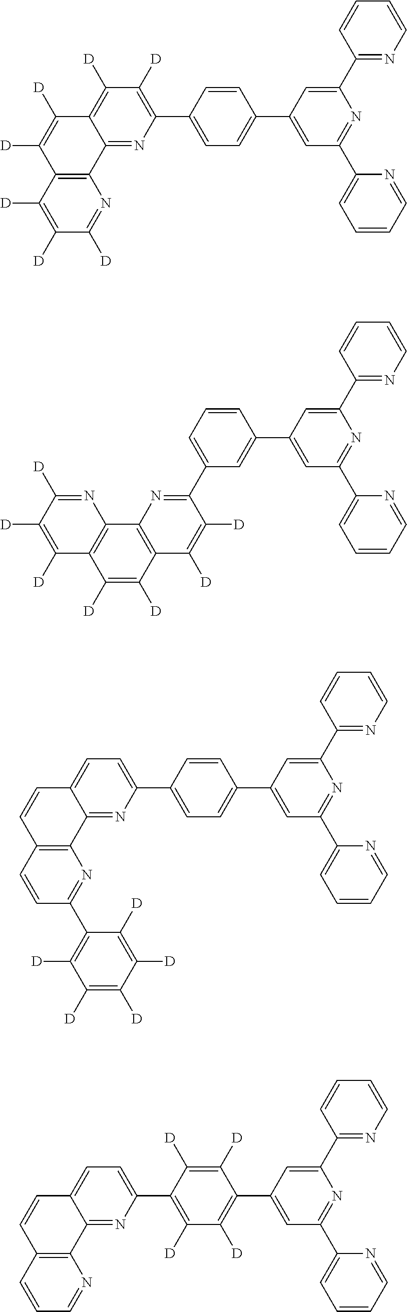

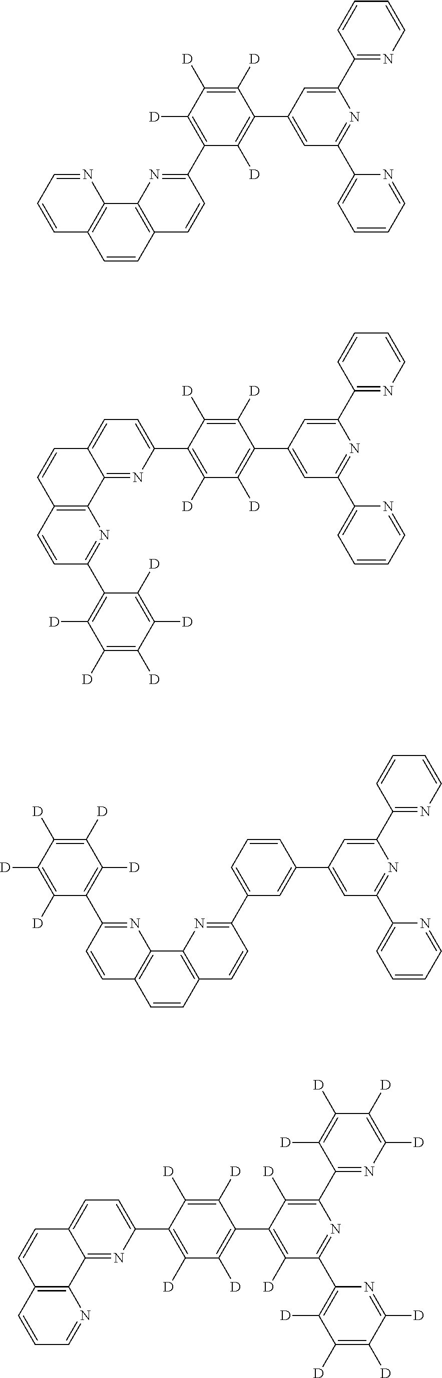

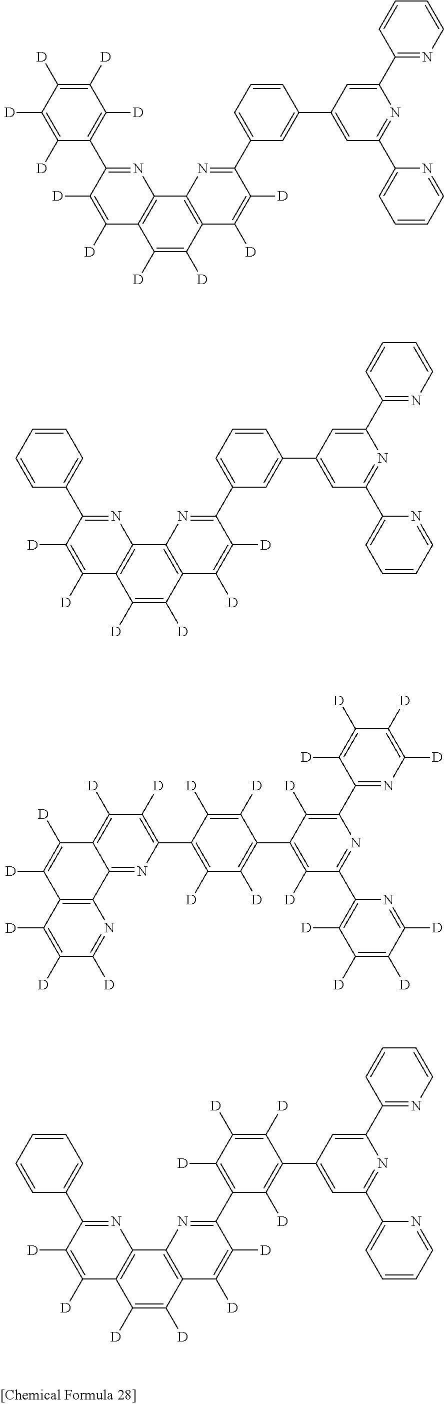

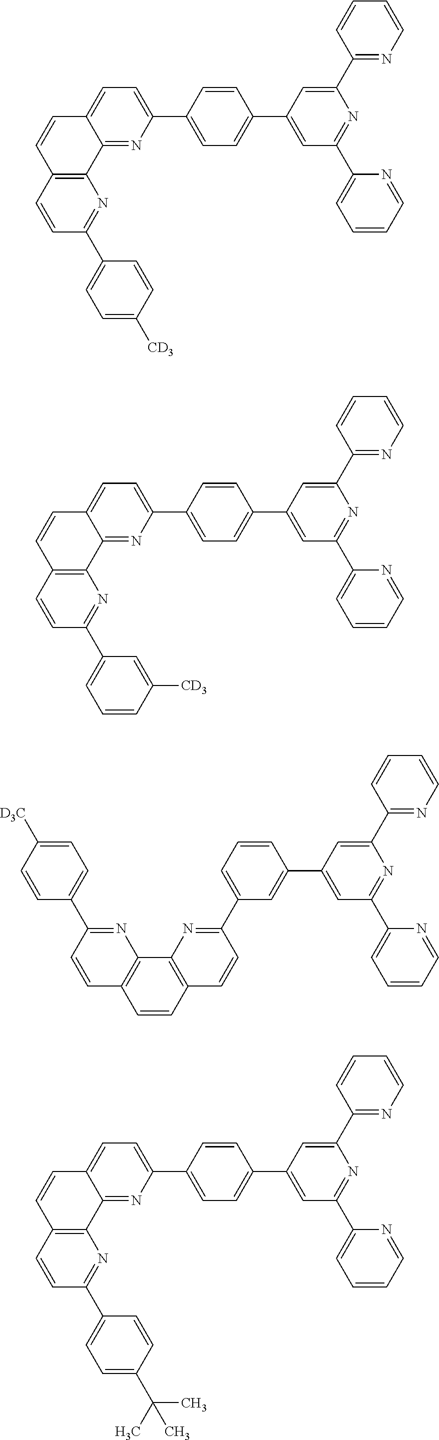

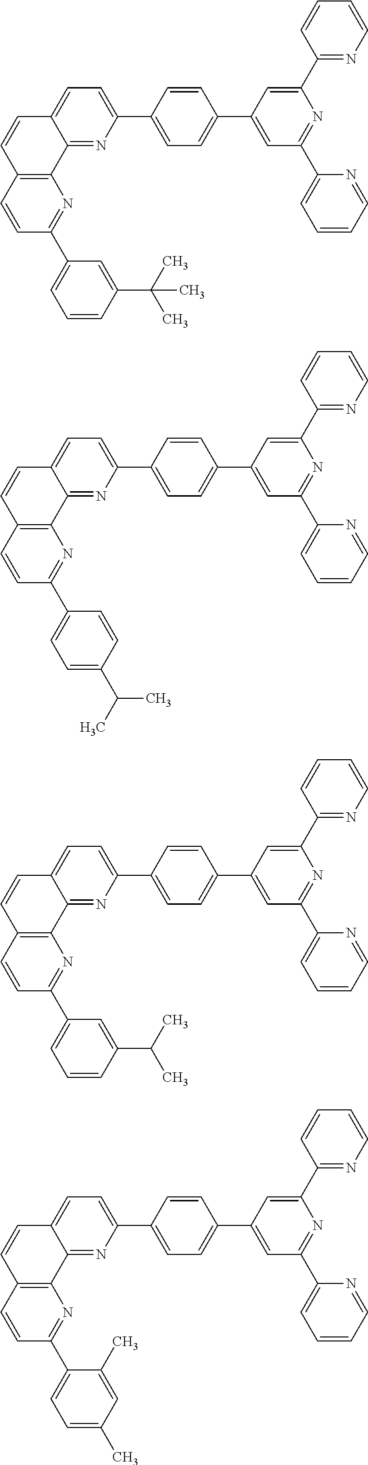

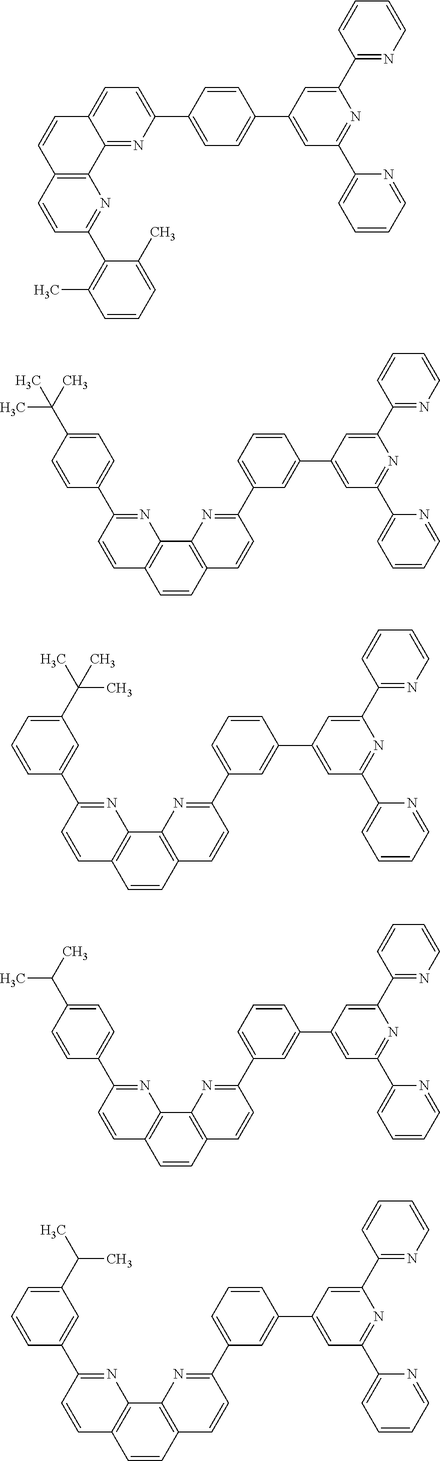

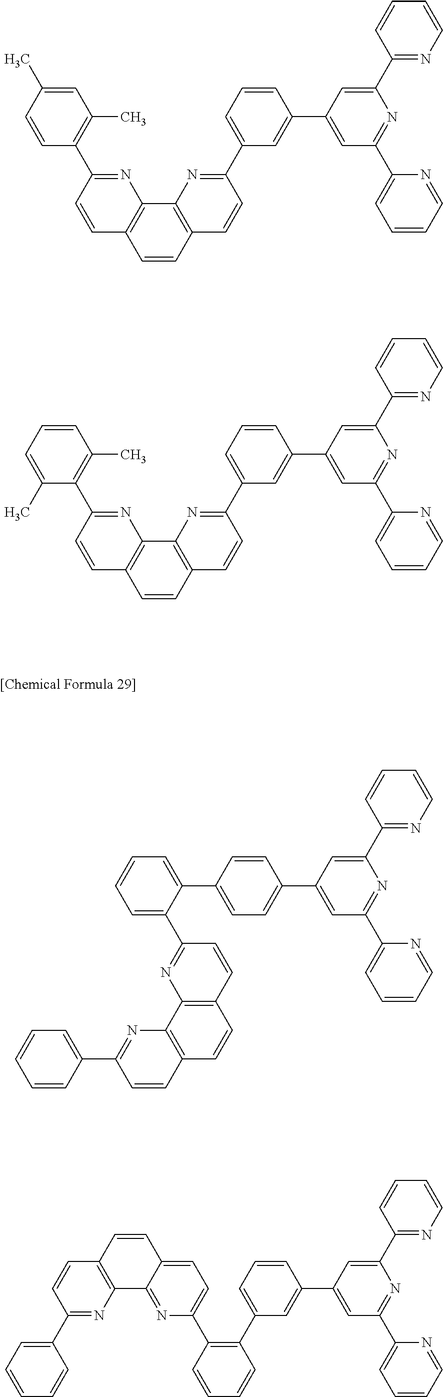

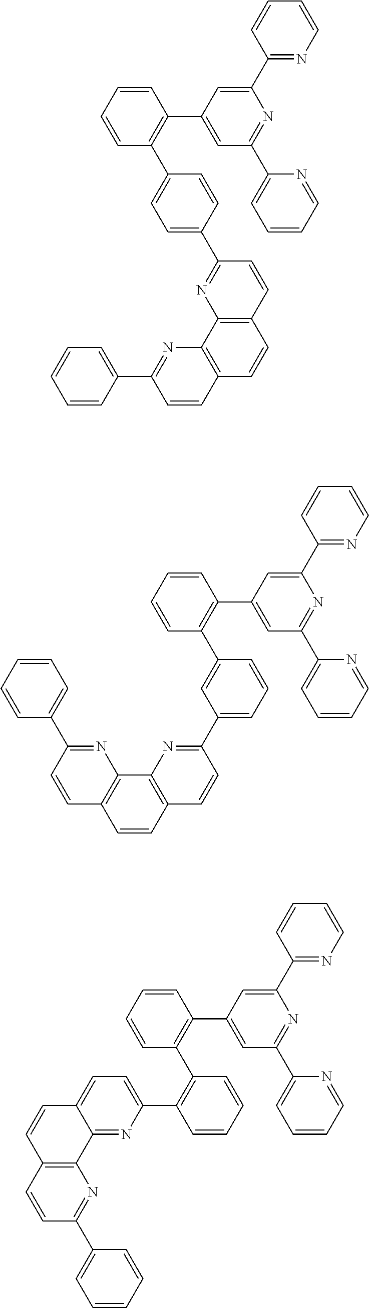

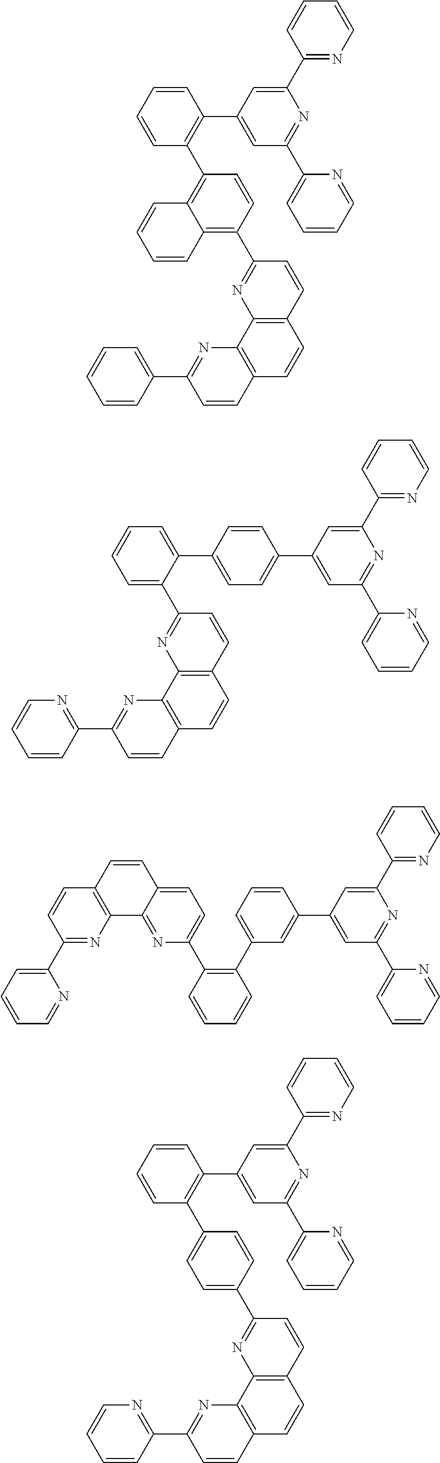

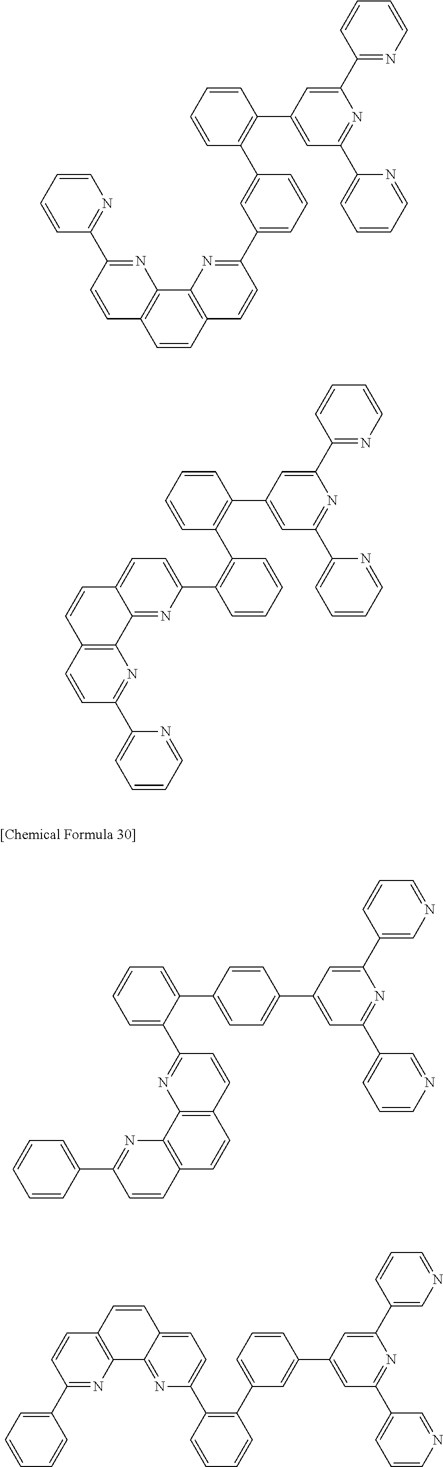

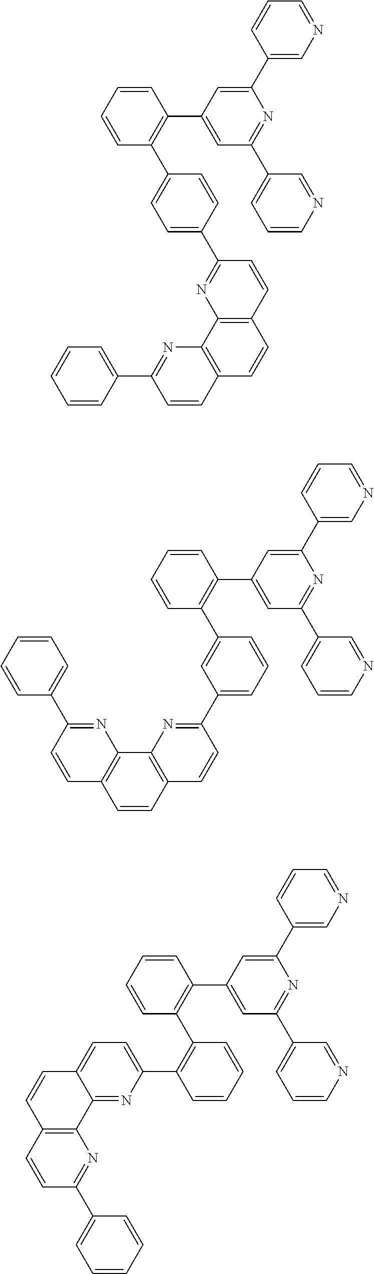

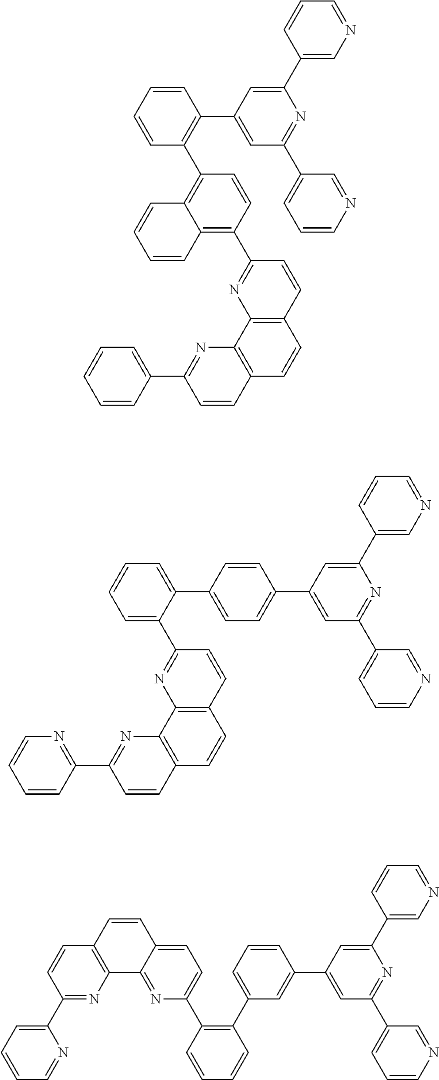

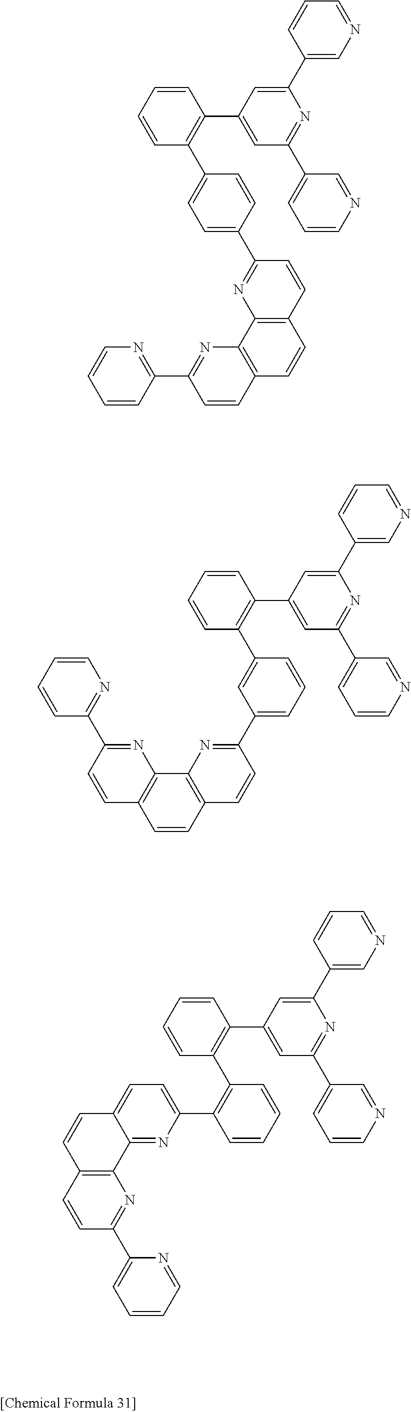

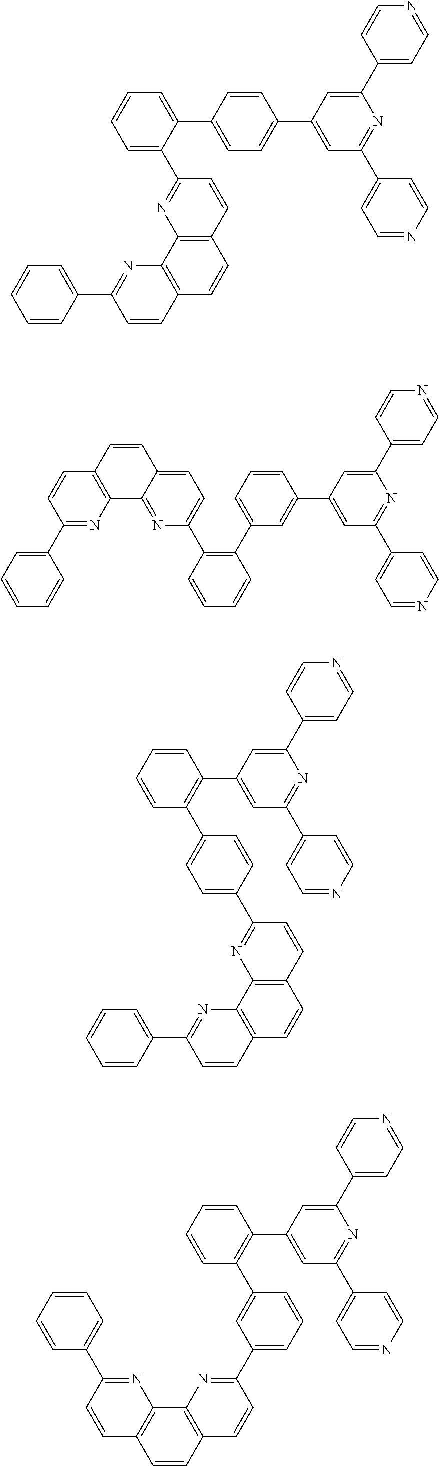

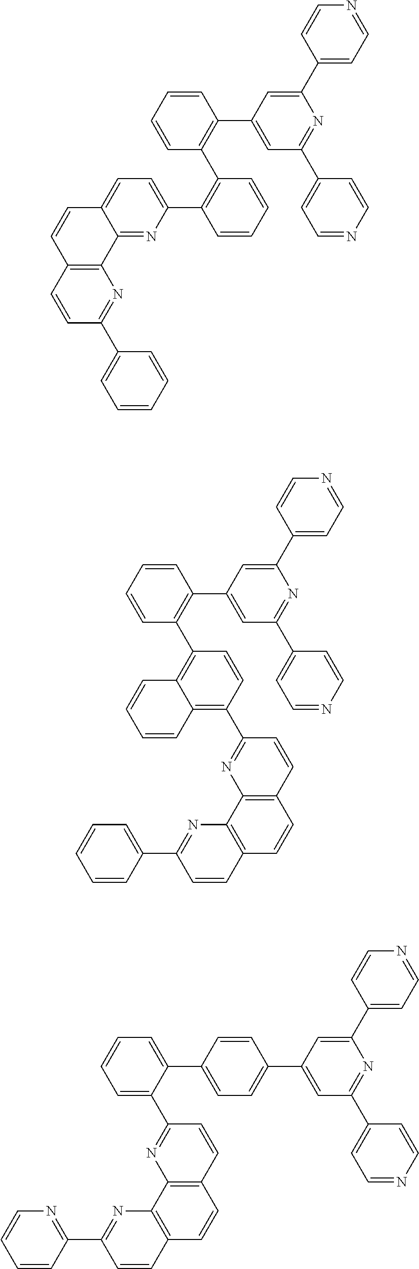

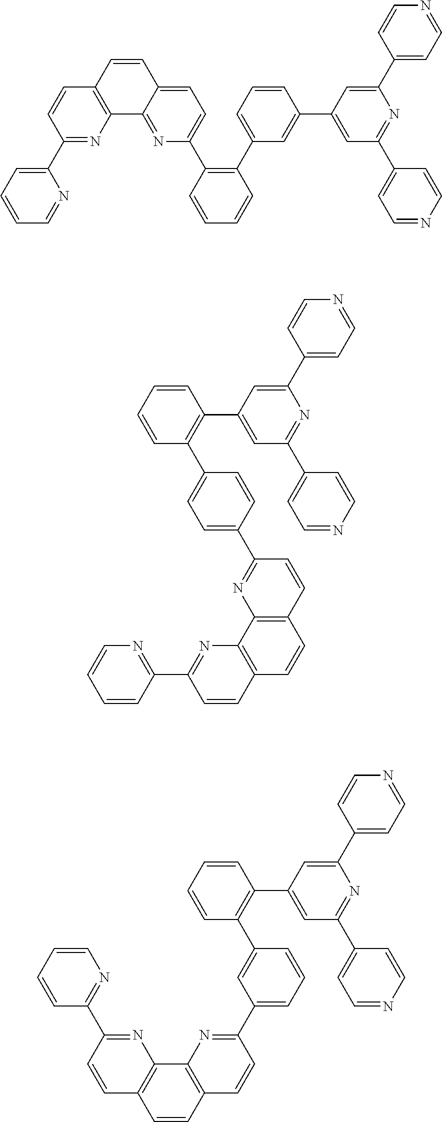

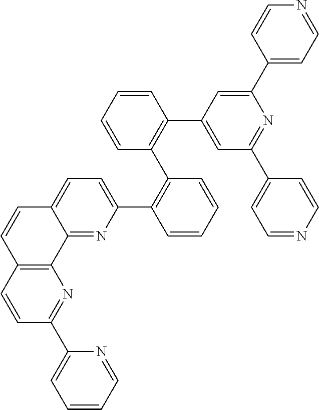

The compounds represented by the general formula (1) can be produced by a publicly known synthesis method. Examples of the synthesis method include, but are not limited to, a coupling reaction between a halogenated aryl derivative and an arylboronic acid derivative using palladium.

The n-type charge generation layer may further contain a second material selected from among an aromatic hydrocarbon compound, a compound having a nitrogen-boron bond, a compound having a silole ring, and a compound having a heteroaryl ring. When these compounds are contained, the efficiency of exchange of electrons can be improved by forming a hydrogen bond with the n-type charge generation layer host, so that the driving voltage can be reduced.

The p-type charge generation layer contains a p-type dopant and a p-type charge generation layer host. The p-type charge generation layer host will be described later. The p-type dopant to be used in the present invention is a radialene derivative represented by the following general formula (2) or an indacene derivative represented by the following general formula (4). That is, the p-type charge generation layer of the present invention contains a compound represented by the following general formula (2) or a compound represented by the following general formula (4).

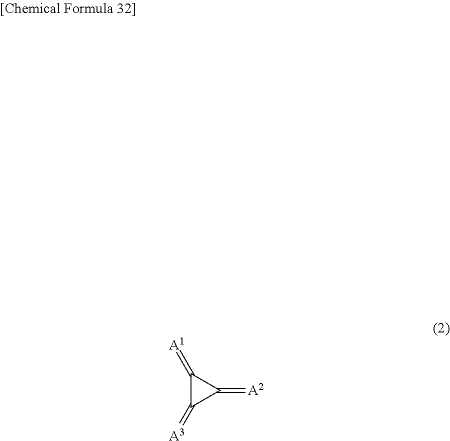

In the general formula (2), A¹ to A³ each independently represent a group that is represented by the general formula (3).

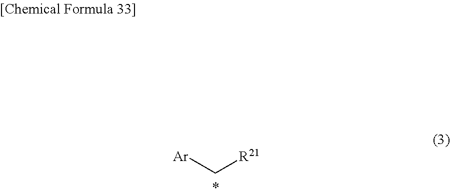

In the general formula (3), * represents a bonding position with A¹ to A³ of the general formula (2) and Z⁴¹ to Z⁴² of the following general formula (4); Ar represents a substituted or unsubstituted aryl group having 6 to 18 carbon atoms, or a substituted or unsubstituted heteroaryl group having 2 to 18 carbon atoms; and meanwhile, if these moieties are substituted, the substituent is one group or atom that is selected from the group consisting of a cyano group, a perfluoroalkyl group, a fluorine atom and a chlorine atom; and R²¹ represents a substituted or unsubstituted aryl group having 6 to 18 carbon atoms, a substituted or unsubstituted heteroaryl group having 2 to 18 carbon atoms, a perfluoroalkyl group having 1 to 8 carbon atoms, a fluorine atom or a cyano group.

The heteroaryl group denotes a cyclic aromatic group having one or a plurality of atoms other than carbon in the ring, such as a pyridyl group, a furanyl group, a thiophenyl group, a quinolinyl group, an isoquinolinyl group, a pyrazinyl group, a pyrimidyl group, a pyridazinyl group, a triazinyl group, a naphthyridinyl group, a cinnolinyl group, a phthalazinyl group, a quinoxalinyl group, a quinazolinyl group, a benzofuranyl group, a benzothiophenyl group, an indolyl group, a dibenzofuranyl group, a dibenzothiophenyl group, a carbazolyl group, a benzocarbazolyl group, a carbolinyl group, an indolocarbazolyl group, a benzofurocarbazolyl group, a benzothienocarbazolyl group, a dihydroindenocarbazolyl group, a benzoquinolinyl group, an acridinyl group, a dibenzoacridinyl group, a benzoimidazolyl group, an imidazopyridyl group, a benzoxazolyl group, a benzothiazolyl group, and a phenanthrolinyl group. The term “naphthyridinyl group” refers to any one of a 1,5-naphthyridinyl group, a 1,6-naphthyridinyl group, a 1,7-naphthyridinyl group, a 1,8-naphthyridinyl group, a 2,6-naphthyridinyl group, and a 2,7-naphthyridinyl group. The heteroaryl group may or may not have a substituent. The number of ring-forming atoms in the heteroaryl group is not particularly limited, and is preferably in the range of 3 or more and 40 or less, and more preferably 3 or more and 30 or less.

The perfluoroalkyl group denotes a group being an alkyl group with all hydrogens thereof replaced by fluorine, such as a trifluoromethyl group, a pentafluoroethyl group, and an octafluoropropyl group. The number of carbon atoms in the perfluoroalkyl group is not particularly limited, and is usually in the range of 1 or more and 20 or less, and more preferably 1 or more and 8 or less from the viewpoints of easy availability and cost.

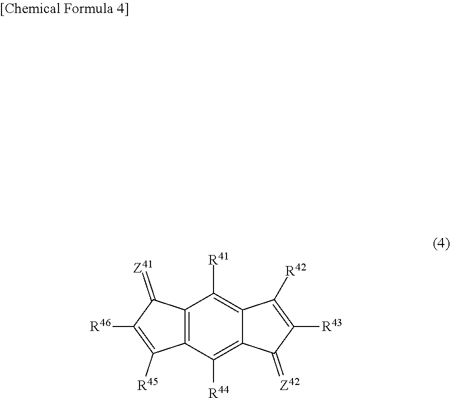

In general formula (4), R⁴¹ to R⁴⁶ are each independently selected from the group consisting of a hydrogen atom, a substituted or unsubstituted aryl group having 6 to 12 carbon atoms, a substituted or unsubstituted heteroaryl group having 1 to 12 carbon atoms, an alkoxy group having 1 to 12 carbon atoms, an ether group having 1 to 12 carbon atoms, a cyano group, a fluorine atom, a trifluoromethyl group, a trifluoromethoxy group, and a trimethylsilyl group, provided that at least one of R⁴¹ to R⁴⁶ has a cyano group; the R⁴¹ to R⁴⁶ moieties may form a ring by having adjacent substituents fused with each other; and Z⁴¹ and Z⁴² are each independently a group represented by the general formula (3).

Examples of the compound represented by the general formula (2) include the following compounds. The following are examples, and any compound other than the compounds specified herein is preferably used as long as it is represented by the general formula (2).

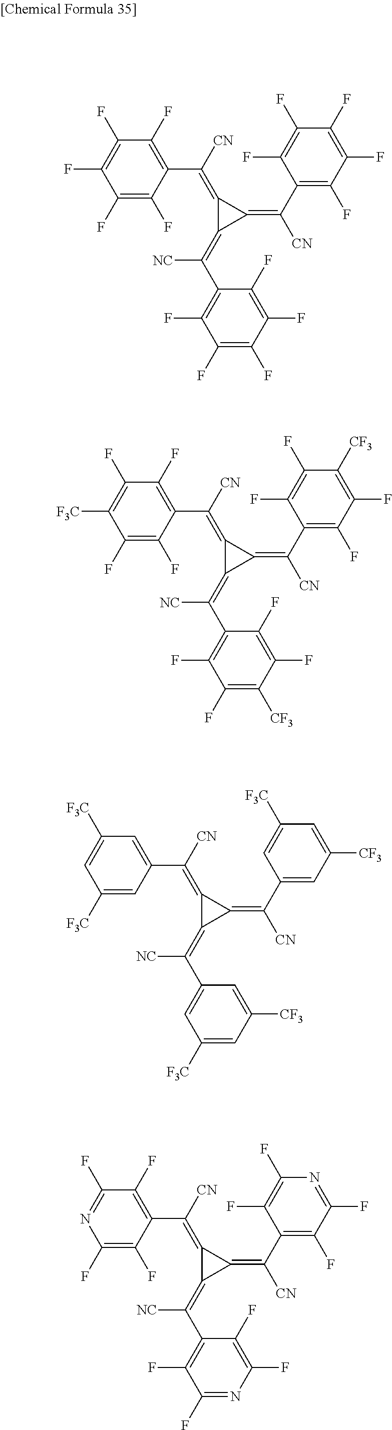

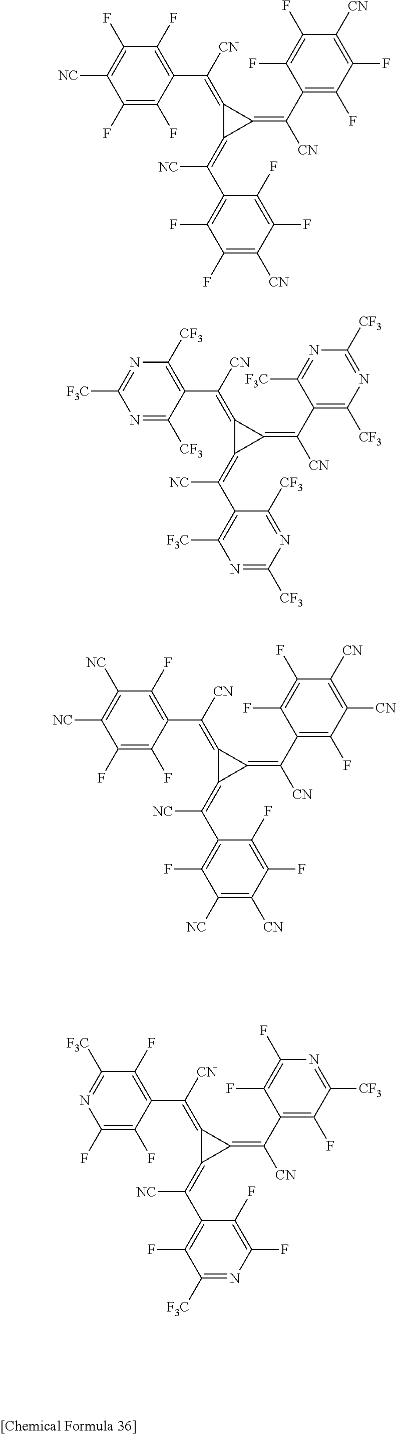

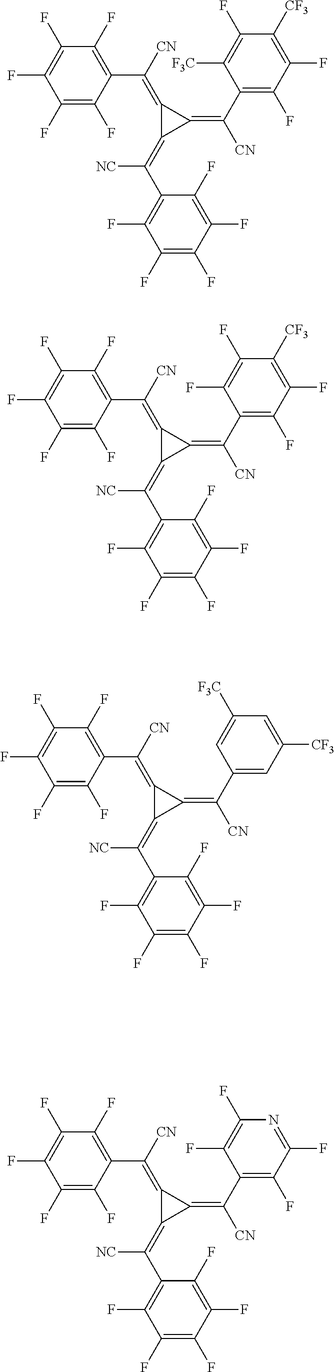

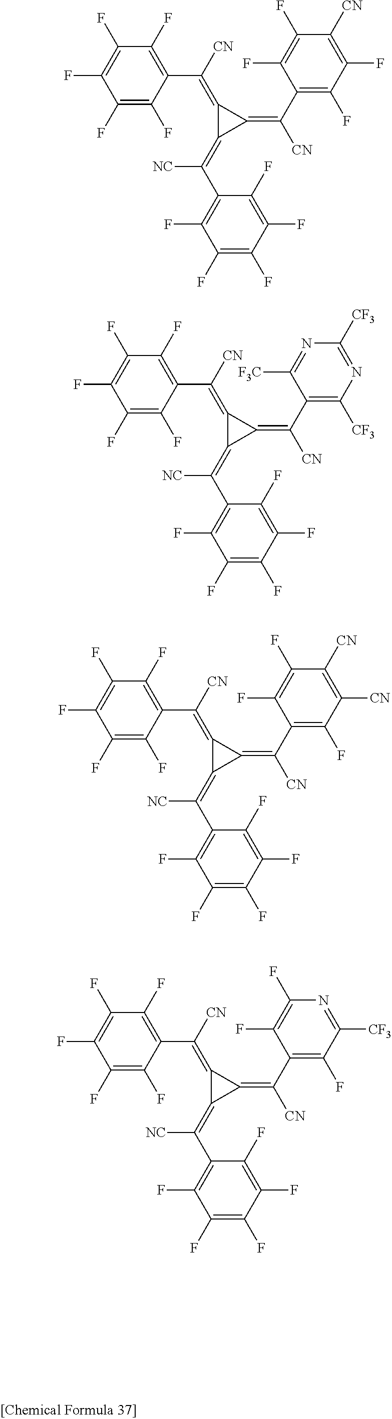

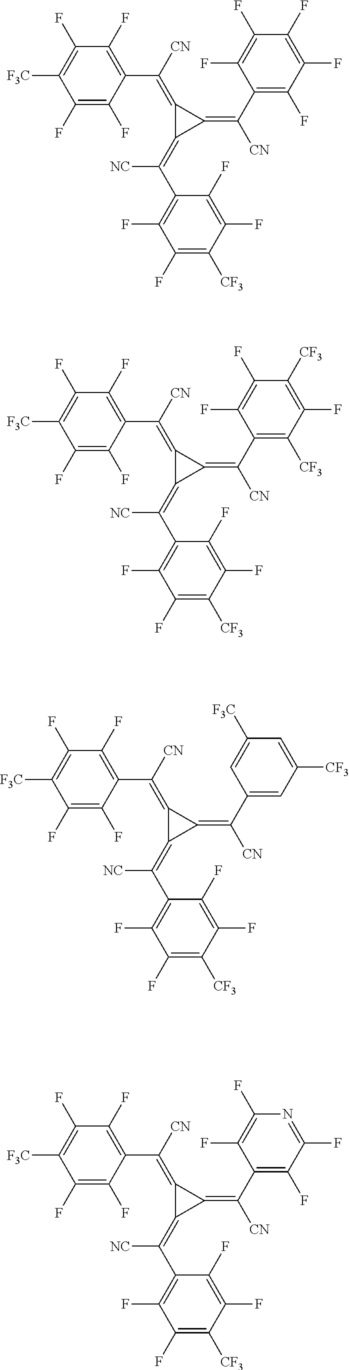

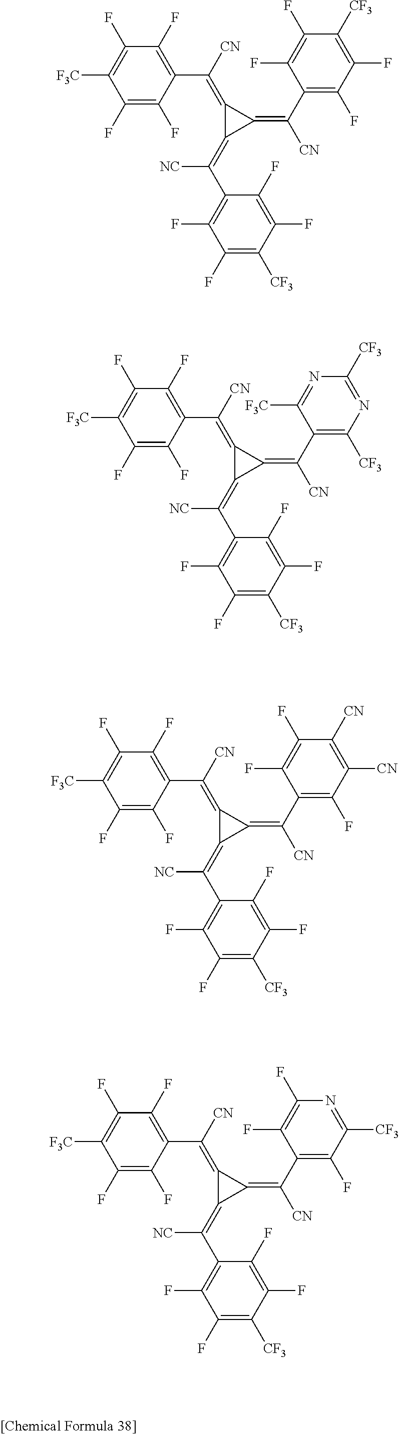

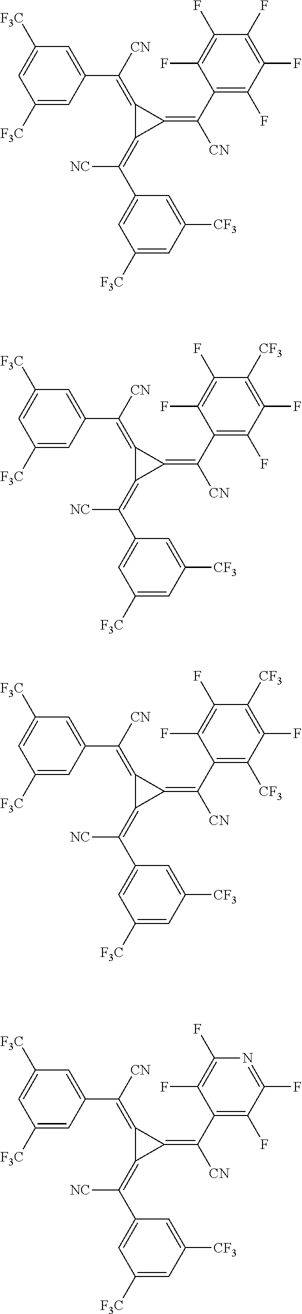

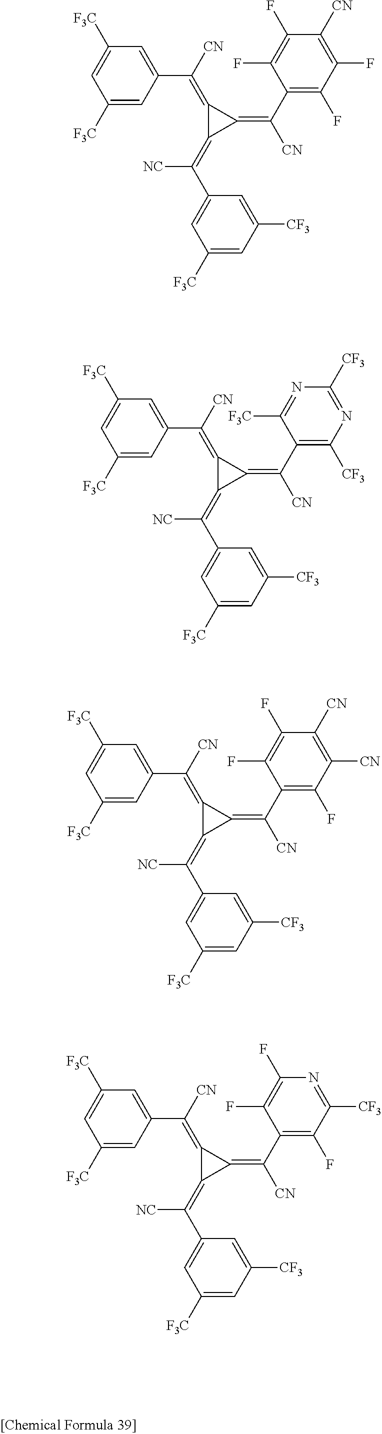

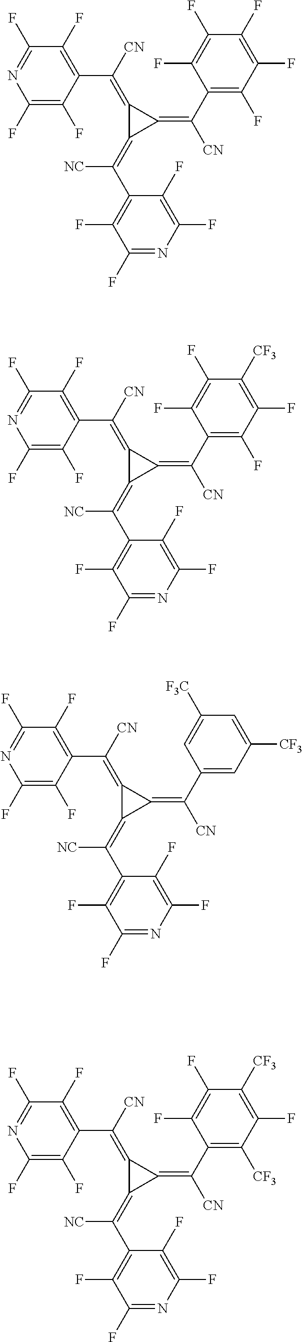

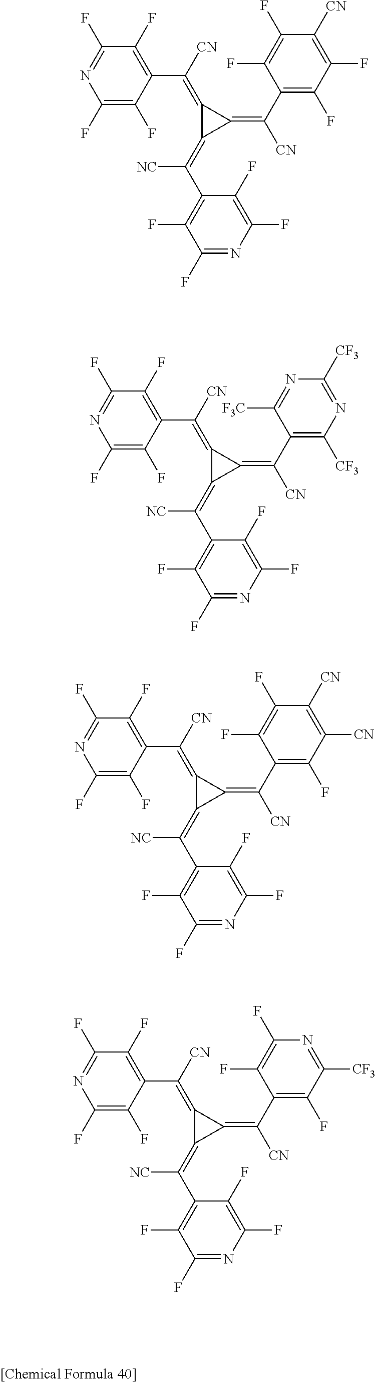

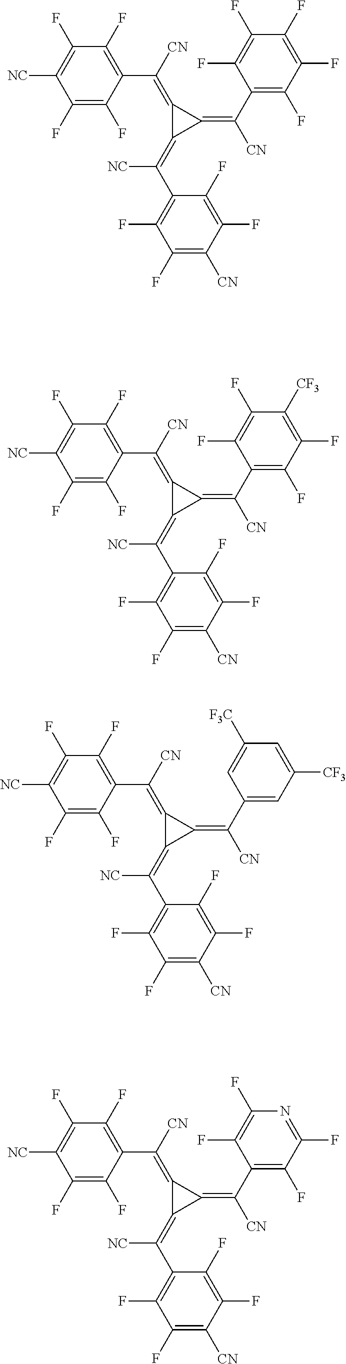

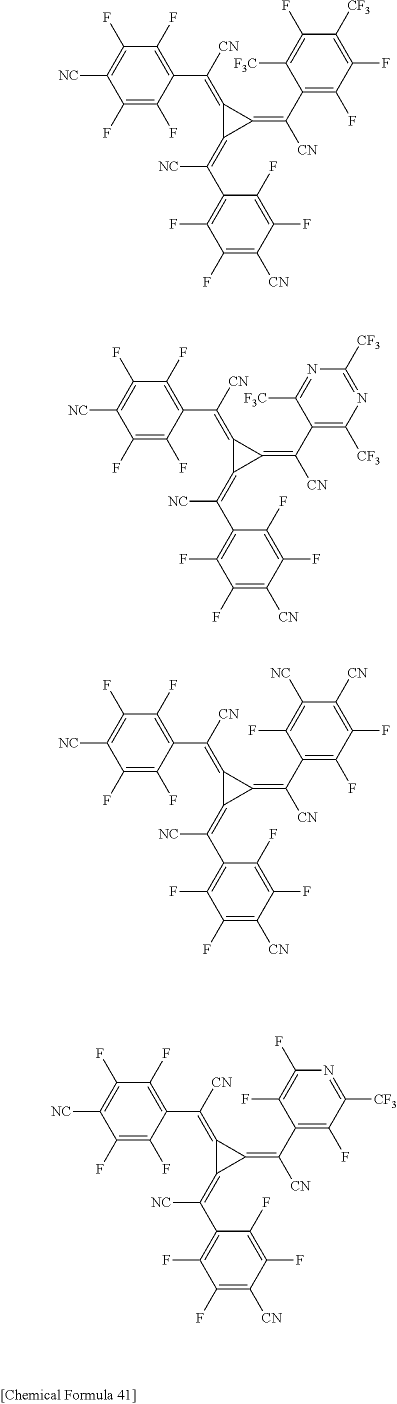

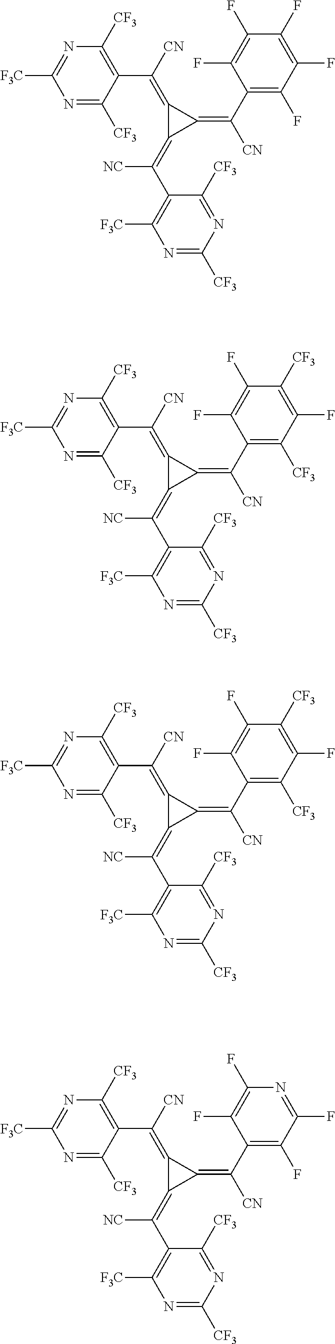

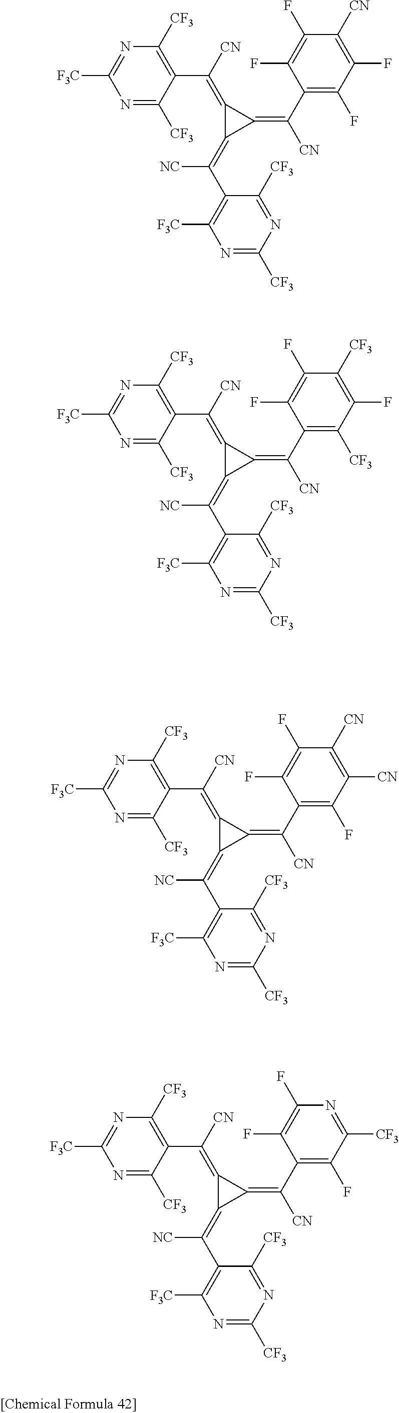

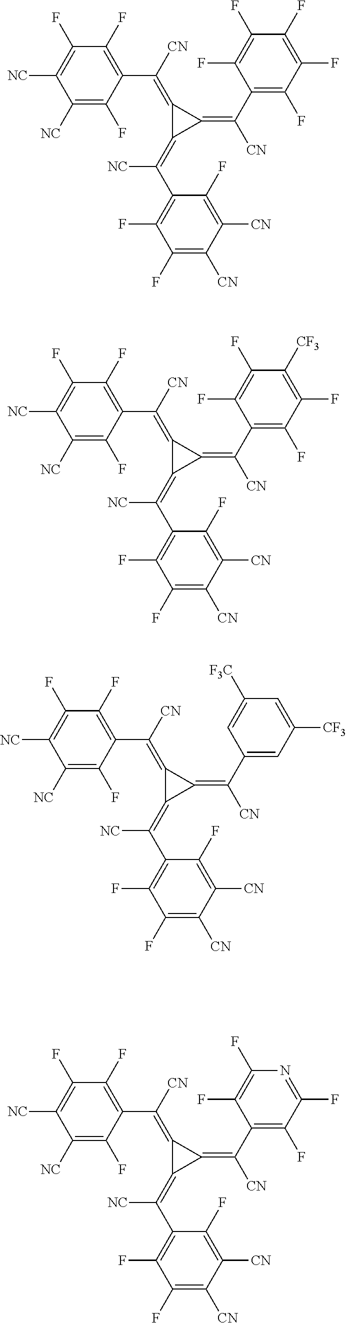

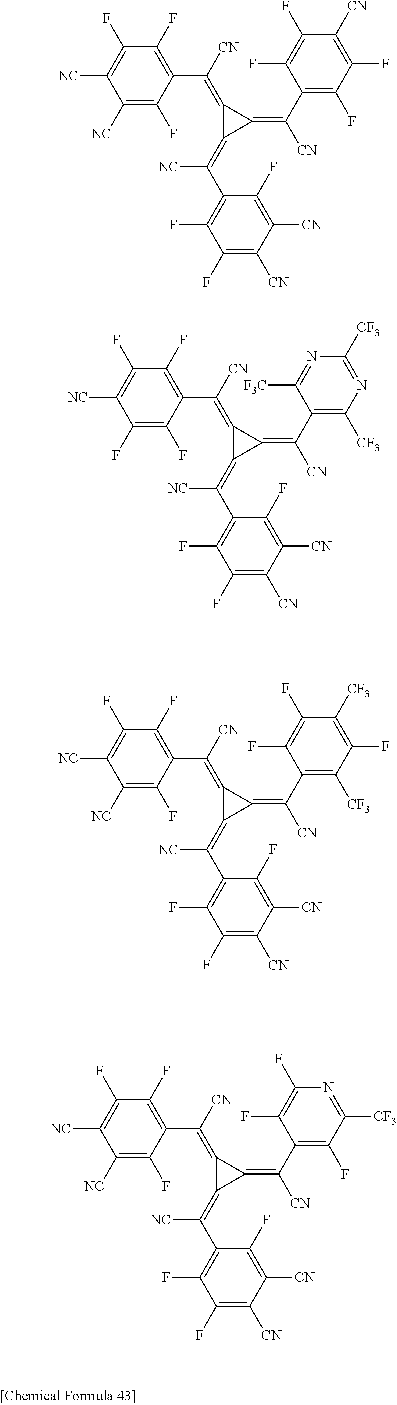

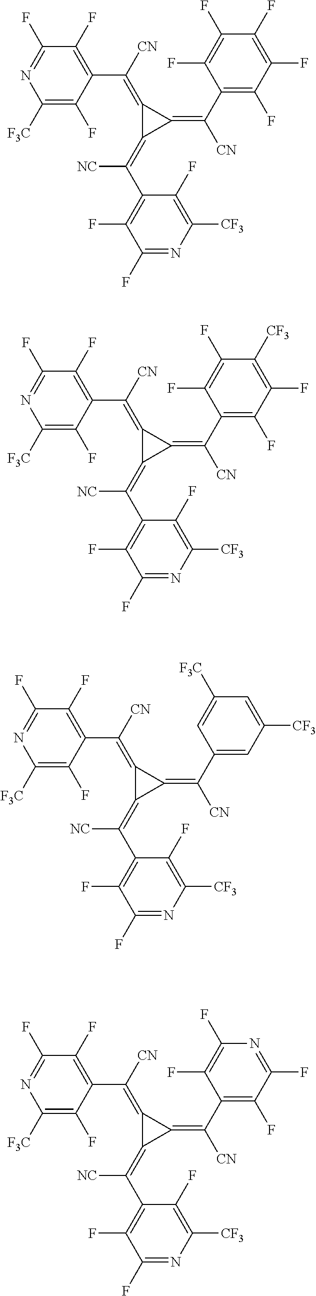

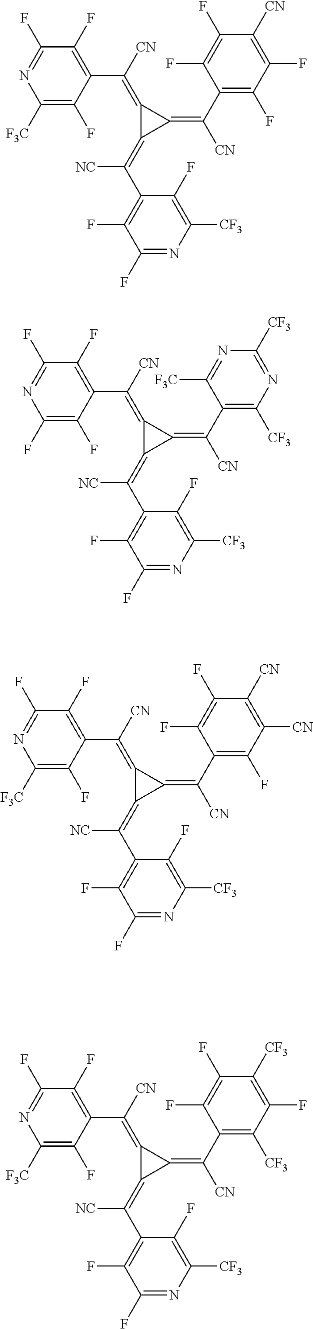

Examples of the compound represented by the general formula (4) include the following compounds. The following are examples, and any compound other than the compounds specified herein is preferably used as long as it is represented by the general formula (4).

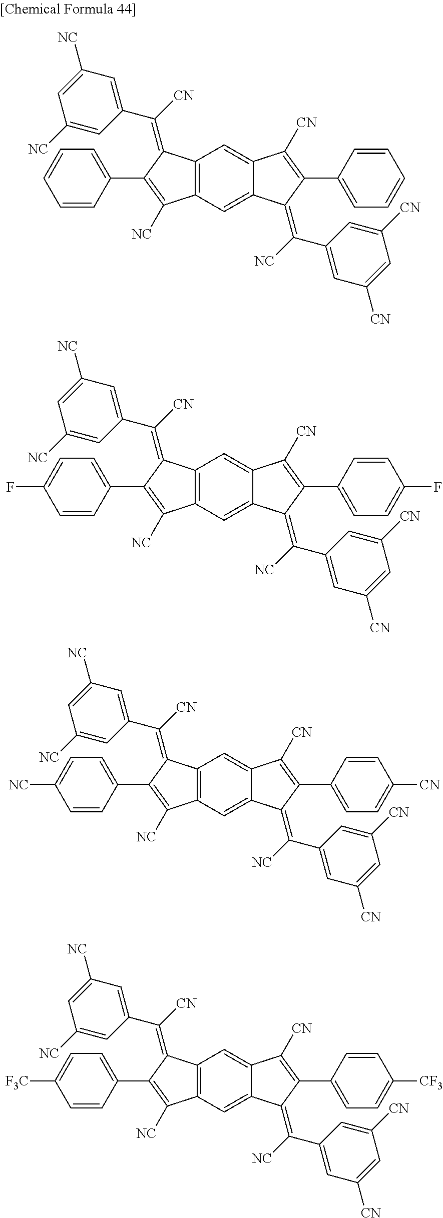

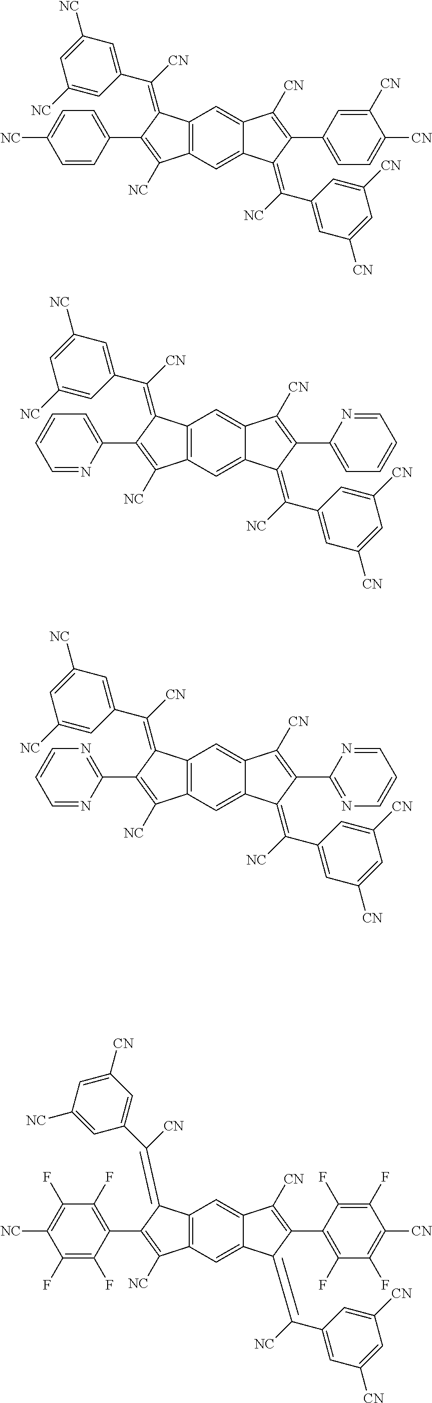

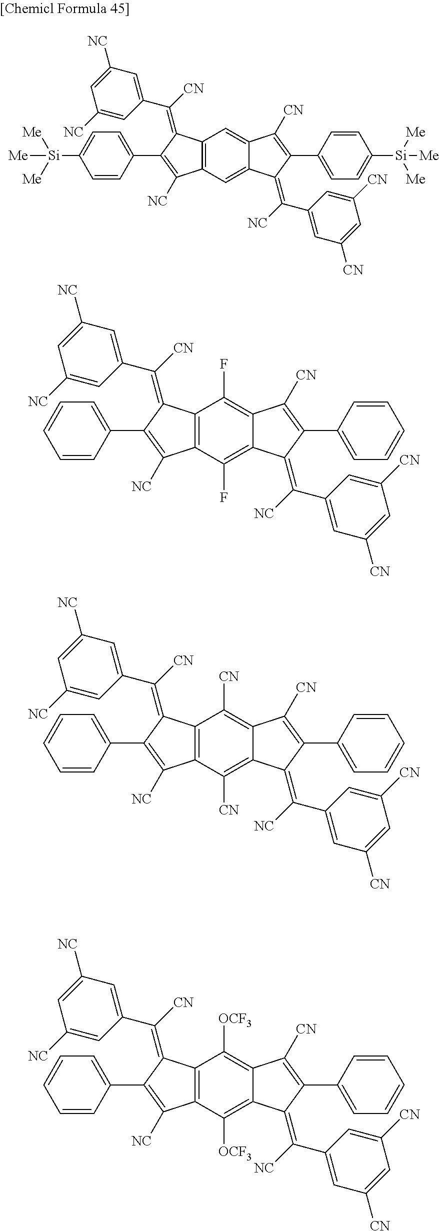

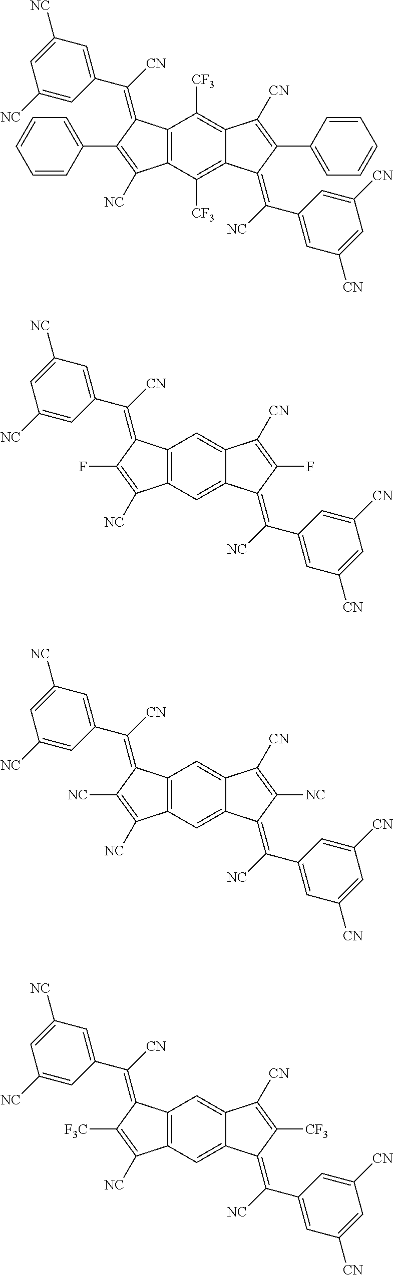

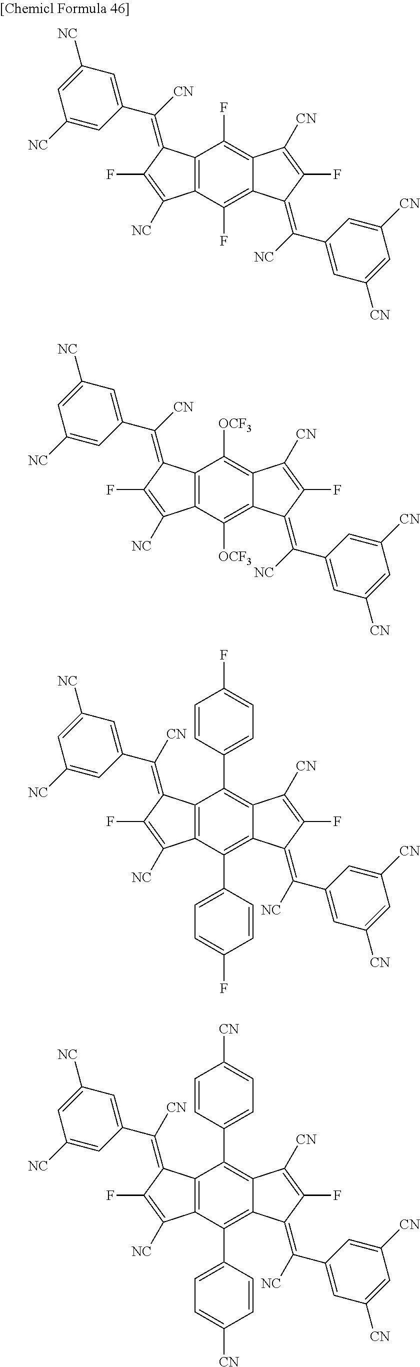

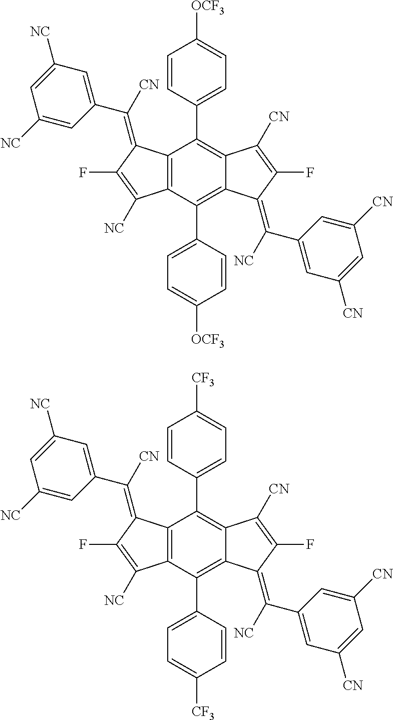

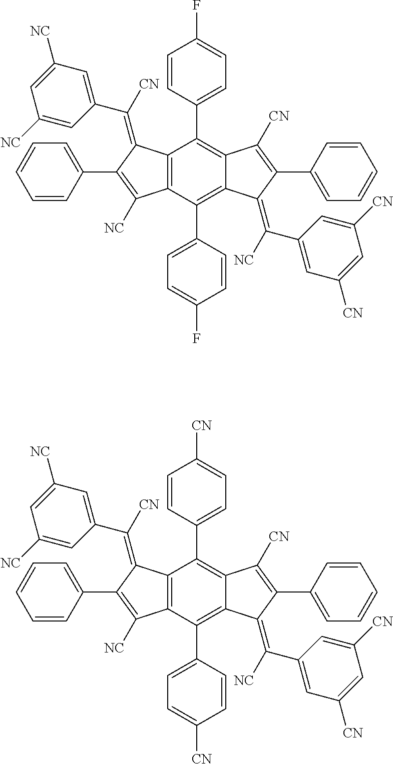

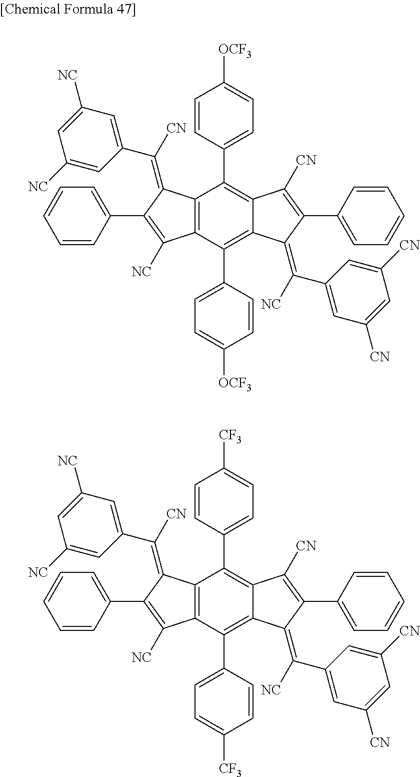

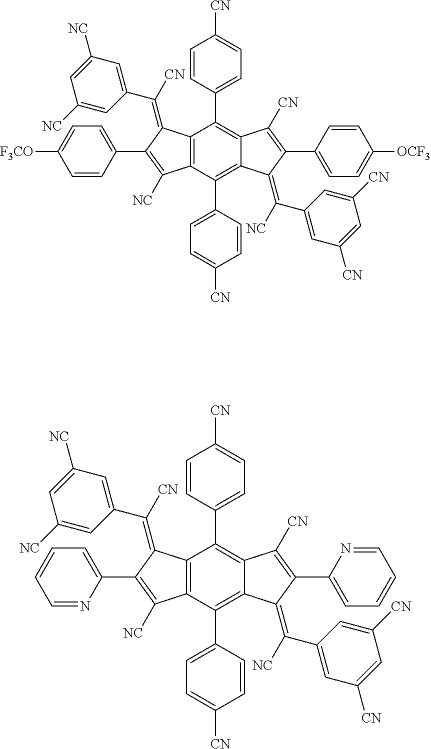

As the p-type dopant, a conventional material may be used in combination with the compound represented by the general formula (2) or the general formula (4). For example, tetrafluoro-7,7,8,8-tetracyanoquinodimethane (F4-TCNQ), a tetracyanoquinodimethane derivative, a radialene derivative, an indacene derivative, a metal borate complex, iodine, FeCl₃, FeF₃, or SbCl₅ can be used.

The p-type charge generation layer host is preferably an arylamine derivative, and a triarylamine derivative having a fluorene skeleton or a carbazole skeleton as a partial structure is particularly preferable. In this case, the benzene ring contained in the fluorene skeleton may also serve as an aryl group in the triarylamine structure. Examples of a preferable p-type charge generation layer host include the following compounds.

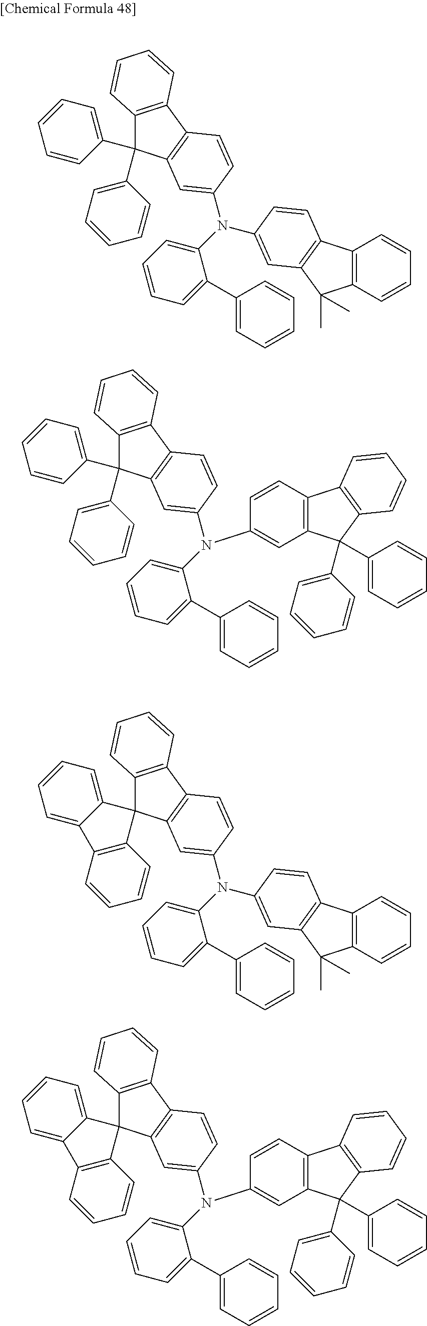 [SMILES: CC1(C)c2ccccc2-c2ccc(N(c3ccc4c(c3)C(c3ccccc3)(c3ccccc3)c3ccccc3-4)c3ccccc3-c3ccccc3)cc21 ; c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1 ; CC1(C)c2ccccc2-c2ccc(N(c3ccc4c(c3)C3(c5ccccc5-c5ccccc53)c3ccccc3-4)c3ccccc3-c3ccccc3)cc21 ; c1ccc(-c2ccccc2N(c2ccc3c(c2)C(c2ccccc2)(c2ccccc2)c2ccccc2-3)c2ccc3c(c2)C2(c4ccccc4-c4ccccc42)c2ccccc2-3)cc1]

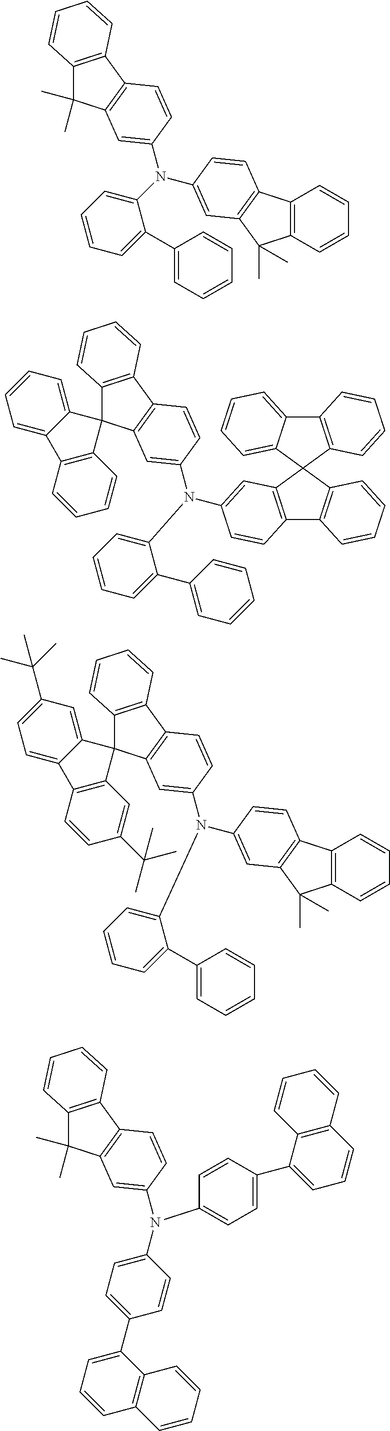 [SMILES: CC1(C)c2ccccc2-c2ccc(N(c3ccc4c(c3)C(C)(C)c3ccccc3-4)c3ccccc3-c3ccccc3)cc21 ; c1ccc(-c2ccccc2N(c2ccc3c(c2)C2(c4ccccc4-c4ccccc42)c2ccccc2-3)c2ccc3c(c2)C2(c4ccccc4-c4ccccc42)c2ccccc2-3)cc1 ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2 ; CC1(C)c2ccccc2-c2ccc(N(c3ccc(-c4cccc5ccccc45)cc3)c3ccc(-c4cccc5ccccc45)cc3)cc21]

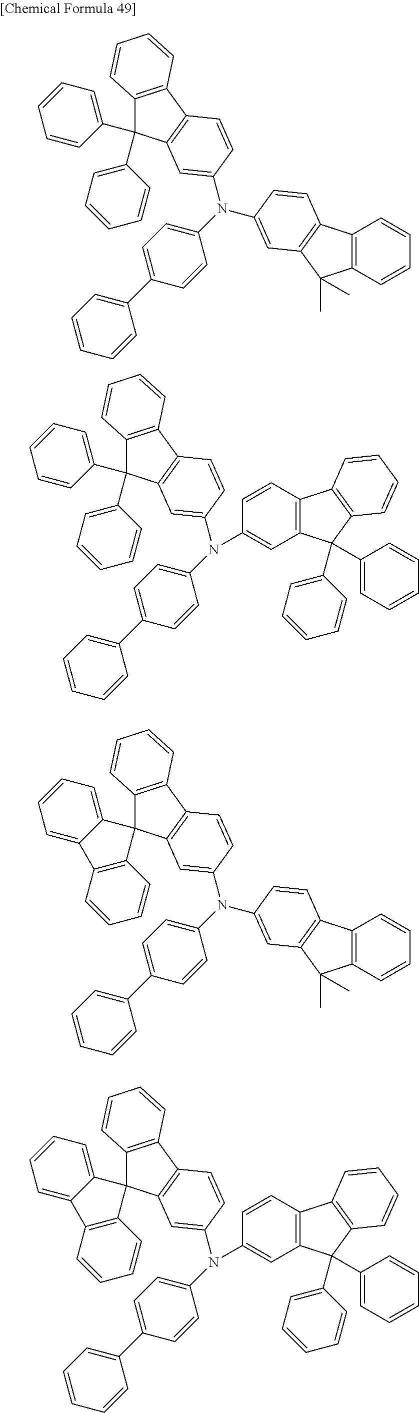

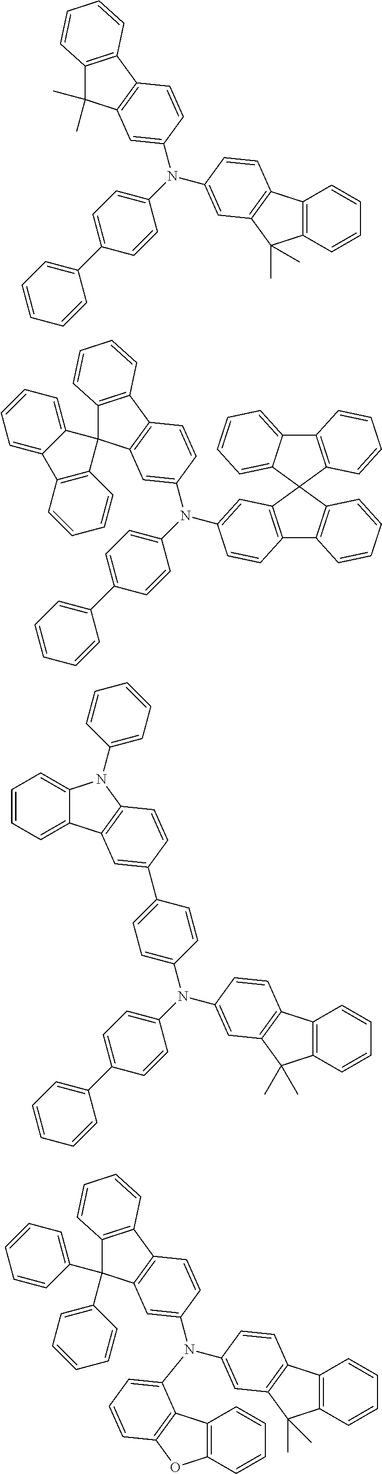

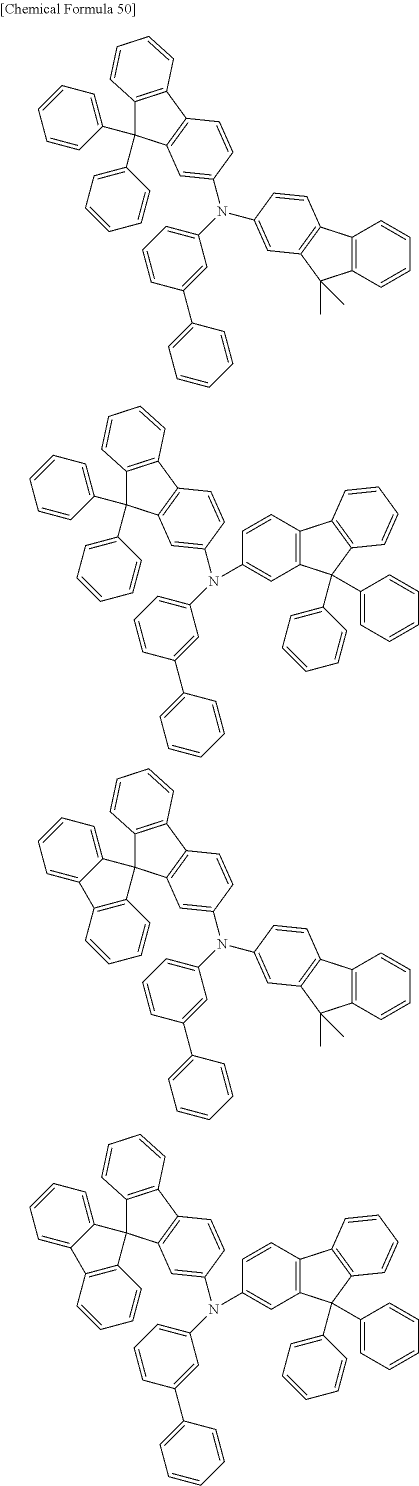

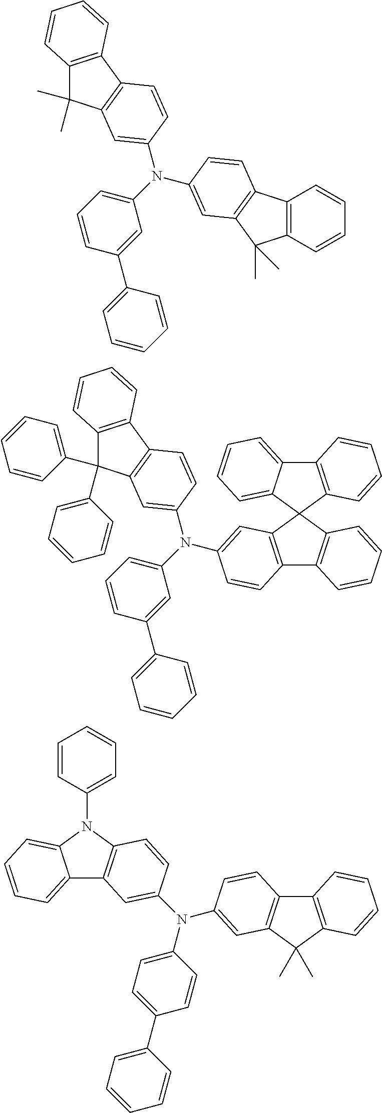

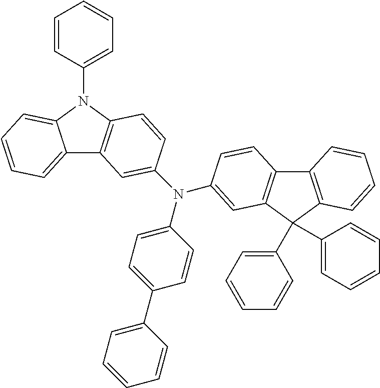 [SMILES: c1ccc(-c2ccc(N(c3ccc4c(c3)C(c3ccccc3)(c3ccccc3)c3ccccc3-4)c3ccc4c(c3)c3ccccc3n4-c3ccccc3)cc2)cc1]

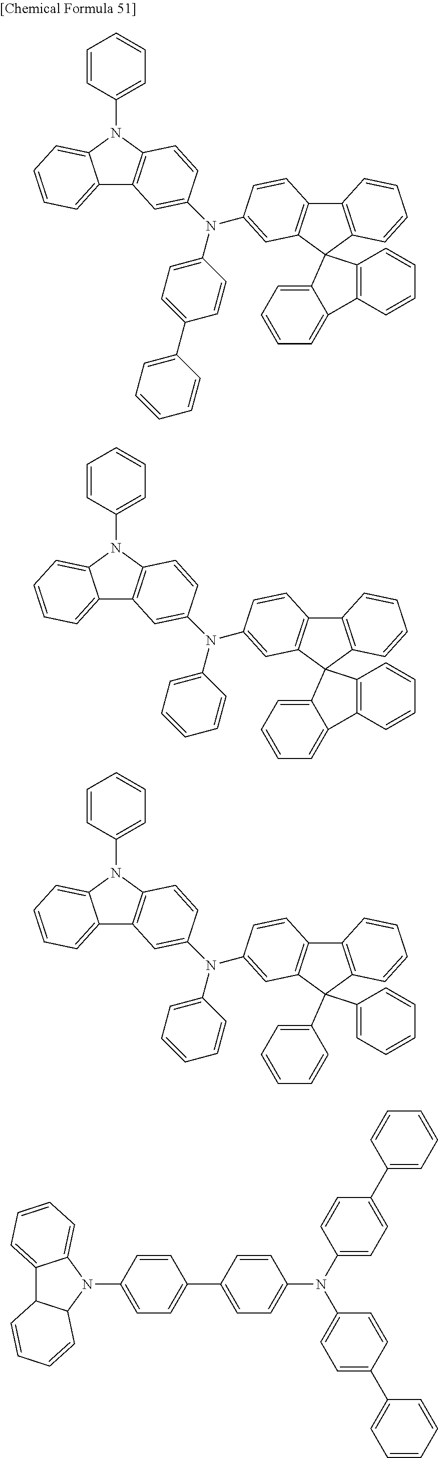 [SMILES: c1ccc(-c2ccc(N(c3ccc4c(c3)C3(c5ccccc5-c5ccccc53)c3ccccc3-4)c3ccc4c(c3)c3ccccc3n4-c3ccccc3)cc2)cc1 ; c1ccc(N(c2ccc3c(c2)C2(c4ccccc4-c4ccccc42)c2ccccc2-3)c2ccc3c(c2)c2ccccc2n3-c2ccccc2)cc1 ; c1ccc(N(c2ccc3c(c2)C(c2ccccc2)(c2ccccc2)c2ccccc2-3)c2ccc3c(c2)c2ccccc2n3-c2ccccc2)cc1 ; C1=CC2c3ccccc3N(c3ccc(-c4ccc(N(c5ccc(-c6ccccc6)cc5)c5ccc(-c6ccccc6)cc5)cc4)cc3)C2C=C1]

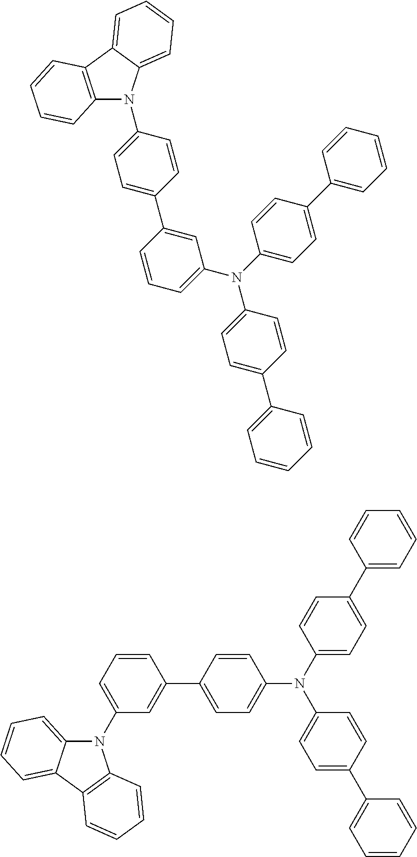 [SMILES: c1ccc(-c2ccc(N(c3ccc(-c4ccccc4)cc3)c3cccc(-c4ccc(-n5c6ccccc6c6ccccc65)cc4)c3)cc2)cc1 ; c1ccc(-c2ccc(N(c3ccc(-c4ccccc4)cc3)c3ccc(-c4cccc(-n5c6ccccc6c6ccccc65)c4)cc3)cc2)cc1]

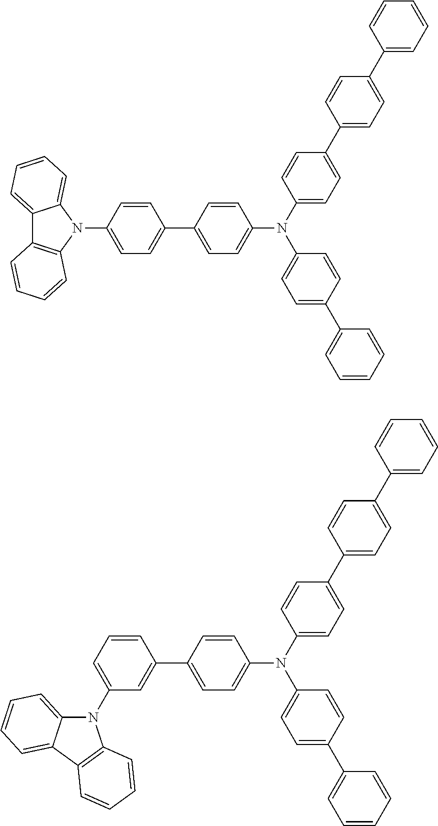 [SMILES: c1ccc(-c2ccc(-c3ccc(N(c4ccc(-c5ccccc5)cc4)c4ccc(-c5ccc(-n6c7ccccc7c7ccccc76)cc5)cc4)cc3)cc2)cc1 ; c1ccc(-c2ccc(-c3ccc(N(c4ccc(-c5ccccc5)cc4)c4ccc(-c5cccc(-n6c7ccccc7c7ccccc76)c5)cc4)cc3)cc2)cc1]

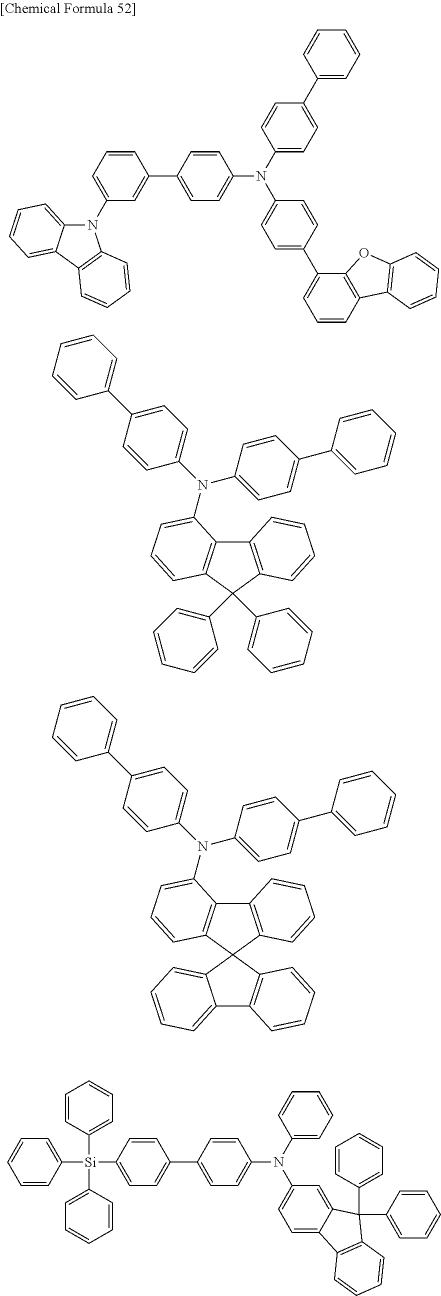

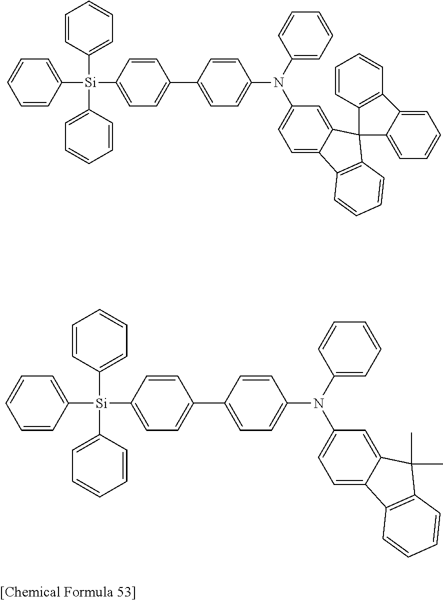 [SMILES: c1ccc(N(c2ccc(-c3ccc([Si](c4ccccc4)(c4ccccc4)c4ccccc4)cc3)cc2)c2ccc3c(c2)C2(c4ccccc4-c4ccccc42)c2ccccc2-3)cc1 ; CC1(C)c2ccccc2-c2ccc(N(c3ccccc3)c3ccc(-c4ccc([Si](c5ccccc5)(c5ccccc5)c5ccccc5)cc4)cc3)cc21]

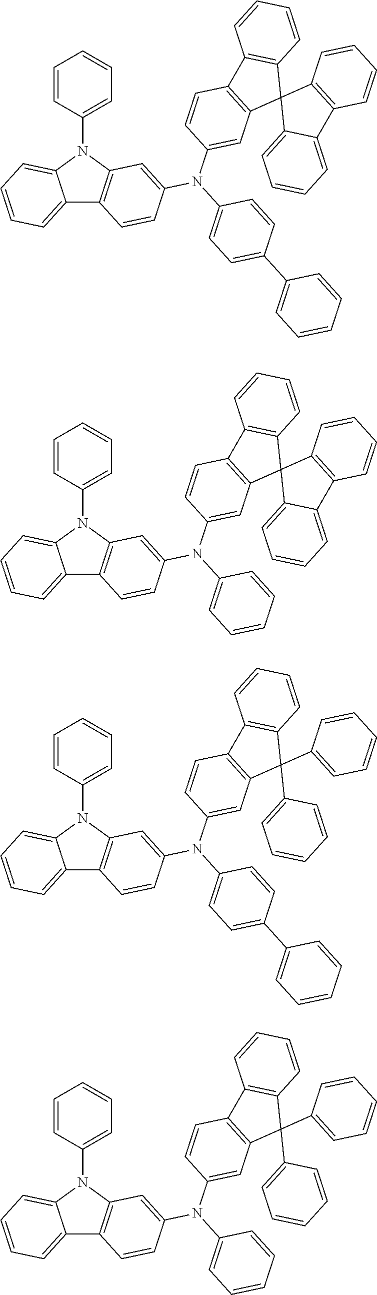

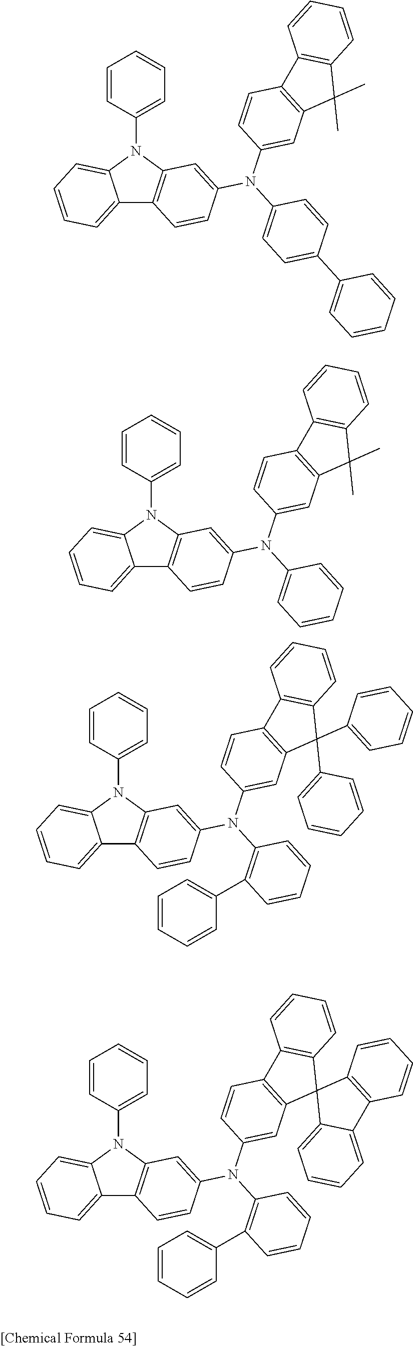

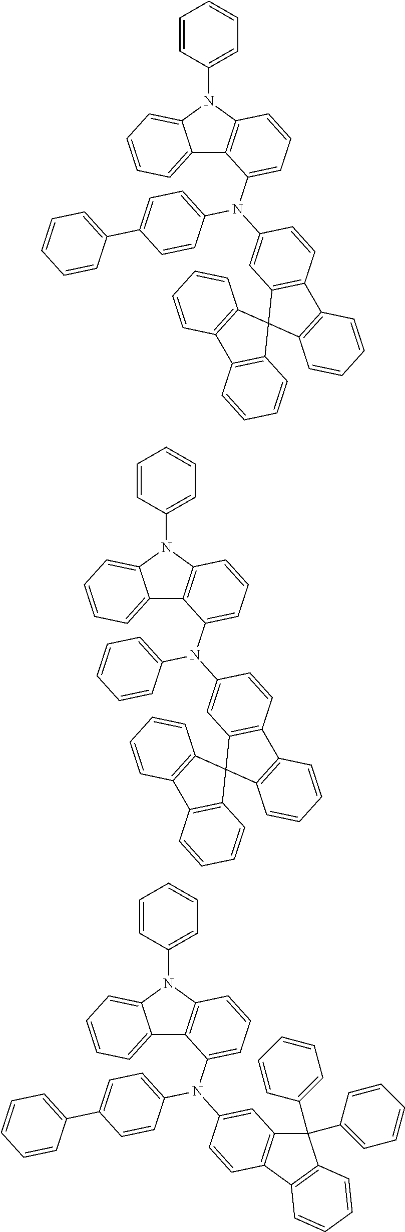

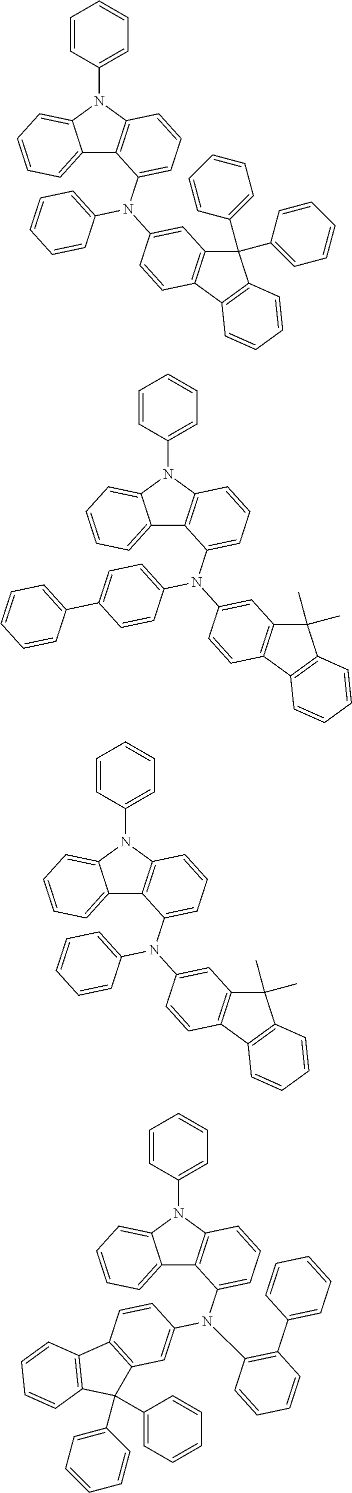 [SMILES: c1ccc(N(c2ccc3c(c2)C(c2ccccc2)(c2ccccc2)c2ccccc2-3)c2cccc3c2c2ccccc2n3-c2ccccc2)cc1 ; CC1(C)c2ccccc2-c2ccc(N(c3ccc(-c4ccccc4)cc3)c3cccc4c3c3ccccc3n4-c3ccccc3)cc21 ; CC1(C)c2ccccc2-c2ccc(N(c3ccccc3)c3cccc4c3c3ccccc3n4-c3ccccc3)cc21 ; c1ccc(-c2ccccc2N(c2ccc3c(c2)C(c2ccccc2)(c2ccccc2)c2ccccc2-3)c2cccc3c2c2ccccc2n3-c2ccccc2)cc1]

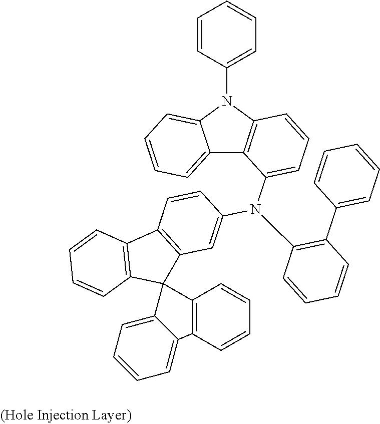 [SMILES: c1ccc(-c2ccccc2N(c2ccc3c(c2)C2(c4ccccc4-c4ccccc42)c2ccccc2-3)c2cccc3c2c2ccccc2n3-c2ccccc2)cc1]

The hole injection layer is a layer to be interposed between the anode and the hole transporting layer. The hole injection layer may be a single layer or may include a plurality of layers that are laminated. The fact that the hole injection layer is present between the hole transporting layer and the anode is preferable because owing to this fact, not only the driving voltage is further reduced and the durable life is improved, but also the carrier balance of the element is improved to improve the luminous efficiency.

As the material to be used for the hole injection layer, a publicly known material can be used. Examples of such a material include benzidine derivatives, materials called starburst arylamines, triarylamine derivatives, heterocyclic compounds such as biscarbazole derivatives, pyrazoline derivatives, stilbene-based compounds, fluorene-based compounds, hydrazone-based compounds, benzofuran derivatives, thiophene derivatives, oxadiazole derivatives, phthalocyanine derivatives, and porphyrin derivatives, and polymer-based materials such as polycarbonates and styrene derivatives having the above-described monomer in a side chain, polythiophene, polyaniline, polyfluorene, polyvinylcarbazole, and polysilane. Benzidine derivatives, starburst arylamine-based materials, and fluorene-based compounds are more preferably used from the viewpoint of smoothly injecting and transporting holes from the anode to the hole transporting layer.

These materials may be used alone, or two or more materials may be mixed and used. A plurality of materials may be stacked to form a hole injection layer. Furthermore, it is more preferable that the hole injection layer is formed of an acceptor compound alone or a hole injection material as described above is doped with an acceptor compound and then used because the above-described effects can be obtained more remarkably. The acceptor compound is a material that forms a charge transfer complex together with a hole transporting layer in contact therewith when the acceptor compound is used as a single layer film, or together with a material forming a hole injection layer when the acceptor compound is used as a dopant. Use of such a material leads to improvement in the electroconductivity of the hole injection layer, further contributes to reduction in the driving voltage of the element, and can further improve the luminous efficiency and the durable life.

Examples of the acceptor compound include a radialene derivative, an indacene derivative, a metal borate complex, a metal chloride such as iron(III) chloride, aluminum chloride, gallium chloride, indium chloride, or antimony chloride, a metal oxide such as molybdenum oxide, vanadium oxide, tungsten oxide, or ruthenium oxide, a charge transfer complex such as tris(4-bromophenyl)aminium hexachloroantimonate (TBPAH), an organic compound having a nitro group, a cyano group, a halogen, or a trifluoromethyl group in the molecule, a quinone-based compound, an acid anhydride-based compound, and fullerene. Among these compounds, metal oxides and cyano group-containing compounds are preferable because metal oxides and cyano group-containing compounds are easily handled and vapor-deposited, and therefore the above-described effects are easily obtained. In either of the case in which the hole injection layer is formed of an acceptor compound alone or the case in which the hole injection layer is doped with an acceptor compound, the hole injection layer may be a single layer or may include a plurality of layers that are laminated.

The acceptor compound with which the hole injection layer it to be doped is preferably a compound represented by the general formula (2) or the general formula (4).

### (Hole Transporting Layer)

The hole transporting layer is a layer that transports holes injected from the anode to the emissive layer. The hole transporting layer may be a single layer or may include a plurality of layers that are laminated.

Examples of the material to be used for the hole transporting layer include those enumerated as examples of the materials to be used for the hole injection layer or the p-type charge generation layer host in the p-type charge generation layer. From the viewpoint of smoothly injecting and transporting holes into the emissive layer, triarylamine derivatives and benzidine derivatives are preferable. It is particularly preferable that the hole transporting layer contains a triarylamine derivative having a fluorene skeleton or a carbazole skeleton as a partial structure.

Examples of a preferable hole transporting material include those previously enumerated as examples of the p-type charge generation layer host in the p-type charge generation layer.

### (Emissive Layer)

The emissive layer may be a single layer or may include a plurality of layers. Each emissive layer is formed of a light-emitting material (a host material and a dopant material), which may be a mixture of a host material and a dopant material, or a host material alone, or a mixture of two host materials and a single dopant material. That is, in the organic EL element in an embodiment of the present invention, in each emissive layer, only a host material or a dopant material may emit light, or both a host material and a dopant material may emit light. From the viewpoint of efficiently utilizing the electrical energy and obtaining light emission of high color purity, the emissive layer is preferably made from a mixture of a host material and a dopant material. Further, each of the host material and the dopant material may be of one type or a combination of multiple types. The dopant material may be contained in the entire host material or may be partially contained therein. The dopant material may be either laminated or dispersed. The dopant material can control an emitted color. From the viewpoint of controlling a concentration quenching phenomenon, the amount of the dopant material is preferably 30% by weight or less, and more preferably 20% by weight or less based on the host material. In a doping process, the dopant material can be applied by a method of co-deposition with a host material. Alternatively, the dopant material may be preliminarily mixed a host material and vapor-deposited simultaneously with the host material.

When the emissive layer includes a plurality of layers, a configuration in which the first emissive layer contains a host material different from that contained in the second emissive layer, and the first emissive layer and the second emissive layer are in direct contact with each other is also preferable. In particular, in an emissive layer using a fluorescent material, by laminating two emissive layers, a region in which charge recombination occurs and a region in which triplet-triplet fusion occurs can be separated, so that luminous efficiency can be enhanced.

Examples of the light-emitting material include fused ring derivatives such as anthracene and pyrene, which are known as luminous bodies, metal chelated oxinoid compounds such as tris(8-quinolinolate)aluminum, bisstyryl derivatives such as bisstyrylanthracene derivatives and distyrylbenzene derivatives, tetraphenyl butadiene derivatives, indene derivatives, coumarin derivatives, oxadiazole derivatives, pyrrolopyridine derivatives, perinone derivatives, cyclopentadiene derivatives, oxadiazole derivatives, thiadiazolopyridine derivatives, dibenzofuran derivatives, carbazole derivatives, indolocarbazole derivatives, and polymers such as polyphenylenevinylene derivatives, polyparaphenylene derivatives, and polythiophene derivatives.

The host material contained in the light-emitting material is not limited to only one compound, and a mixture of multiple compounds may be used. Alternatively, the host materials may be laminated and used. The host material is not particularly limited, and examples thereof include compounds having a fused aryl ring such as naphthalene, anthracene, phenanthrene, pyrene, chrysene, naphthacene, triphenylene, perylene, fluoranthene, fluorene, and indene, and derivatives thereof, aromatic amine derivatives such as N,N′-dinaphthyl-N,N′-diphenyl-4,4′-diphenyl-1,1′-diamine, metal chelated oxinoid compounds such as tris(8-quinolinato)aluminum(III), bisstyryl derivatives such as distyrylbenzene derivatives, tetraphenylbutadiene derivatives, indene derivatives, coumarin derivatives, oxadiazole derivatives, pyrrolopyridine derivatives, perinone derivatives, cyclopentadiene derivatives, pyrrolopyrrole derivatives, thiadiazolopyridine derivatives, dibenzofuran derivatives, carbazole derivatives, indolocarbazole derivatives and triazine derivatives, and polymers such as polyphenylenevinylene derivatives, polyparaphenylene derivatives, polyfluorene derivatives, polyvinylcarbazole derivatives, and polythiophene derivatives. Among them, as a host to be used when the emissive layer performs triplet emission (phosphorescent emission), metal chelated oxynoid compounds, dibenzofuran derivatives, dibenzothiophene derivatives, carbazole derivatives, indolocarbazole derivatives, triazine derivatives, triphenylene derivatives, etc. are suitably used.

Examples of the dopant material contained in the light-emitting material include compounds having an aryl ring such as naphthalene, anthracene, phenanthrene, pyrene, fluoranthene, triphenylene, perylene, fluorene and indene, and derivatives thereof (e.g., 2-(benzothiazol-2-yl)-9,10-diphenylanthracene and 5,6,11,12-tetraphenylnaphthacene); compounds having a heteroaryl ring such as furan, pyrrole, thiophene, silole, 9-silafluorene, 9,9′-spirobisilafluorene, benzothiophene, benzofuran, indole, dibenzothiophene, dibenzofuran, imidazopyridine, phenanthroline, pyrazine, naphthyridine, quinoxaline, pyrrolopyridine and thioxanthene, and derivatives thereof; distyrylbenzene derivatives; aminostyryl derivatives such as 4,4′-bis(2-(4-diphenylaminophenyl)ethenyl)biphenyl and 4,4′-bis(N-(stilben-4-yl)-N-phenylamino)stilbene; aromatic acetylene derivatives; tetraphenylbutadiene derivatives; stilbene derivatives; aldazine derivatives; pyrromethene derivatives; diketopyrrolo[3,4-c]pyrrole derivatives; coumarin derivatives such as 2,3,5,6-1H,4H-tetrahydro-9-(2′-benzothiazolyl)quinolizino[9,9a,1-gh]coumarin; azole derivatives such as imidazole, thiazole, thiadiazole, carbazole, oxazole, oxadiazole and triazole, metal complexes thereof; aromatic amine derivatives such as N,N′-diphenyl-N,N′-di(3-methylphenyl)-4,4′-diphenyl-1,1′-diamine; and compounds represented by the following general formula (6). Among them, dopants containing a diamine skeleton and dopants containing a fluoranthene skeleton can further improve the luminous efficiency, and the compounds represented by the following general formula (6) can further improve the luminous efficiency and the durable life.

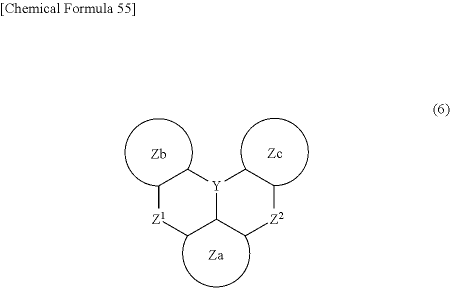

In the general formula (6), ring Za, ring Zb, and ring Zc are each independently a substituted or unsubstituted aryl ring having 6 to 30 ring-forming carbon atoms, or a substituted or unsubstituted heteroaryl ring having 5 to 30 ring-forming atoms. It is preferable that the ring Za, the ring Zb, and the ring Zc are each independently a substituted or unsubstituted aryl ring having 6 to 30 ring-forming carbon atoms. Z¹ and Z² are each independently an oxygen atom, NRa (a nitrogen atom having a substituent Ra), or a sulfur atom, provided that when Z¹ is NRa, Z¹ may or may not be bonded to ring Za or ring Zb and form a ring, and when Z² is NRa, Z² may or may not be bonded to ring Zb or ring Zc and form a ring; Ra is independently at each occurrence a substituted or unsubstituted aryl group having 6 to 30 ring-forming carbon atoms, a substituted or unsubstituted heteroaryl group having 5 to 30 ring-forming atoms, or a substituted or unsubstituted alkyl group having 1 to 30 carbon atoms; It is preferable that Z¹ and Z² are both NRa, and Ra is a substituted or unsubstituted aryl group having 6 to 30 ring-forming carbon atoms. Y is a boron atom, a phosphorus atom, SiRb (a silicon atom having substituent Rb), P═O, or P═S; Rb is independently at each occurrence a substituted or unsubstituted aryl group having 6 to 30 ring-forming carbon atoms, a substituted or unsubstituted heteroaryl group having 5 to 30 ring-forming atoms, or a substituted or unsubstituted alkyl group having 1 to 30 carbon atoms. Y is preferably a boron atom. In all the groups described above, when a group is substituted, the substituent is preferably an alkyl group, a cycloalkyl group, a heterocyclic group, an alkenyl group, a cycloalkenyl group, an alkynyl group, an aryl group, a heteroaryl group, a hydroxyl group, a thiol group, an alkoxy group, an alkylthio group, an aryl ether group, an aryl thioether group, a halogen, a cyano group, a formyl group, an acyl group, a carboxyl group, an ester group, an amide group, a sulfonyl group, a sulfonate ester group, a sulfonamide group, an amino group, a nitro group, a silyl group, a siloxanyl group, a boryl group, or an oxo group. These substituents may be further substituted with the substituents described above.

Examples of the alkyl group and the alkoxy group include those enumerated as examples of the substituent in the general formula (1).

The cycloalkyl group denotes a saturated alicyclic hydrocarbon group, such as a cyclopropyl group, a cyclohexyl group, a norbornyl group, or an adamantyl group, and the cycloalkyl group may or may not have a substituent. There is no particular limitation on the number of ring-forming carbon atoms, and the number of ring-forming carbon atoms is preferably in the range of 3 or more and 20 or less.

The heterocyclic group denotes an aliphatic ring having an atom other than carbon in the ring, such as a pyran ring, a piperidine ring, or a cyclic amide, and the heterocyclic group may or may not have a substituent. There is no particular limitation on the number of ring-forming atoms, and the number of ring-forming atoms is preferably in the range of 3 or more and 20 or less.

The alkenyl group denotes an unsaturated aliphatic hydrocarbon group including a double bond, such as a vinyl group, an allyl group, or a butadienyl group, and the alkenyl group may or may not have a substituent. The number of carbon atoms in the alkenyl group is not particularly limited, and is preferably in the range of 2 or more and 20 or less.

The cycloalkenyl group denotes an unsaturated alicyclic hydrocarbon group including a double bond, such as a cyclopentenyl group, a cyclopentadienyl group, or a cyclohexenyl group, and the cycloalkenyl group may or may not have a substituent.

The alkynyl group denotes an unsaturated aliphatic hydrocarbon group including a triple bond, such as an ethynyl group, and the alkynyl group may or may not have a substituent. The number of carbon atoms in the alkynyl group is not particularly limited, and is preferably in the range of 2 or more and 20 or less.

The aryl group denotes an aromatic hydrocarbon group, such as a phenyl group, a biphenyl group, a terphenyl group, a naphthyl group, a fluorenyl group, a benzofluorenyl group, a dibenzofluorenyl group, a phenanthryl group, an anthracenyl group, a benzophenanthryl group, a benzoanthracenyl group, a chrysenyl group, a pyrenyl group, a fluoranthenyl group, a triphenylenyl group, a benzofluoranthenyl group, a dibenzoanthracenyl group, a perylenyl group, or a helicenyl group. Among these groups, a phenyl group, a biphenyl group, a terphenyl group, a naphthyl group, a fluorenyl group, a phenanthryl group, an anthracenyl group, a pyrenyl group, a fluoranthenyl group, and a triphenylenyl group are preferable. The aryl group may or may not have a substituent. The number of carbon atoms in the aryl group is not particularly limited, and is preferably in the range of 6 or more and 40 or less, and more preferably 6 or more and 30 or less.

In a substituted phenyl group, when the phenyl group has substituents on two adjacent carbon atoms of the phenyl group, the substituents may form a ring structure together. The resulting group may correspond to any one or more of a “substituted phenyl group”, an “aryl group having a structure in which two or more rings are fused”, and a “heteroaryl group having a structure in which two or more rings are fused” depending on the structure.

Examples of the heteroaryl group include those enumerated as examples of the substituent in the general formula (3).

The term “alkylthio group” refers to a group in which the oxygen atom of the ether bond of an alkoxy group is substituted by a sulfur atom. The alkylthio group may or may not have a substituent. The number of carbon atoms in the alkylthio group is not particularly limited, and is preferably in the range of 1 or more and 20 or less.

The aryl ether group denotes a functional group having an aromatic hydrocarbon group bonded via an ether bond, such as a phenoxy group, and the aryl ether group may have a substituent or no substituent. The number of carbon atoms in the aryl ether group is not particularly limited, and is preferably in the range of 6 or more and 40 or less.

The term “aryl thioether group” refers to a functional group in which an oxygen atom in an ether linkage in an aryl ether group is replaced by a sulfur atom, and may or may not have a substituent. The number of carbon atoms in the aryl thioether group is not particularly limited, and is preferably in the range of 6 or more and 40 or less.

The halogen refers to fluorine, chlorine, bromine, or iodine.

The acyl group denotes a functional group having an alkyl group, a cycloalkyl group, an alkenyl group, an alkynyl group, an aryl group, or a heteroaryl group bonded via a carbonyl group, such as an acetyl group, a propionyl group, a benzoyl group, or an acrylyl group, and the acyl group may or may not have a substituent. The number of carbon atoms in the acyl group is not particularly limited, and is preferably 2 or more and 40 or less, and more preferably 2 or more and 30 or less.

The ester group denotes a functional group having, for example, an alkyl group, a cycloalkyl group, an aryl group, or a heteroaryl group bonded thereto via an ester linkage, and the ester group may or may not have a substituent. The number of carbon atoms in the ester group is not particularly limited, and is preferably in the range of 1 or more and 20 or less. More specific examples include a methyl ester group such as a methoxycarbonyl group, an ethyl ester group such as an ethoxycarbonyl group, a propyl ester group such as a propoxycarbonyl group, a butyl ester group such as a butoxycarbonyl group, an isopropyl ester group such as an isopropoxymethoxycarbonyl group, a hexyl ester group such as a hexyloxycarbonyl group, and a phenyl ester group such as a phenoxycarbonyl group.

The amide group denotes a functional group having, for example, an alkyl group, a cycloalkyl group, an aryl group, or a heteroaryl group bonded thereto via an amide linkage, and the amide group may or may not have a substituent. The number of carbon atoms in the amide group is not particularly limited, and is preferably in the range of 1 or more and 20 or less. More specific examples include a methylamide group, an ethylamide group, a propylamide group, a butyramide group, an isopropylamide group, a hexylamide group, and a phenylamide group.

The sulfonyl group denotes a functional group having, for example, an alkyl group, a cycloalkyl group, an aryl group, or a heteroaryl group bonded thereto via a —S(═O)₂-linkage, and the sulfonyl group may or may not have a substituent. The number of carbon atoms in the sulfonyl group is not particularly limited, and is preferably in the range of 1 or more and 20 or less.

The sulfonate ester group denotes a functional group having, for example, an alkyl group, a cycloalkyl group, an aryl group, or a heteroaryl group bonded thereto via a sulfonate ester linkage, and the sulfonate ester group may or may not have a substituent. Here, the term “sulfonate ester linkage” refers to a linkage in which a carbonyl moiety in an ester linkage, namely, —C(═O)— is replaced by a sulfonyl moiety, namely, —S(═O)₂—. The number of carbon atoms in the sulfonate ester group is not particularly limited, and is preferably in the range of 1 or more and 20 or less.

The sulfonamide group denotes a functional group having, for example, an alkyl group, a cycloalkyl group, an aryl group, or a heteroaryl group bonded thereto via a sulfonamide linkage, and the sulfonamide group may or may not have a substituent. Here, the sulfonamide linkage refers to a linkage in which a carbonyl moiety in an ester linkage, namely, —C(═O)— is replaced by a sulfonyl moiety, namely, —S(═O)₂—. The number of carbon atoms in the sulfonamide group is not particularly limited, and is preferably in the range of 1 or more and 20 or less.

The amino group may or may not have a substituent. The number of carbon atoms in the amino group is not particularly limited, and is preferably in the range of 2 or more and 50 or less, more preferably 6 or more and 40 or less, and particularly preferably 6 or more and 30 or less.

The silyl group denotes a functional group having a substituted or unsubstituted silicon atom bonded, and denotes, for example, an alkylsilyl group such as a trimethylsilyl group, a triethylsilyl group, a tert-butyldimethylsilyl group, a propyldimethylsilyl group, or a vinyldimethylsilyl group, or an arylsilyl group such as a phenyldimethylsilyl group, a tert-butyldiphenylsilyl group, a triphenylsilyl group, or a trinaphthylsilyl group. The silyl group may or may not have a substituent. The number of carbon atoms in the silyl group is not particularly limited, and is preferably in the range of 1 or more and 30 or less.

The term “siloxanyl group” refers to a silicon compound group that is bonded via an ether linkage, such as a trimethylsiloxanyl group. The siloxanyl group may or may not have a substituent.

The boryl group may or may not have a substituent.

Examples of the compound represented by the general formula (6) include the following compounds.

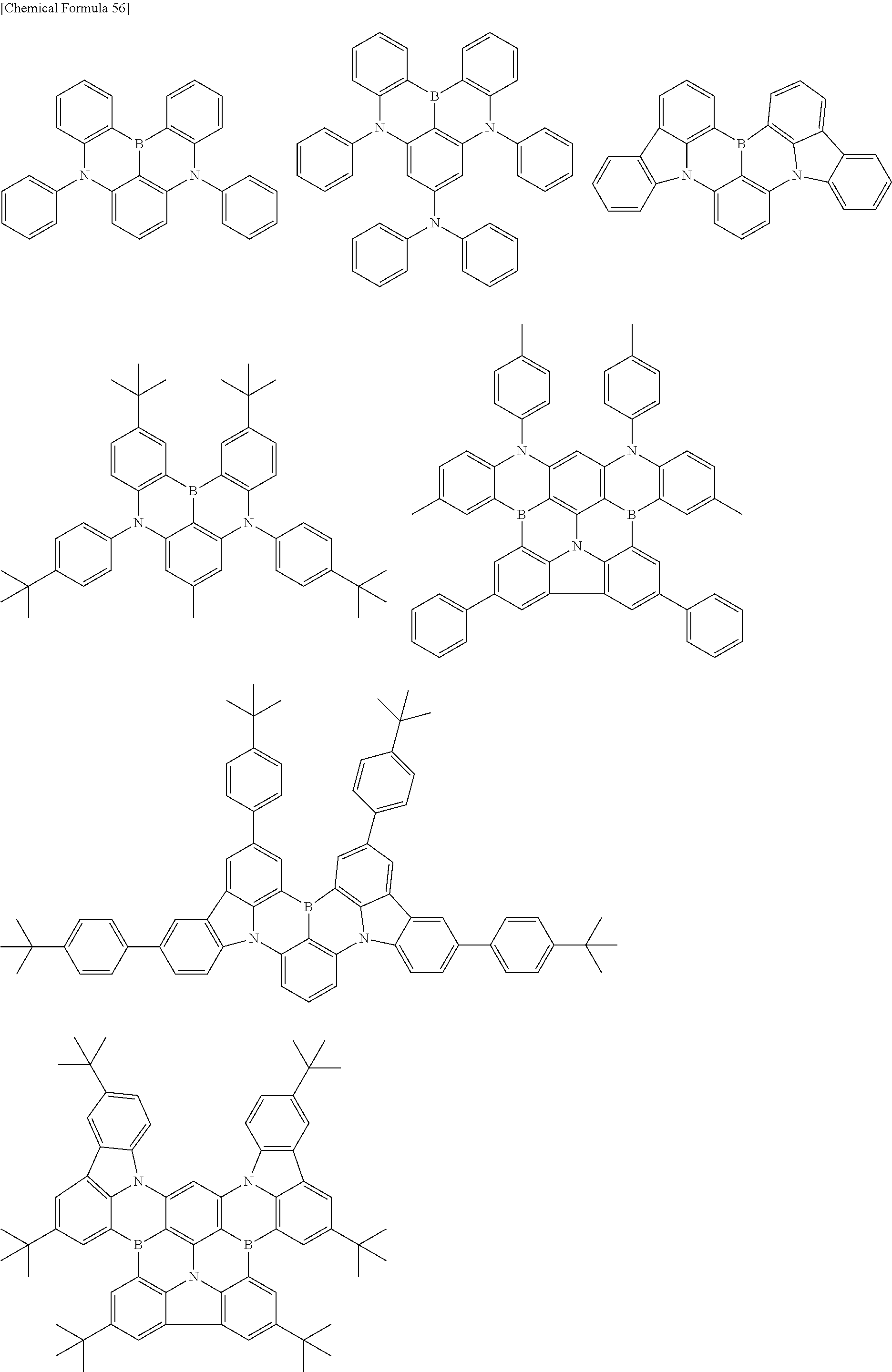

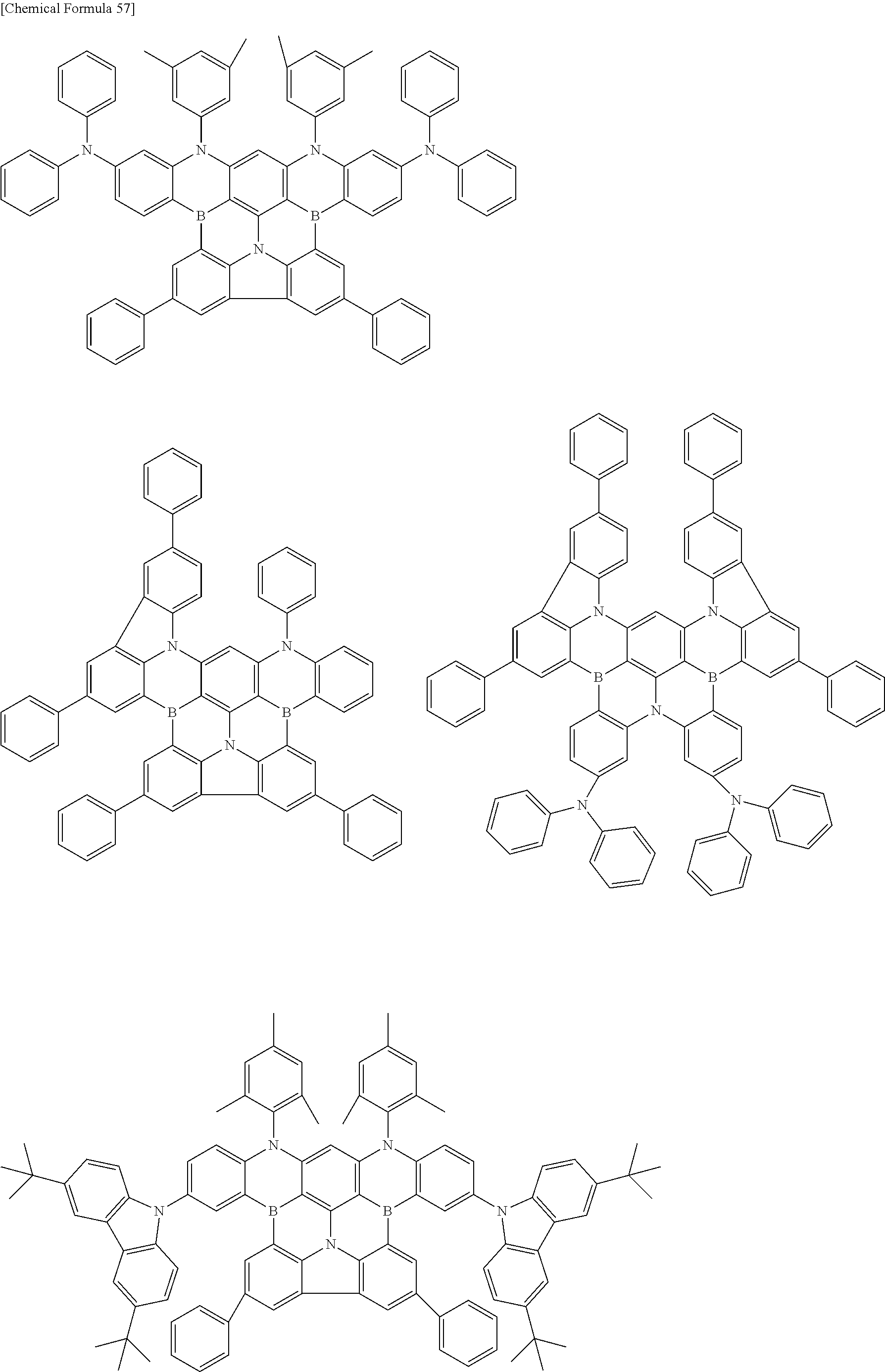

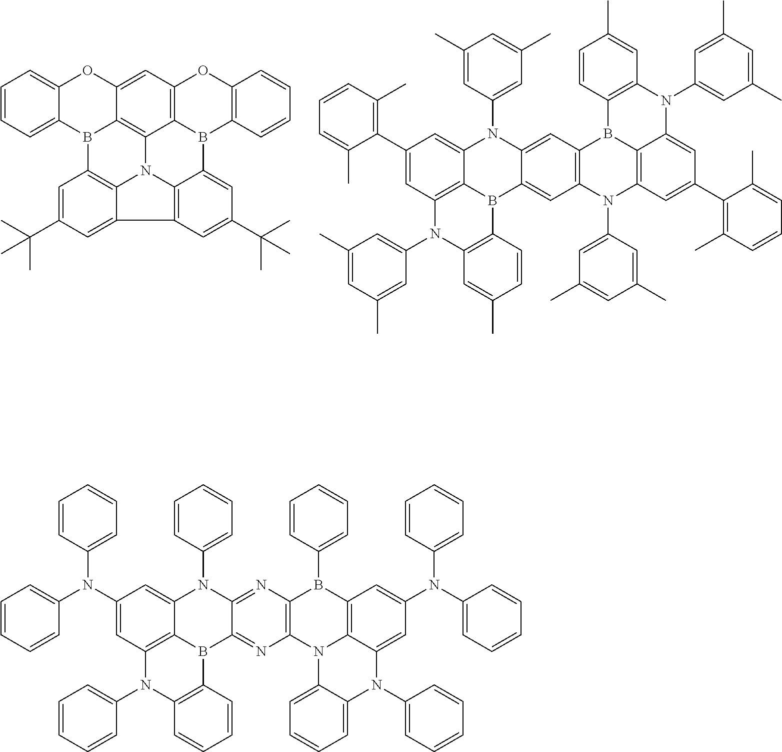

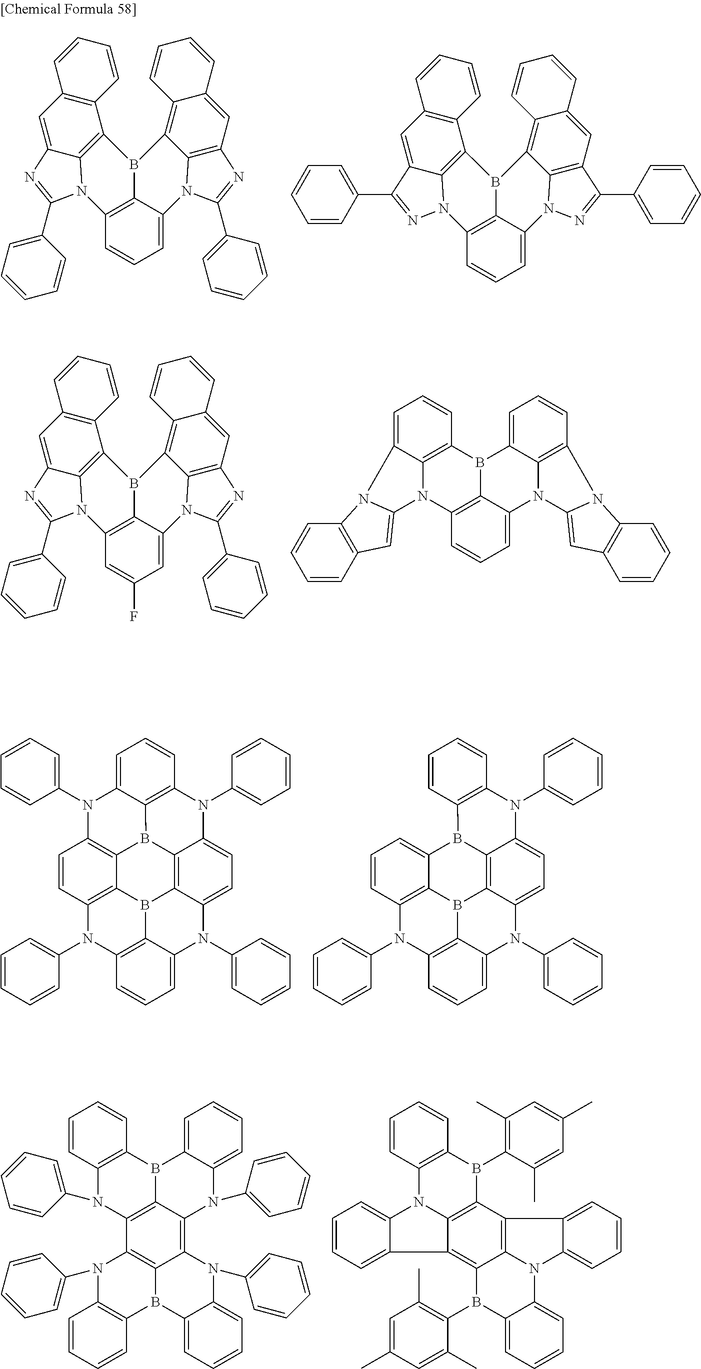

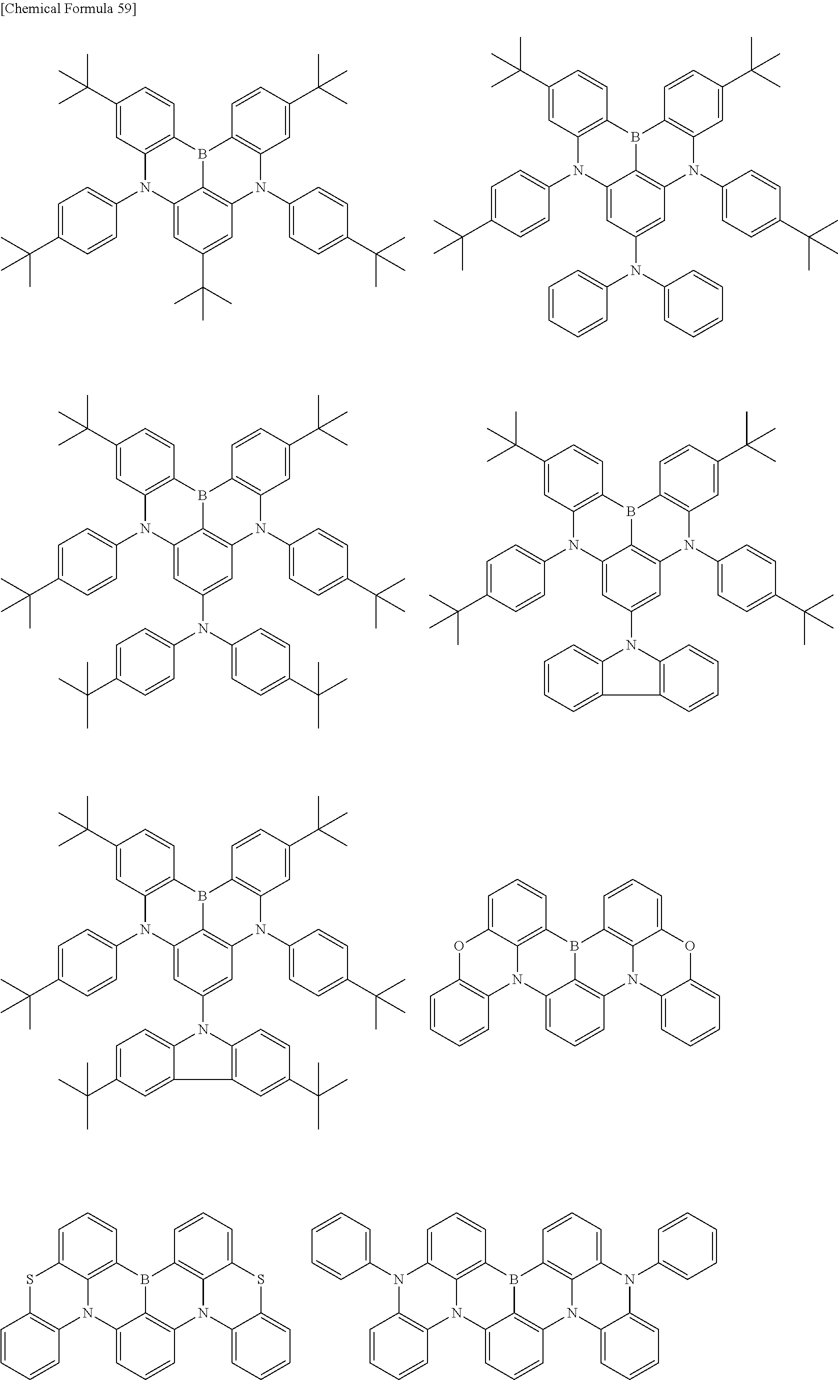

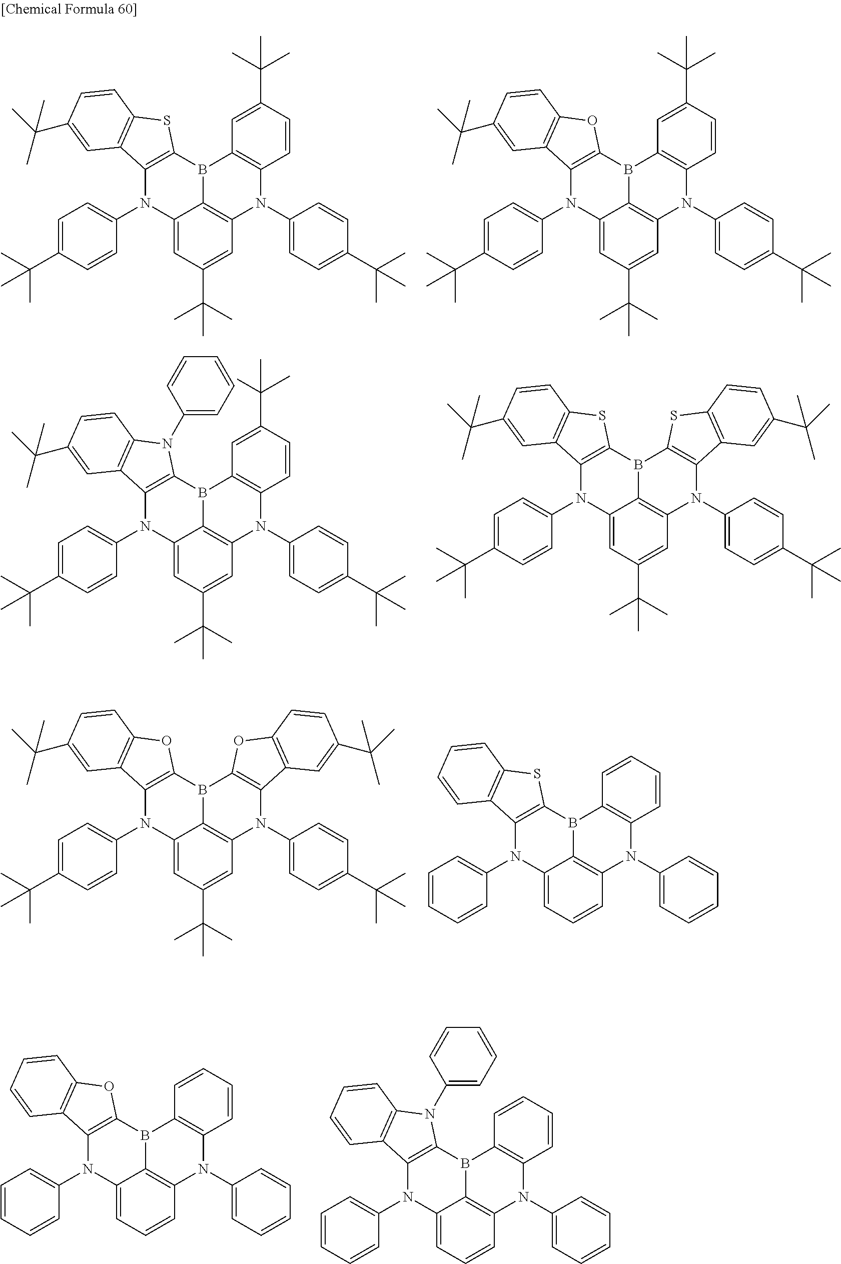

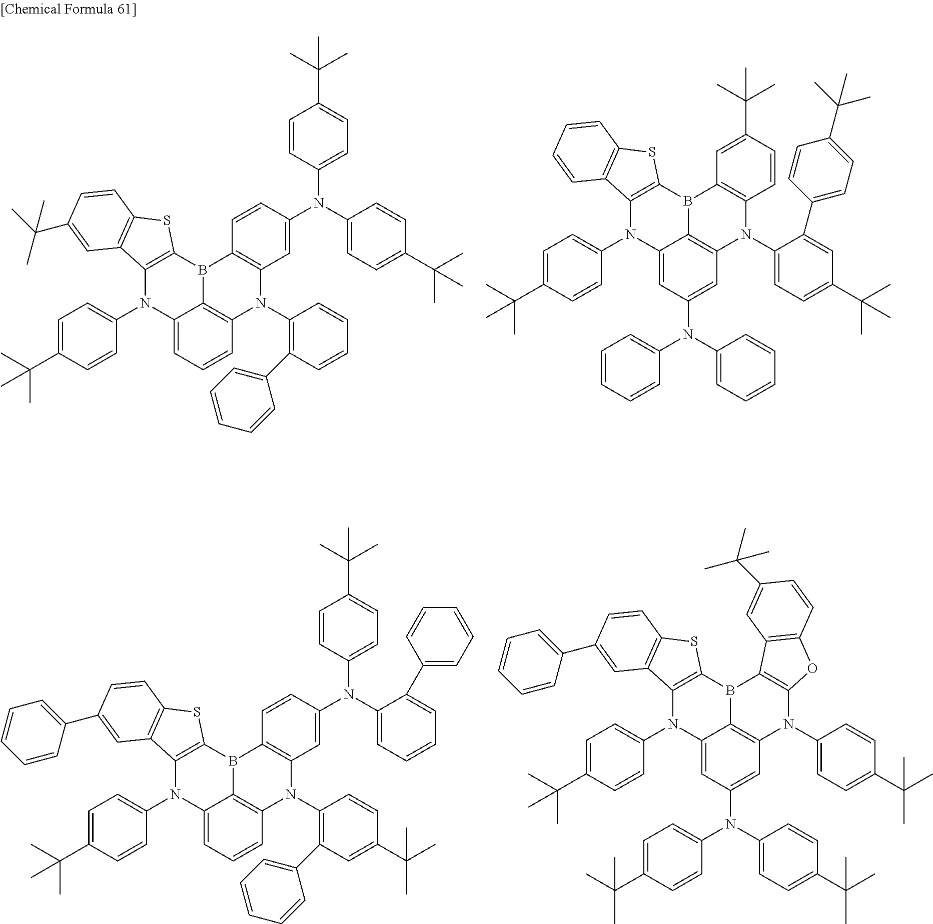

In the organic EL element according to an embodiment of the present invention, it is also preferable that the emissive layer contains a triplet light-emitting material.

The dopant to be used when the emissive layer performs triplet emission (phosphorescent emission) is preferably a metal complex compound containing at least one metal selected from the group consisting of iridium (Ir), ruthenium (Ru), palladium (Pd), platinum (Pt), osmium (Os), and rhenium (Re). The ligand preferably has a nitrogen-containing aromatic heterocyclic ring such as a phenylpyridine skeleton, a phenylquinoline skeleton, or a carbene skeleton. However, the complex is not limited thereto, and an appropriate complex is selected considering the required emission color, element performance, and relationship with the host compound. Examples of such a complex specifically include tris-(2-phenylpyridyl) iridium complex, tris-{2-(2-thiophenyl)pyridyl}iridium complex, tris-{2-(2-benzothiophenyl)pyridyl}iridium complex, tris-(2-phenylbenzothiazole) iridium complex, tris-(2-phenylbenzooxazole) iridium complex, tris-benzoquinoline iridium complex, bis(2-phenylpyridyl) (acetylacetonato) iridium complex, bis{2-(2-thiophenyl)pyridyl}iridium complex, bis{2-(2-benzothiophenyl)pyridyl}(acetylacetonato) iridium complex, bis(2-phenylbenzothiazole) (acetylacetonato) iridium complex, bis(2-phenylbenzooxazole) (acetylacetonato) iridium complex, bisbenzoquinoline (acetylacetonato) iridium complex, bis{2-(2,4-difluorophenyl)pyridyl}(acetylacetonato) iridium complex, tetraethylporphyrin platinum complex, {tris-(thenoyltrifluoroacetone) mono(1,10-phenanthroline)}europium complex, {tris-(thenoyltrifluoroacetone) mono(4,7-diphenyl-1,10-phenanthroline)}europium complex, {tris-(1,3-diphenyl-1,3-propanedione) mono(1,10-phenanthroline)}europium complex, and tris-acetylacetone terbium complex. The phosphorescent dopants described in JP 2009-130141 A are also suitably used. The emissive layer preferably contains a phosphorescent dopant formed of an iridium complex or a platinum complex, whereby the luminous efficiency can be further improved.

In addition, the organic EL element containing the triplet light-emitting material may further contain a compound represented by the general formula (6).

As to the triplet light-emitting material to be used as the dopant material, the emissive layer may contain only one triplet light-emitting material, or two or more types thereof may be used in combination. When two or more triplet light-emitting materials are used, the total weight of the dopant material is preferably 30% by weight or less, more preferably 20% by weight or less with respect to the host material.

The host and the dopant preferable in a triplet emission system are not particularly limited, and specific examples thereof include the following.

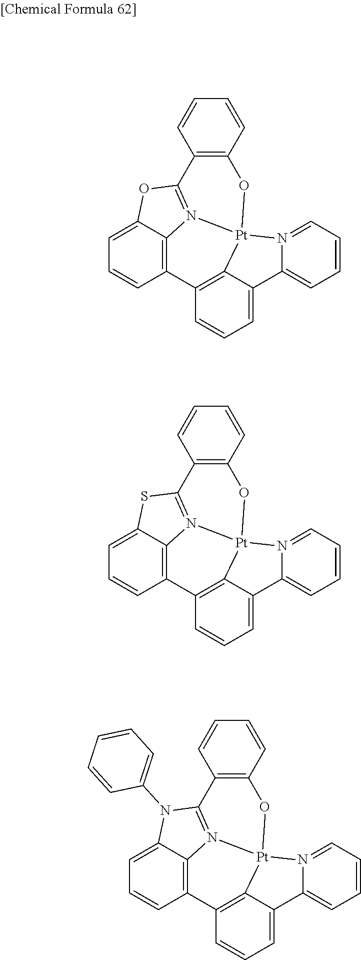

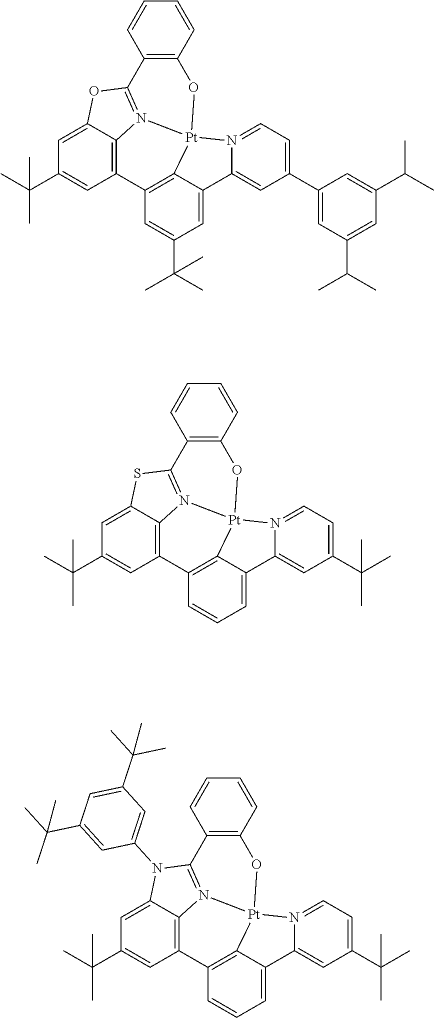

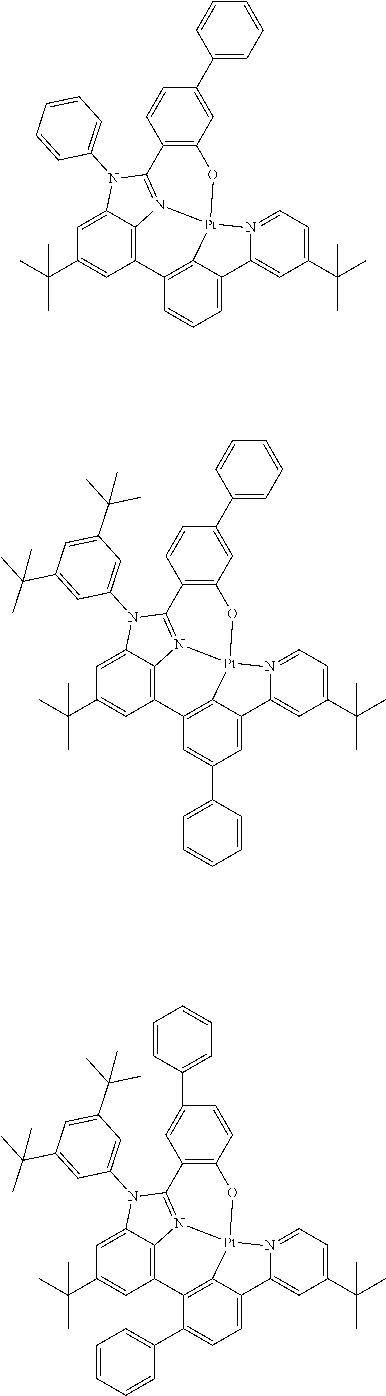

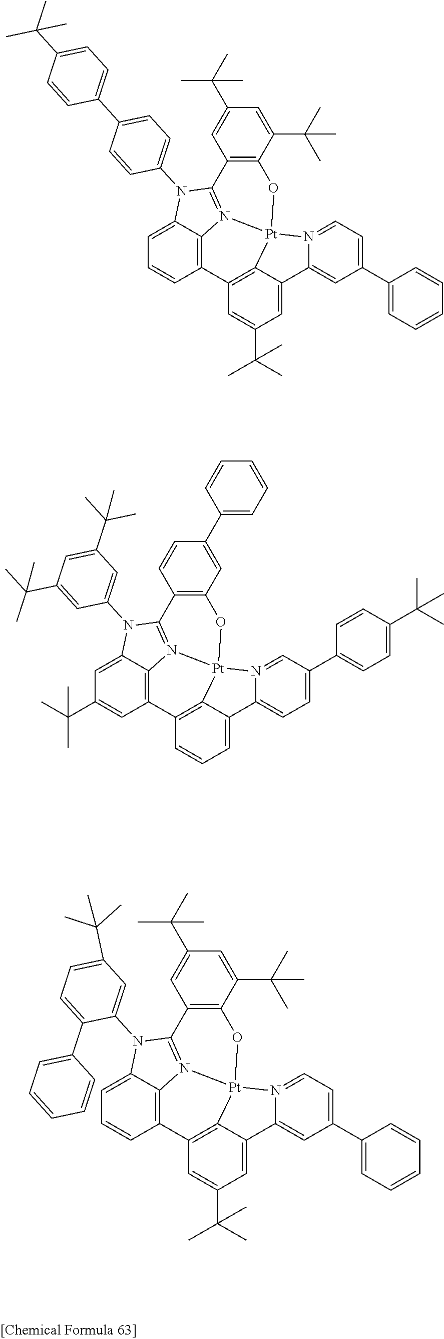

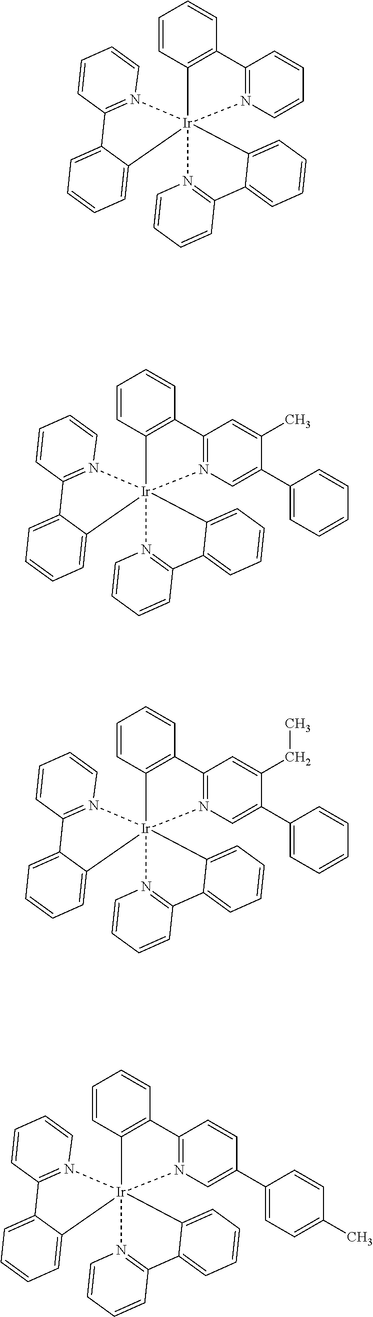

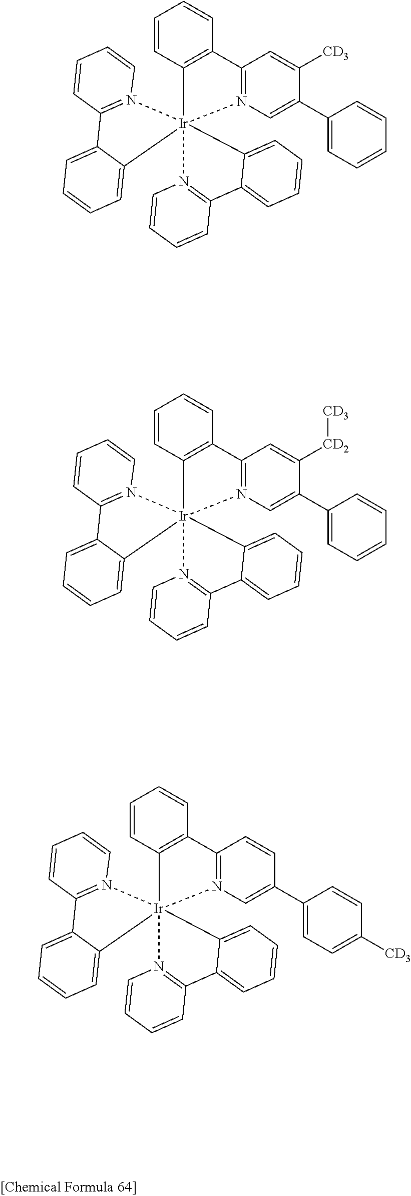

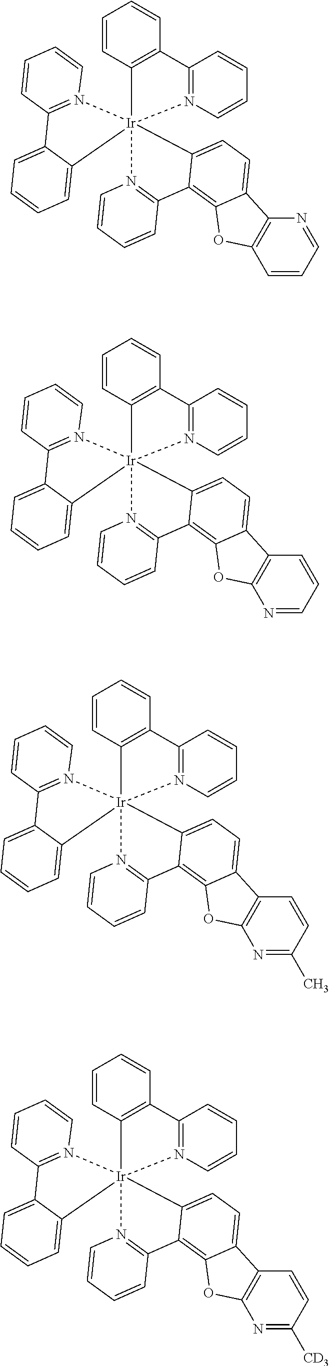

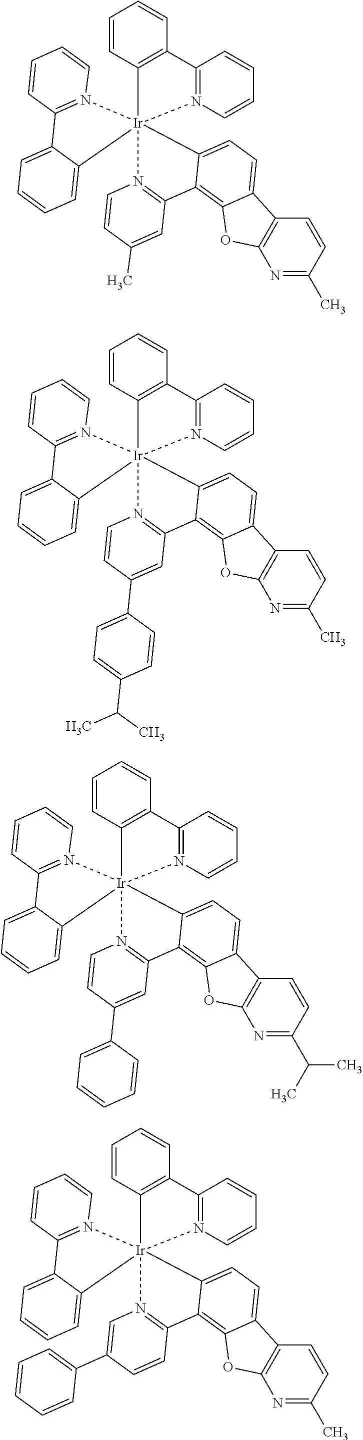

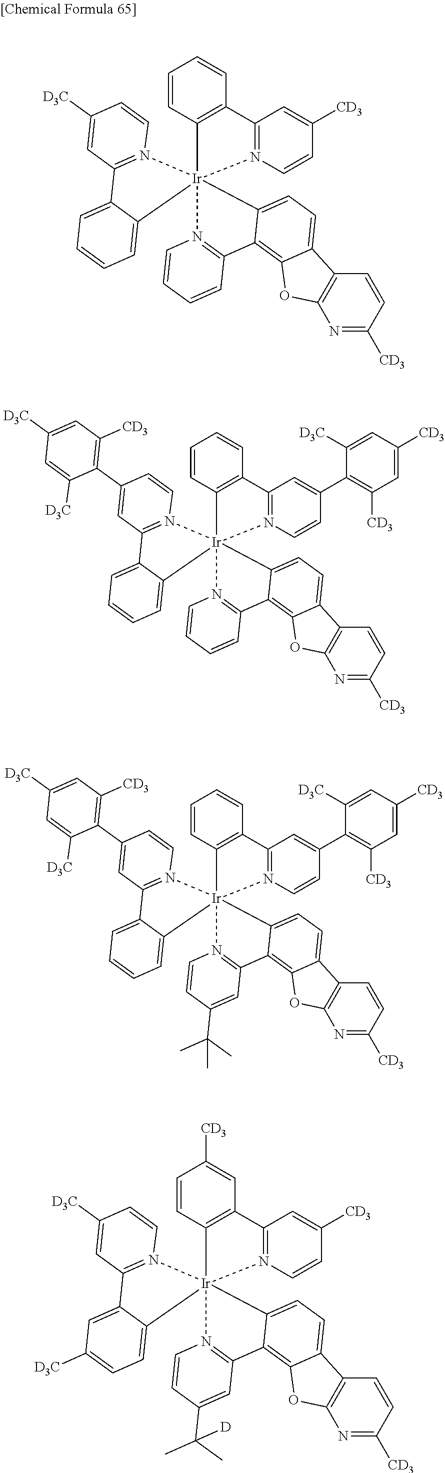

It is also preferred that the emissive layer contains a thermally activated delayed fluorescence material. Thermally activated delayed fluorescence is explained in “State-of-the-Art Organic Light-Emitting Diodes” (edited by Chihaya Adachi and Hiroshi Fujimoto, published by CMC Publishing Co., Ltd.), pages 87-103. The document explains that when energy levels in an excited singlet state and an excited triplet state of a fluorescent light-emitting material are brought close to each other, reverse energy transfer to the excited singlet state from the excited triplet state normally with a low transition probability occurs with high efficiency, so that thermally activated delayed fluorescence (TADF) is generated. Further, the mechanism of generation of delayed fluorescence is illustrated in FIG. 5 in the document. The light emission of delayed fluorescence can be determined by transient PL (photo luminescence) measurement.

Thermally activated delayed fluorescence materials are also commonly referred to as TADF materials. In the thermally activated delayed fluorescence material, the thermally activated delayed fluorescence may be exhibited with a single material or a plurality of materials. When the material is composed of a plurality of materials, the material may be used in the form of a mixture, or layers composed of the respective materials may be laminated and used. As the thermally activated delayed fluorescence material, publicly known materials can be used. Specific examples of the material include, but are not limited to, benzonitrile derivatives, triazine derivatives, disulfoxide derivatives, carbazole derivatives, indolocarbazole derivatives, dihydrophenazine derivatives, thiazole derivatives, and oxadiazole derivatives.

Preferred TADF materials include the compounds enumerated as examples below.

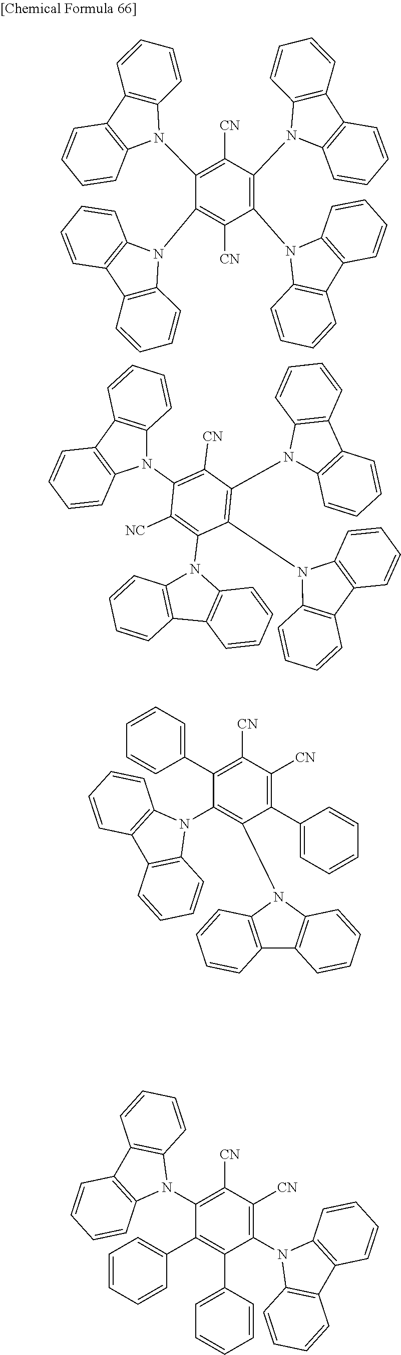

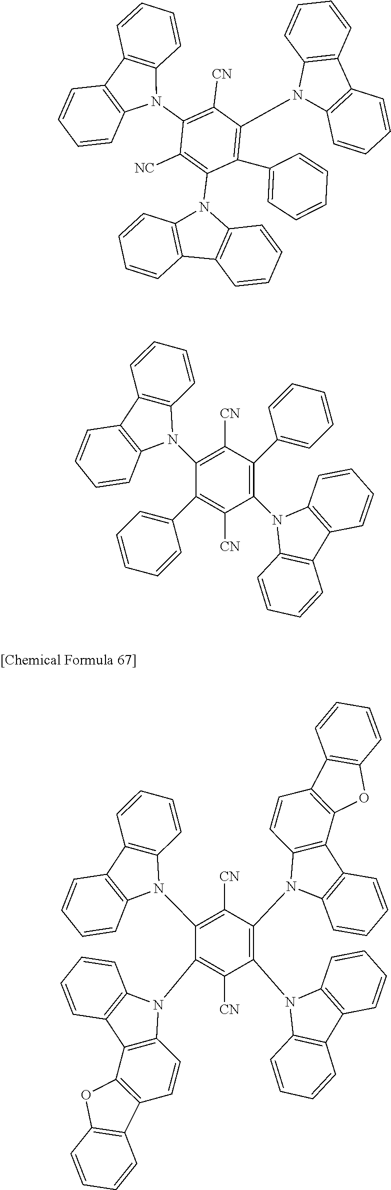 [SMILES: N#Cc1c(-n2c3ccccc3c3ccccc32)c(C#N)c(-n2c3ccccc3c3ccccc32)c(-c2ccccc2)c1-n1c2ccccc2c2ccccc21 ; N#Cc1c(-c2ccccc2)c(-n2c3ccccc3c3ccccc32)c(C#N)c(-c2ccccc2)c1-n1c2ccccc2c2ccccc21 ; N#Cc1c(-n2c3ccccc3c3ccccc32)c(-n2c3ccccc3c3c4oc5ccccc5c4ccc32)c(C#N)c(-n2c3ccccc3c3ccccc32)c1-n1c2ccccc2c2c3oc4ccccc4c3ccc21]

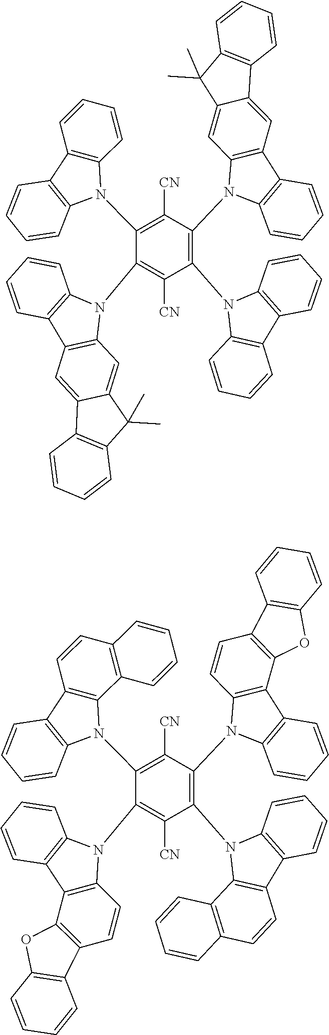 [SMILES: CC1(C)c2ccccc2-c2cc3c4ccccc4n(-c4c(C#N)c(-n5c6ccccc6c6ccccc65)c(-n5c6ccccc6c6cc7c(cc65)C(C)(C)c5ccccc5-7)c(C#N)c4-n4c5ccccc5c5ccccc54)c3cc21 ; N#Cc1c(-n2c3ccccc3c3c4oc5ccccc5c4ccc32)c(-n2c3ccccc3c3ccc4ccccc4c32)c(C#N)c(-n2c3ccccc3c3c4oc5ccccc5c4ccc32)c1-n1c2ccccc2c2ccc3ccccc3c21]

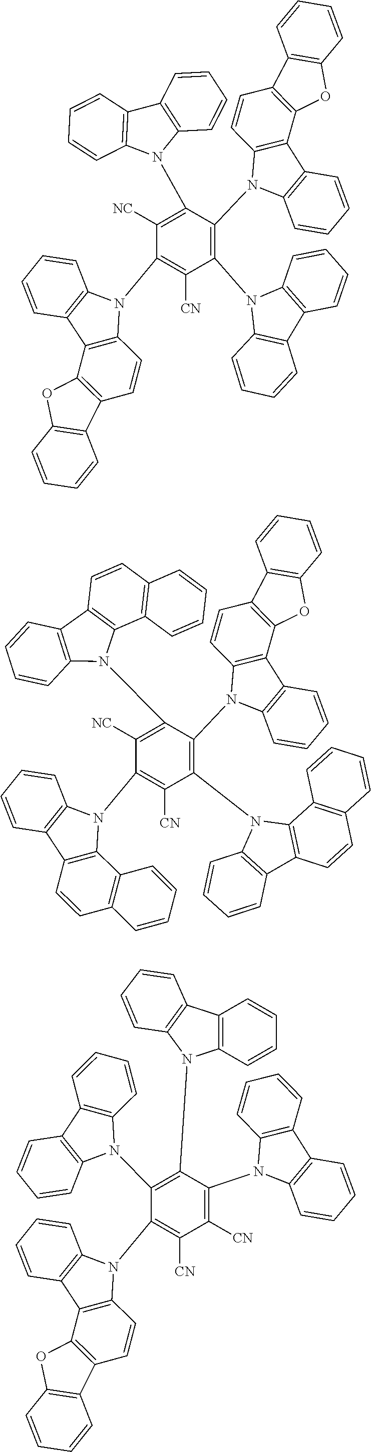

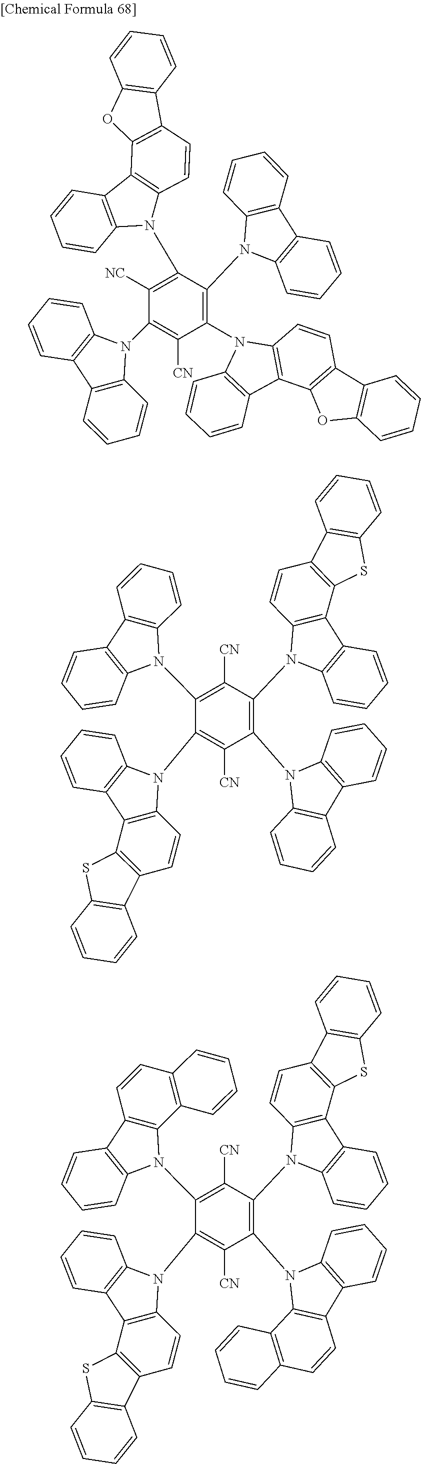

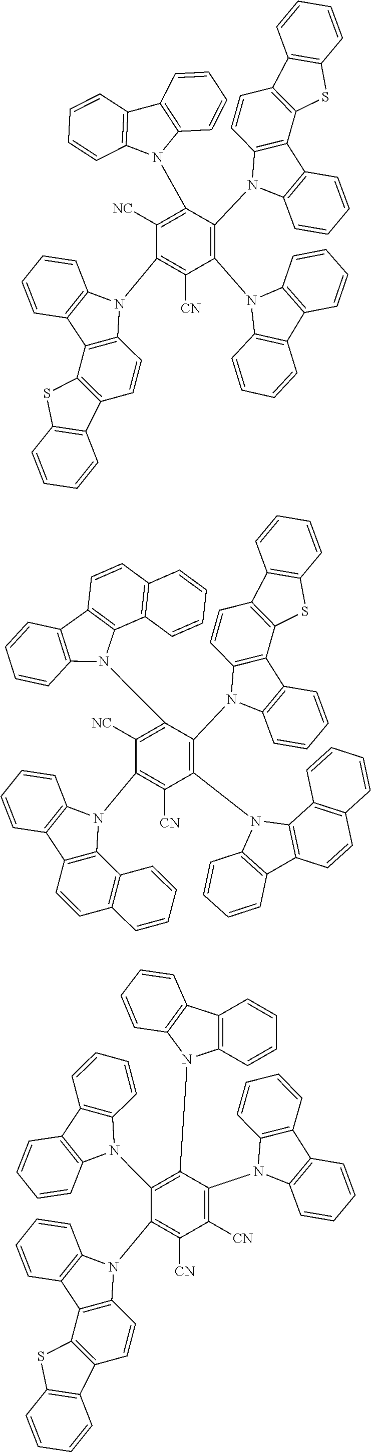

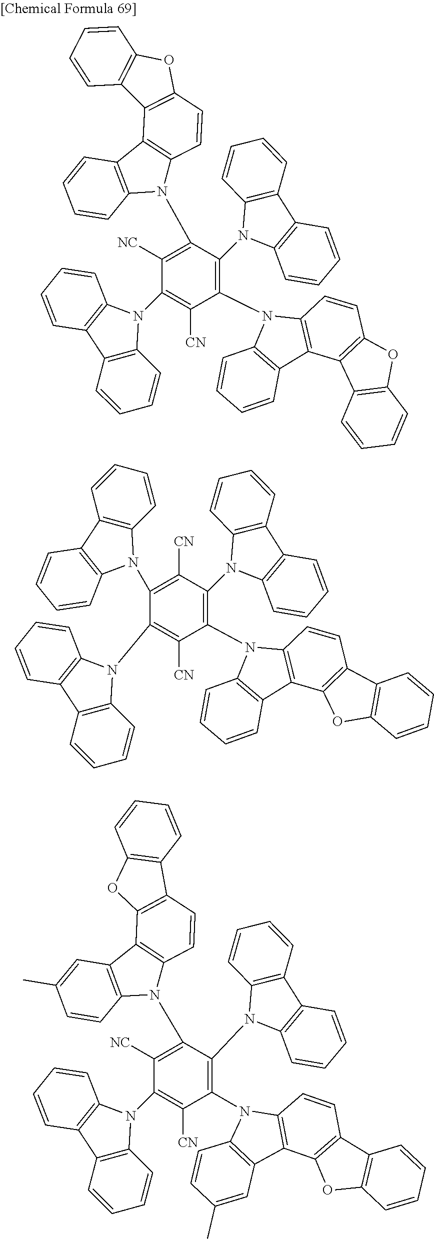

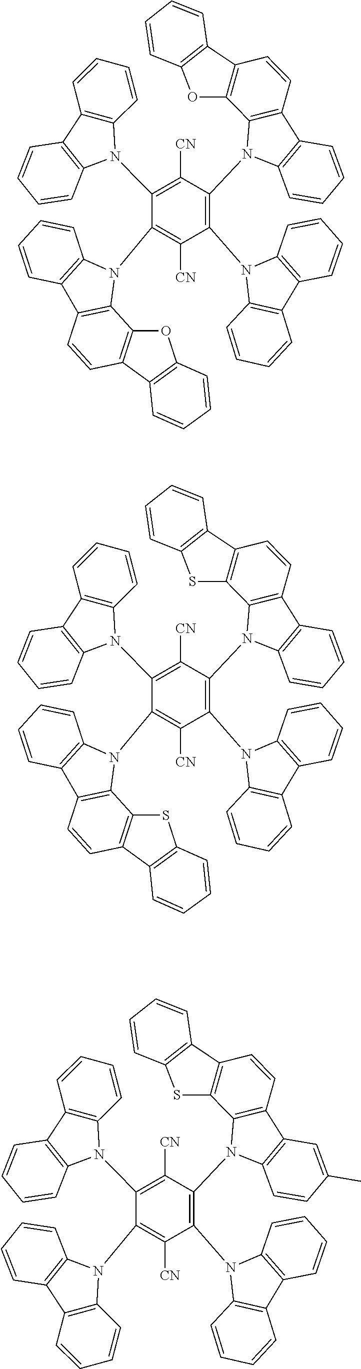 [SMILES: N#Cc1c(-n2c3ccccc3c3ccccc32)c(-n2c3ccccc3c3ccc4c5ccccc5oc4c32)c(C#N)c(-n2c3ccccc3c3ccccc32)c1-n1c2ccccc2c2ccc3c4ccccc4oc3c21 ; N#Cc1c(-n2c3ccccc3c3ccccc32)c(-n2c3ccccc3c3ccc4c5ccccc5sc4c32)c(C#N)c(-n2c3ccccc3c3ccccc32)c1-n1c2ccccc2c2ccc3c4ccccc4sc3c21 ; Cc1ccc2c(c1)c1ccc3c4ccccc4sc3c1n2-c1c(C#N)c(-n2c3ccccc3c3ccccc32)c(-n2c3ccccc3c3ccccc32)c(C#N)c1-n1c2ccccc2c2ccccc21]

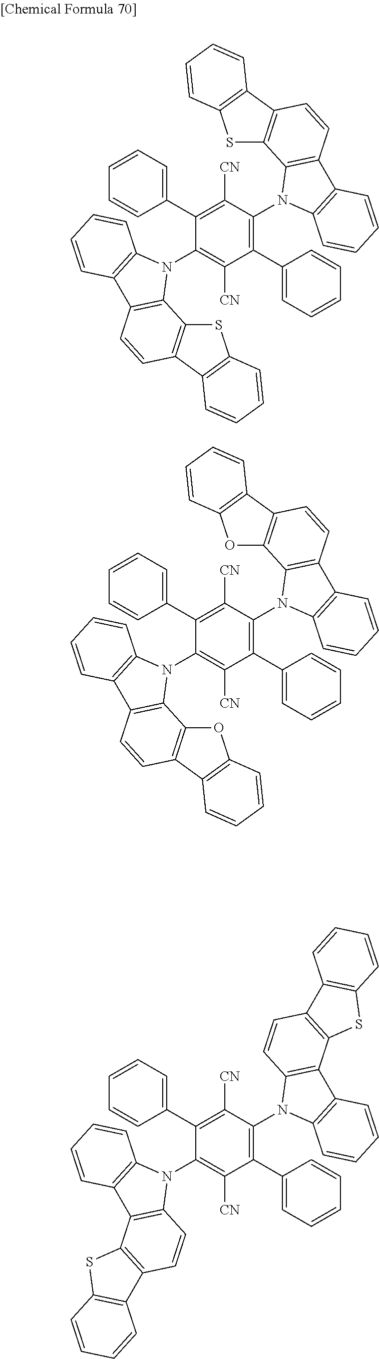

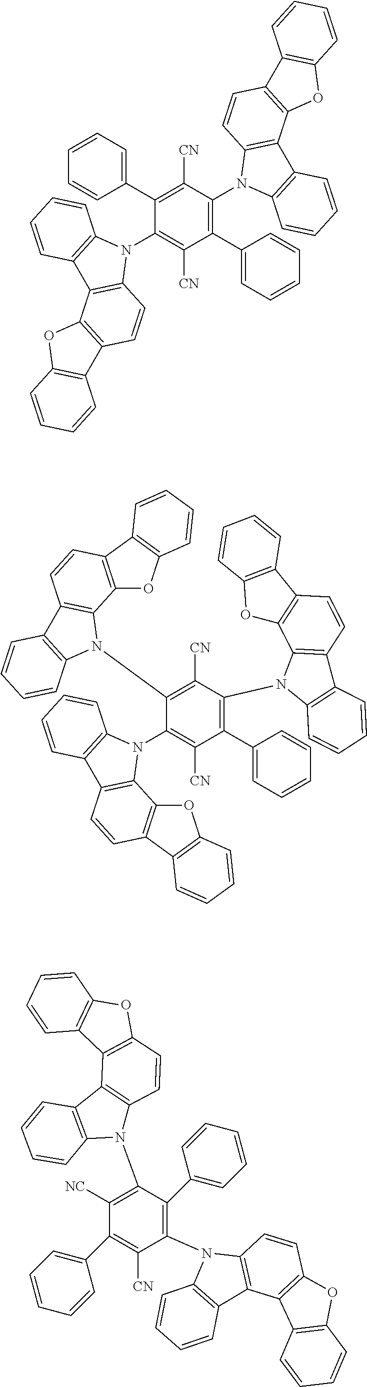 [SMILES: N#Cc1c(-c2ccccc2)c(-n2c3ccccc3c3c4oc5ccccc5c4ccc32)c(C#N)c(-c2ccccc2)c1-n1c2ccccc2c2c3oc4ccccc4c3ccc21 ; N#Cc1c(-c2ccccc2)c(-n2c3ccccc3c3ccc4c5ccccc5oc4c32)c(C#N)c(-n2c3ccccc3c3ccc4c5ccccc5oc4c32)c1-n1c2ccccc2c2ccc3c4ccccc4oc3c21 ; N#Cc1c(-c2ccccc2)c(C#N)c(-n2c3ccccc3c3c4c(ccc32)oc2ccccc24)c(-c2ccccc2)c1-n1c2ccccc2c2c3c(ccc21)oc1ccccc13]

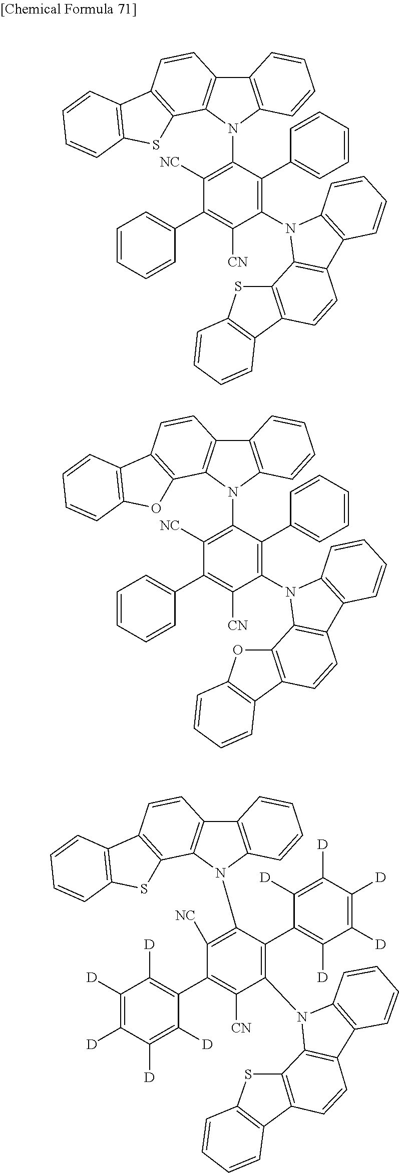

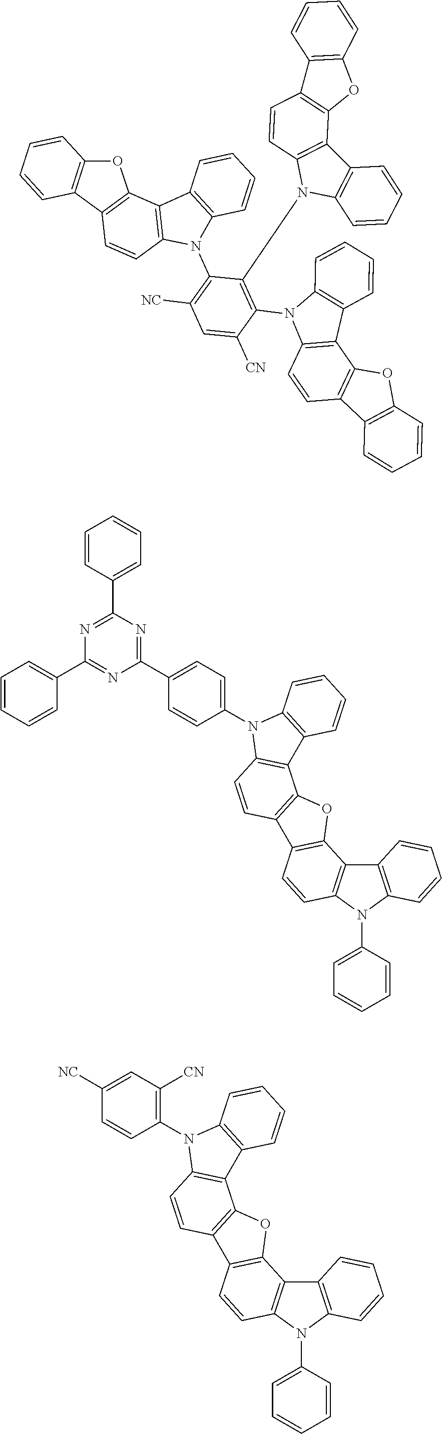 [SMILES: N#Cc1cc(C#N)c(-n2c3ccccc3c3c4oc5ccccc5c4ccc32)c(-n2c3ccccc3c3c4oc5ccccc5c4ccc32)c1-n1c2ccccc2c2c3oc4ccccc4c3ccc21 ; c1ccc(-c2nc(-c3ccccc3)nc(-c3ccc(-n4c5ccccc5c5c6oc7c(ccc8c7c7ccccc7n8-c7ccccc7)c6ccc54)cc3)n2)cc1 ; N#Cc1ccc(-n2c3ccccc3c3c4oc5c(ccc6c5c5ccccc5n6-c5ccccc5)c4ccc32)c(C#N)c1]

In an element in which a TADF material is contained in an emissive layer, the emissive layer preferably further contains a fluorescent dopant. That is, the emissive layer preferably contains a thermally activated delayed fluorescence material and a fluorescent dopant. This is because triplet excitons are converted into singlet excitons by the TADF material, and the fluorescent dopant receives the singlet excitons, whereby higher luminous efficiency and longer durable life can be achieved.

Examples of the fluorescent dopant to be used for an element in which the TADF material is contained in the emissive layer include compounds represented by the general formula (6) described above and the pyrromethene derivatives disclosed below as examples. The fluorescent dopant is preferably a compound represented by the general formula (6).

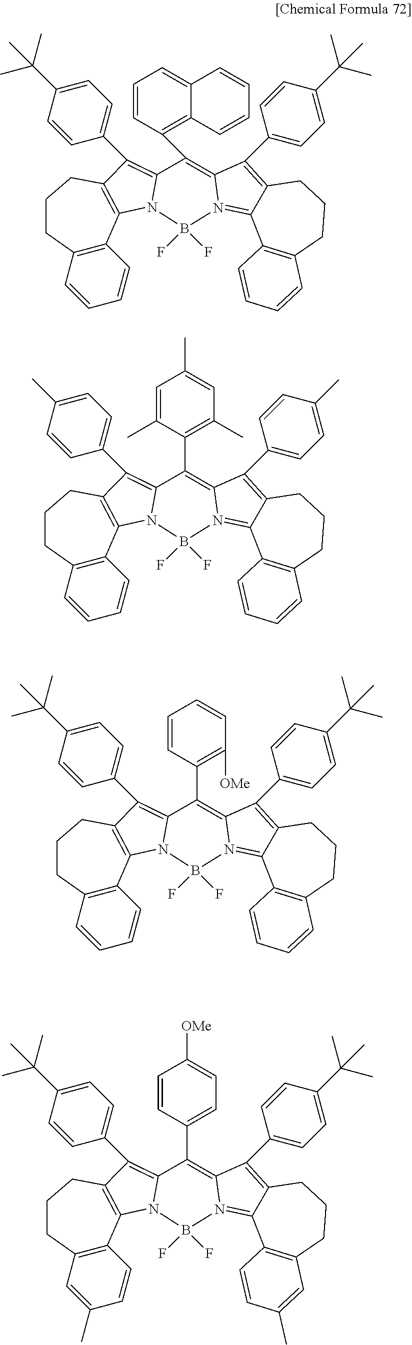

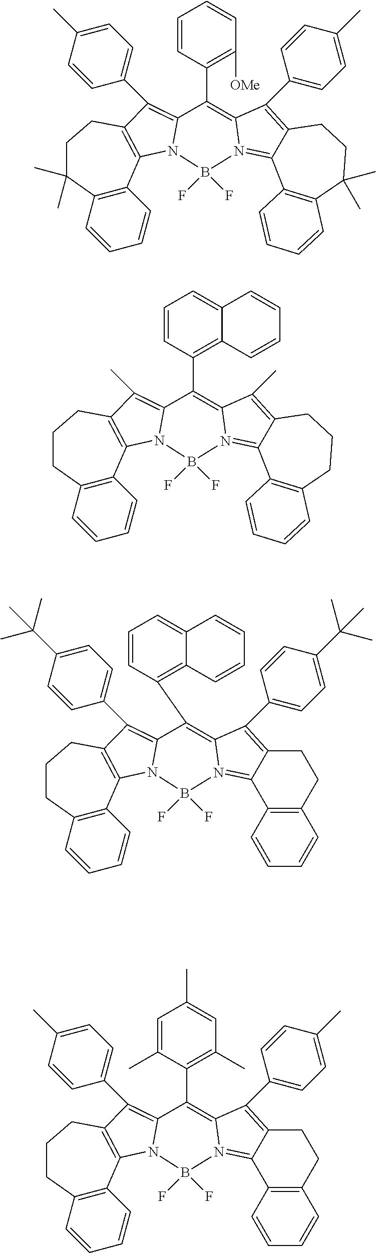

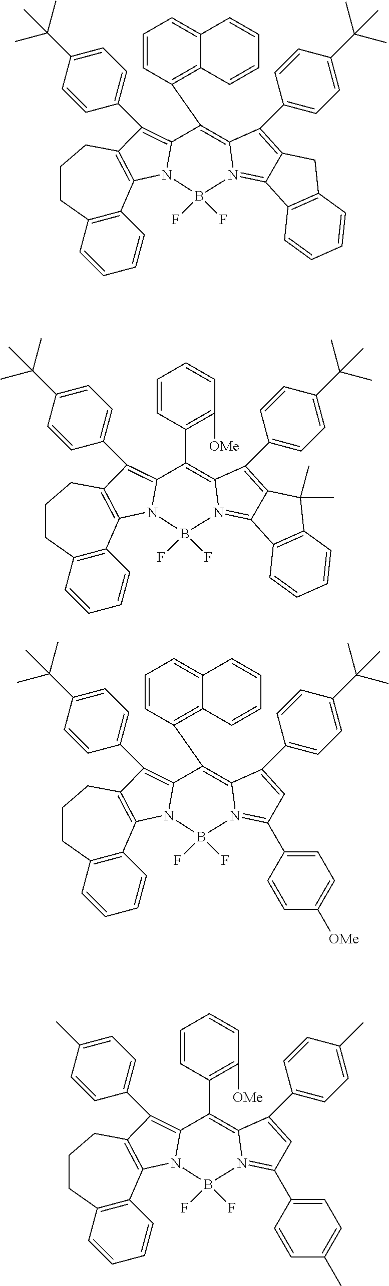

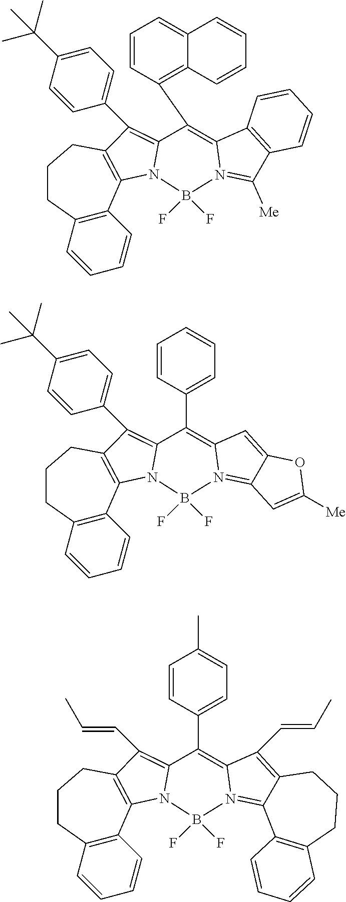

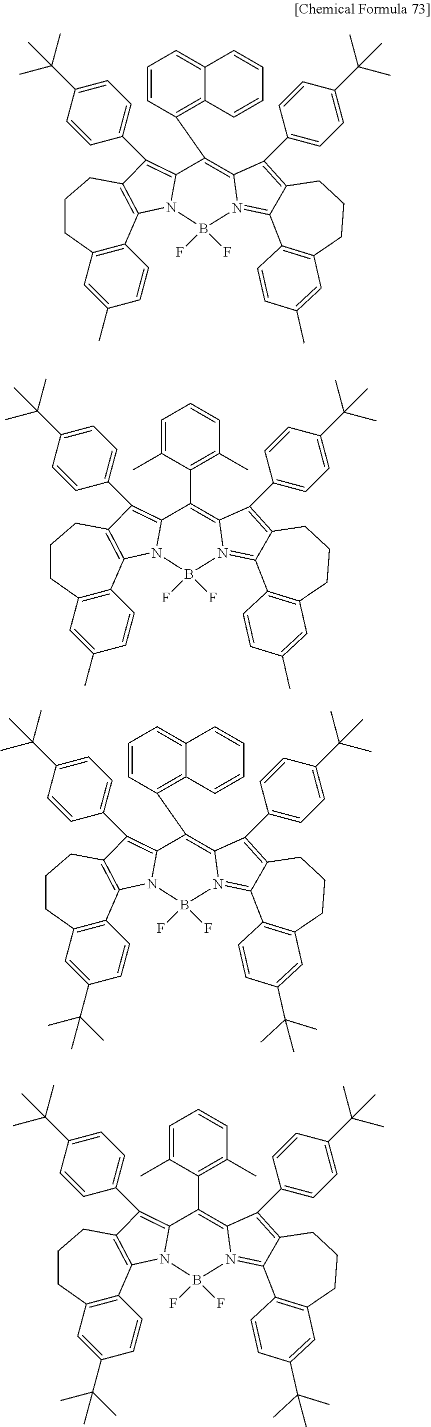

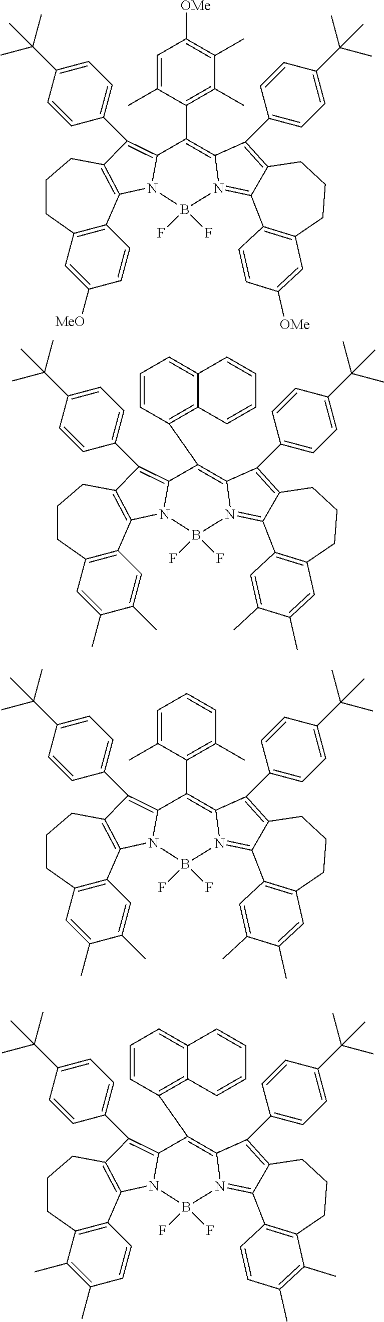

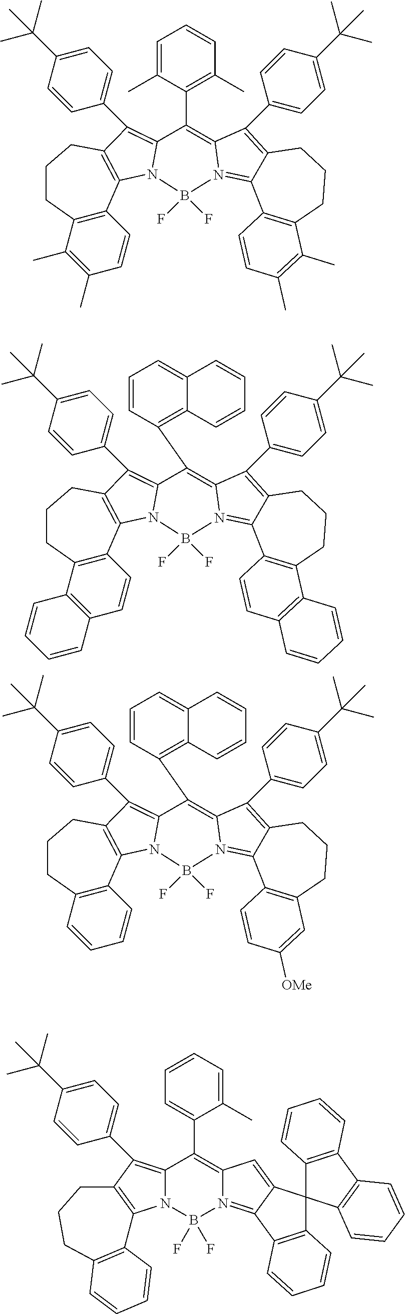

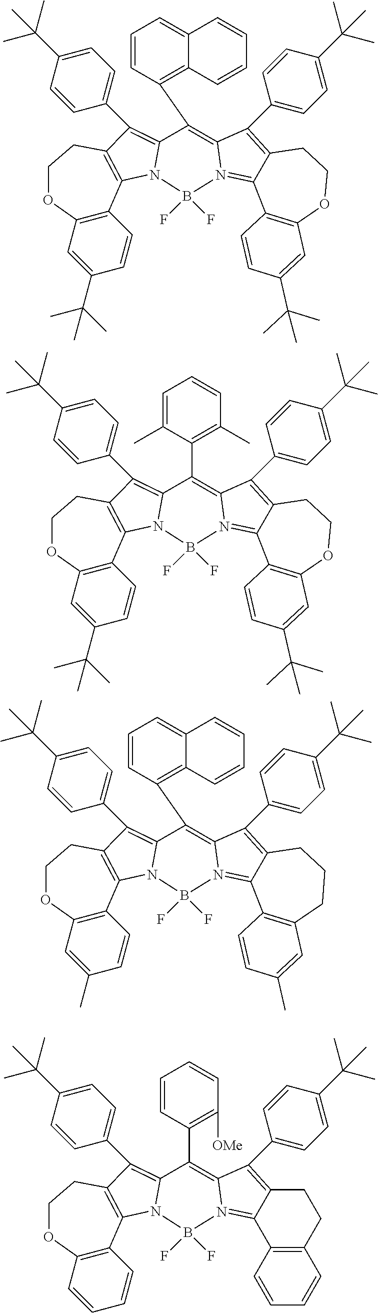

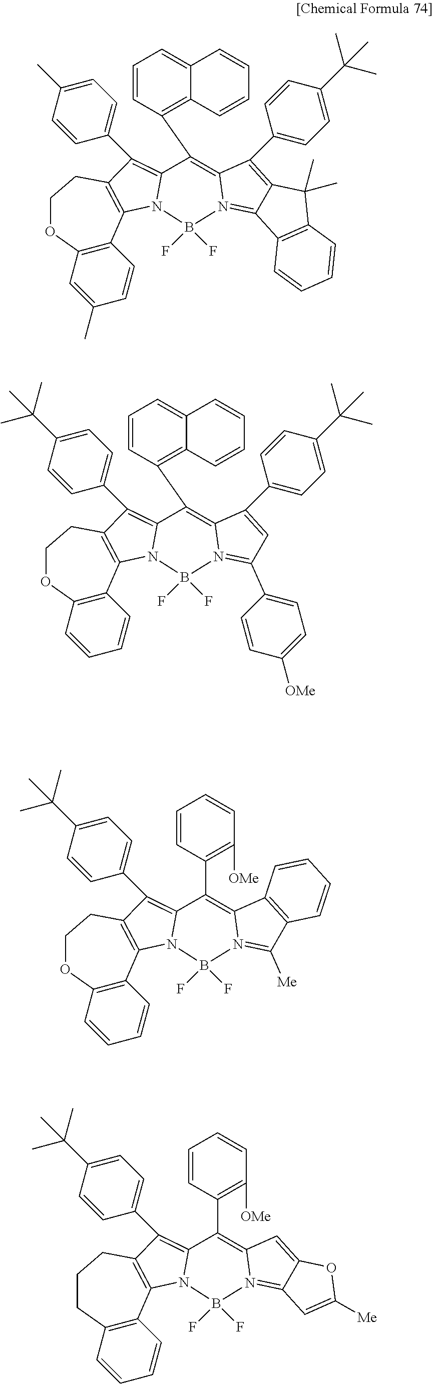

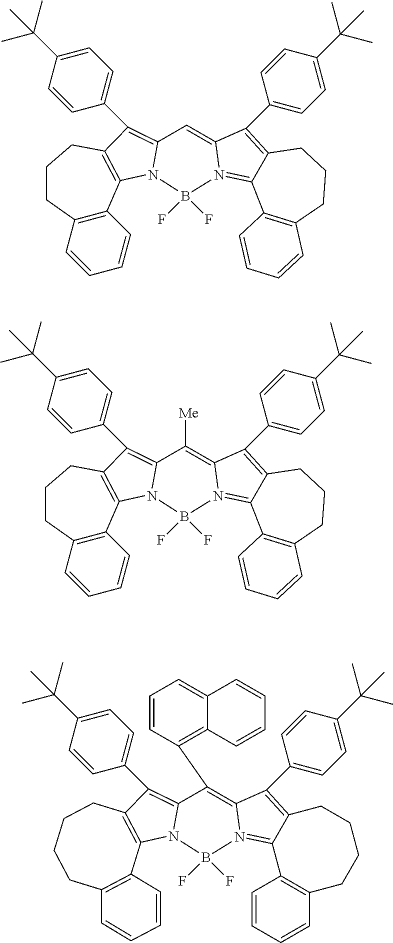

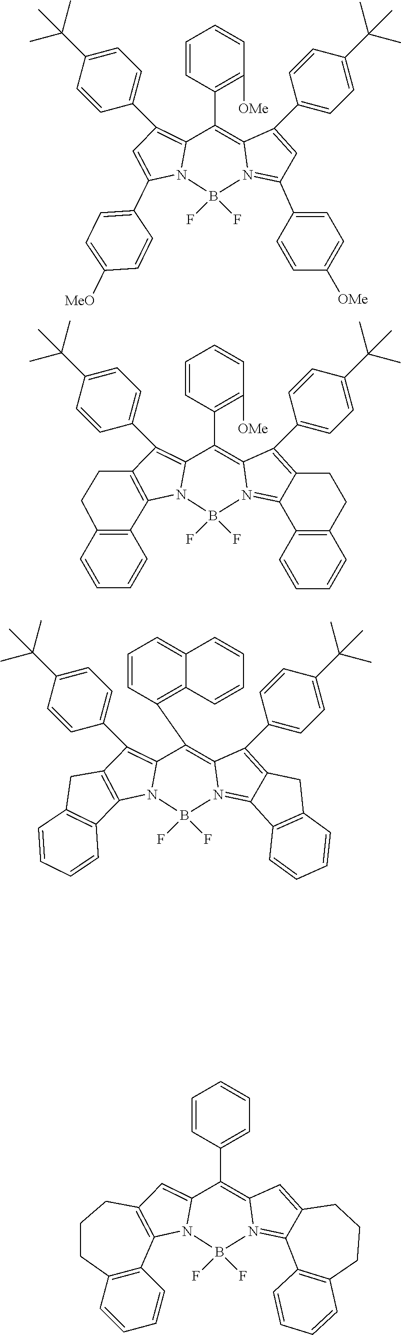

### (Electron Transporting Layer)

In the present invention, the electron transporting layer is a layer into which electrons are injected from the cathode and which transports the electrons. The electron transporting layer is desired to have a high electron injection efficiency and efficiently transport injected electrons. Therefore, it is preferable that the material forming the electron transporting layer be a substance that has high electron affinity and high electron mobility, is superior in stability, and hardly generates impurities that serve as a trap, at the time of production and use. In particular, in the case of laminating layers in a large film thickness, the film quality easily degrades due to crystallization of a compound having a low molecular weight or the like, and therefore, to maintain stable film quality, a compound having a molecular weight of 400 or more is preferred. The electron transporting layer may be a single layer or may be formed of a plurality of materials laminated.

Examples of the electron transporting material to be used for the electron transporting layer include fused polycyclic aromatic derivatives such as naphthalene and anthracene, styryl-based aromatic ring derivatives such as 4,4′-bis(diphenylethenyl)biphenyl, quinone derivatives such as anthraquinone and diphenoquinone, phosphorus oxide derivatives, and various types of metal complexes such as quinolinol complexes, e.g., tris(8-quinolinolato)aluminum(III), benzoquinolinol complexes, hydroxyazole complexes, azomethine complexes, tropolone metal complexes, and flavonol metal complexes. It is preferable to use a compound that includes an element selected from among carbon, hydrogen, nitrogen, oxygen, silicon, and phosphorus and has a heteroaryl ring structure including electron-accepting nitrogen because the driving voltage is further reduced and further efficient light emission can be obtained with such a compound.

Here, the electron-accepting nitrogen denotes a nitrogen atom forming a multiple bond with an adjacent atom. The multiple bond has an electron-accepting property because a nitrogen atom has a high electron negativity. Therefore, an aromatic heterocyclic ring including electron-accepting nitrogen has a high electron affinity. An electron transporting material having electron-accepting nitrogen facilitates reception of electrons from a cathode having a high electron affinity and makes driving at a lower voltage possible. Furthermore, the supply of electrons to the emissive layer increases to enhance the recombination probability, and as a result, the luminous efficiency is further improved.

Examples of the heteroaryl ring including electron-accepting nitrogen include a triazine ring, a pyridine ring, a pyrazine ring, a pyrimidine ring, a quinoline ring, a quinoxaline ring, a quinazoline ring, a naphthyridine ring, a pyrimidopyrimidine ring, a benzoquinoline ring, a phenanthroline ring, an imidazole ring, an oxazole ring, an oxadiazole ring, a triazole ring, a thiazole ring, a thiadiazole ring, a benzoxazole ring, a benzothiazole ring, a benzimidazole ring, and a phenanthroimidazole ring.

Examples of compounds having such a heteroaryl ring structure include pyridine derivatives, triazine derivatives, quinazoline derivatives, pyrimidine derivatives, benzimidazole derivatives, benzoxazole derivatives, benzthiazole derivatives, oxadiazole derivatives, thiadiazole derivatives, triazole derivatives, pyrazine derivatives, phenanthroline derivatives, quinoxaline derivatives, quinoline derivatives, benzoquinoline derivatives, oligopyridine derivatives such as bipyridine and terpyridine, quinoxaline derivatives, and naphthyridine derivatives. Among them, those preferably used from the viewpoint of electron transporting ability include: imidazole derivatives such as tris(N-phenylbenzimidazol-2-yl)benzene, oxadiazole derivatives such as 1,3-bis[(4-tert-butylphenyl)1,3,4-oxadiazolyl]phenylene, triazole derivatives such as N-naphthyl-2,5-diphenyl-1,3,4-triazole, phenanthroline derivatives such as bathocuproine and 1,3-bis(1,10-phenanthrolin-9-yl)benzene, benzoquinoline derivatives such as 2,2′-bis(benzo[h]quinolin-2-yl)-9,9′-spirobifluorene, bipyridine derivatives such as 2,5-bis(6′-(2′,2″-bipyridyl))-1,1-dimethyl-3,4-diphenylsilole, terpyridine derivatives such as 1,3-bis(4′-(2,2′:6′2″-terpyridinyl)benzene, and naphthyridine derivatives such as bis(1-naphthyl)-4-(1,8-naphthyridin-2-yl)phenylphosphine oxide. The electron transporting layer particularly preferably contains a triazine derivative or a pyrimidine derivative. Most preferably, the electron transporting layer contains a triazine derivative or a pyrimidine derivative represented by the following general formula (5),

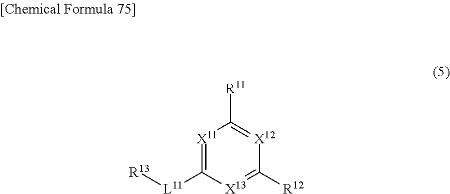

in the general formula (5), at least two of X¹¹ to X¹³ are nitrogen atoms, and each of X¹¹ to X¹³ is a methine group when not being a nitrogen atom; R¹¹ and R¹² are each a substituted or unsubstituted phenyl group, a substituted or unsubstituted biphenyl group, or a substituted or unsubstituted fluorenyl group; L¹¹ is a single bond or an arylene group; and R¹³ is a substituted or unsubstituted heteroaryl group or an aryl group substituted with a cyano group.

The arylene group denotes a divalent aromatic hydrocarbon group, such as a phenylene group, a biphenylene group, a terphenylene group, a naphthylene group, a fluorenylene group, a benzofluorenylene group, a dibenzofluorenylene group, a phenanthrylene group, and an anthracenylene group, and a plurality of these groups may be linked. The arylene group may or may not have a substituent. The number of carbon atoms in the arylene group is not particularly limited, and is preferably in the range of 6 or more and 40 or less, and more preferably 6 or more and 30 or less.

Examples of a preferable triazine derivative and a preferable pyrimidine derivative include the following compounds.

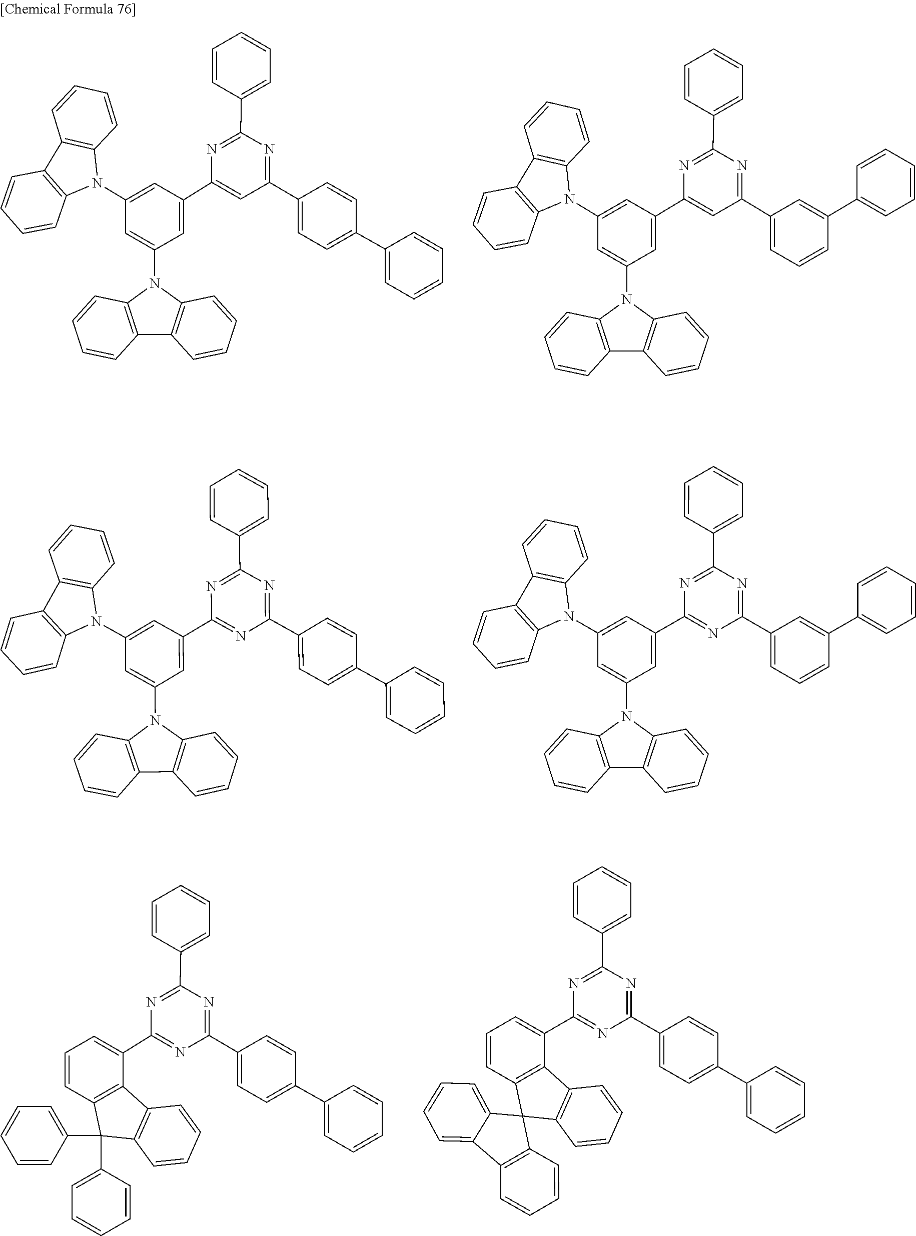

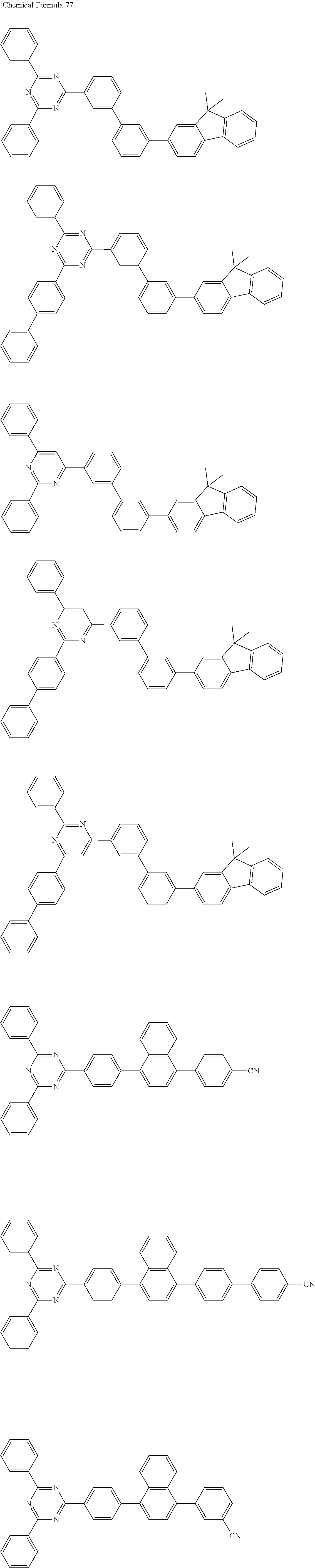

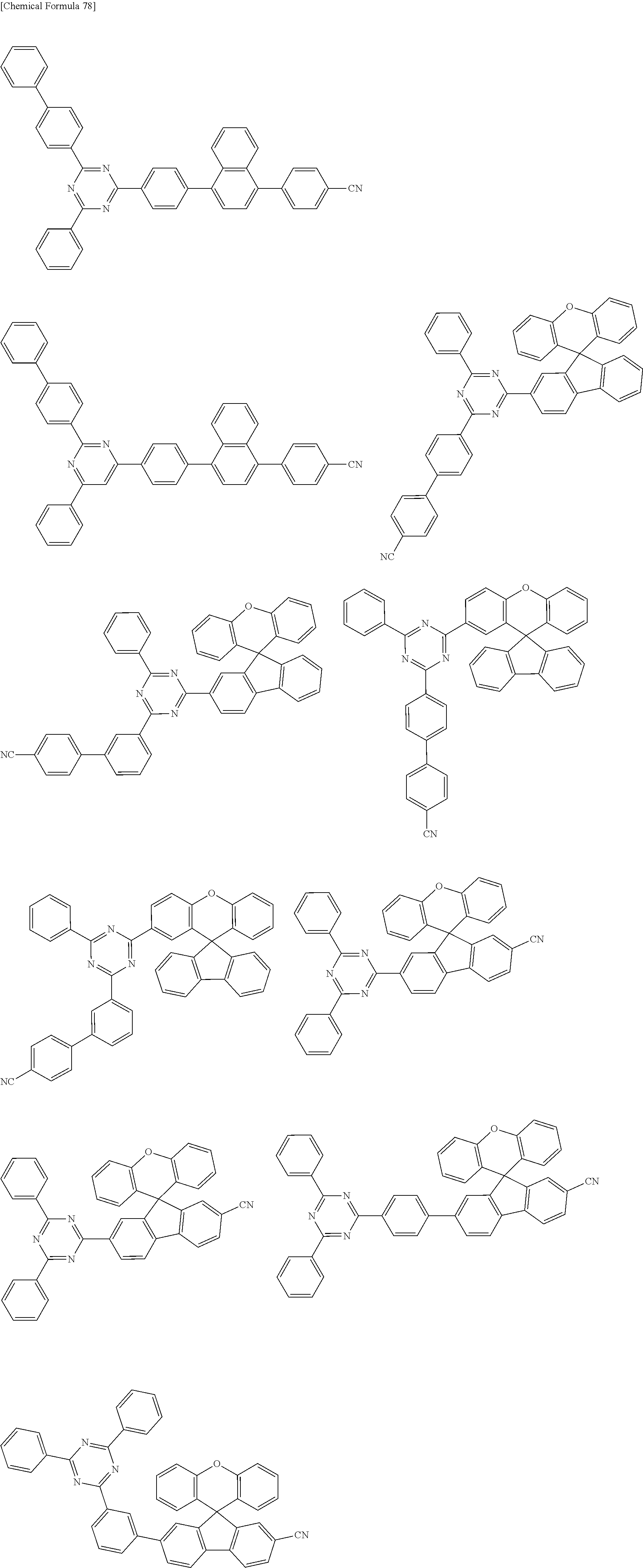

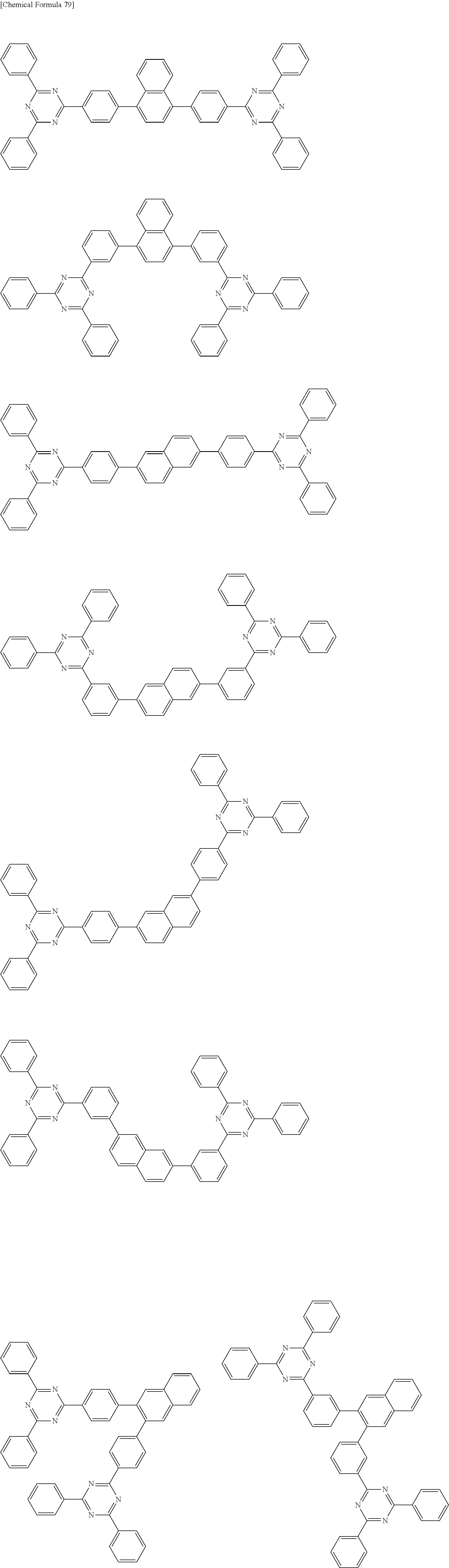

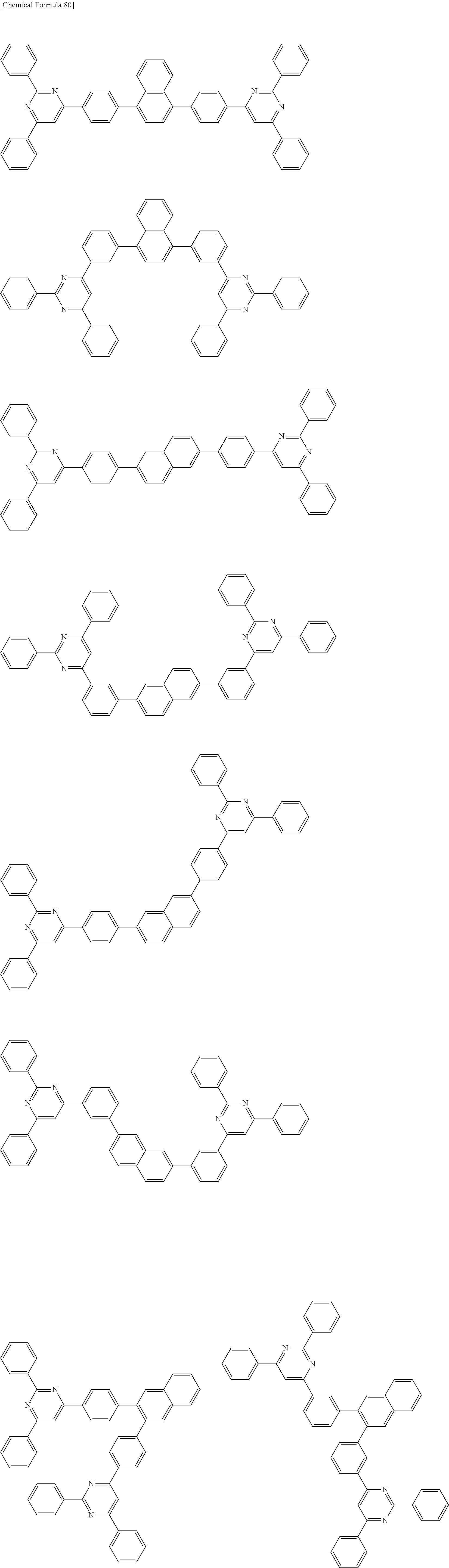

As to the electron transporting material described above, a single material thereof may be used alone, two or more electron transporting materials described above may be used in combination, or one or more other electron transporting materials may be used in combination with the electron transporting material described above. The electron transporting material may contain a donor compound. Here, the donor compound denotes a compound that facilitates electron injection from the cathode or the electron injection layer into the electron transporting layer through improvement in the electron injection barrier, and improves the electroconductivity of the electron transporting layer.

Preferred examples of the donor compound include an alkali metal, an inorganic salt containing an alkali metal, a complex of an alkali metal with an organic substance, an alkaline earth metal, an inorganic salt containing an alkaline earth metal, a complex of an alkaline earth metal with an organic substance, and a rare earth metal. Preferable examples of alkali metal, alkaline earth metal, and rare earth metal include alkali metals such as lithium, sodium, potassium, rubidium, and cesium, alkali earth metals such as magnesium, calcium, cerium, and barium, and rare earth metals such as samarium, europium, and ytterbium, which have a low work function and a great effect of enhancing electron transporting ability. A plurality of these metals may be used, or an alloy including these metals may be used.

In addition, the donor compound is preferably an inorganic salt or in a state of a complex of a metal with an organic substance rather than a simple metal because such an inorganic salt or a complex is easily deposited in vacuum and is superior in handleability. Furthermore, it is more preferable that the donor compound is in the state of a complex with an organic substance in terms of facilitating handling in the atmosphere and facilitating adjustment of the addition concentration. Examples of the inorganic salt include oxides such as LiO and Li₂O, nitrides, fluorides such as LiF, NaF, and KF, and carbonates such as Li₂CO₃, Na₂CO₃, K₂CO₃, Rb₂CO₃, and Cs₂CO₃. Preferable examples of the alkali metal or alkaline earth metal include lithium and cesium in terms of the fact that the driving voltage can be further reduced. Regarding the complex with an organic substance, preferable examples of the organic substance include quinolinol, benzoquinolinol, pyridylphenol, flavonol, hydroxyimidazopyridine, hydroxybenzazole, and hydroxytriazole. Among them, in terms of the fact that the driving voltage of the organic EL element can be further reduced, the complex of an alkali metal with an organic substance is preferable. Furthermore, in terms of ease of synthesis and thermal stability, a complex of lithium with an organic substance is more preferable, and lithium quinolinol (Liq), which is available at a relatively low cost, is particularly preferable.

The ionization potential of the electron transporting layer is not particularly limited, but is preferably 5.6 eV or more and 8.0 eV or less, and more preferably 5.6 eV or more and 7.0 eV or less.

The method for forming each of the aforementioned layers constituting the organic EL element is not particularly limited and may be resistance heating deposition, electron beam deposition, sputtering, a molecular lamination method, a coating method, or the like, but usually, resistance heating deposition or electron beam deposition is preferred from the viewpoint of element properties.

### (Hole Inhibition Layer)

In the present invention, a hole inhibition layer may be provided between the emissive layer and the electron transporting layer. In general, a hole inhibition layer is inserted for the purpose of preventing holes in the emissive layer from flowing toward the cathode. By preventing holes in the emissive layer from flowing toward the cathode, the amount of holes that can be recombined increases, so that the luminous efficiency of the light-emitting element can be improved.

As the material to be used for the hole inhibition layer, a material having high hole inhibition property and high electron transporting ability is preferable, and a compound having a heteroaryl ring structure containing electron-accepting nitrogen is preferably used. The hole inhibition layer particularly preferably contains a triazine derivative or a pyrimidine derivative. Most preferably, the hole inhibition layer contains a triazine derivative or a pyrimidine derivative represented by the general formula (5) shown above.

### (Electron Injection Layer)

In the present invention, an electron injection layer may be provided between the cathode and the electron transporting layer. The electron injection layer is interposed generally for the purpose of assisting injection of electrons from the cathode to the electron transporting layer. When the electron injection layer is interposed, a compound having a heteroaryl ring structure including electron-accepting nitrogen may be used, or a layer containing the above-described donor material may be used.

An inorganic substance such as an insulator or a semiconductor can also be used for the electron injection layer. The use of such a material can inhibit a short-circuit of the organic EL element, and can improve electron injection property.

As such an insulator, at least one metal compound selected from the group consisting of alkali metal chalcogenides, alkaline earth metal chalcogenides, halides of alkali metal, and halides of alkaline earth metal is preferable.

Specifically, examples of preferable alkali metal chalcogenides include Li₂O, Na₂S, and Na₂Se. In addition, examples of preferable alkaline earth metal chalcogenides include CaO, BaO, SrO, BeO, BaS, and CaSe. Examples of preferable halides of an alkali metal include LiF, NaF, KF, LiCl, KCl, and NaCl. Examples of preferable halides of an alkaline earth metal include fluorides such as CaF₂, BaF₂, SrF₂, MgF₂, and BeF₂, and halides other than fluorides.

A complex of an organic substance with a metal is also suitably used. When a complex of an organic substance with a metal is used in the electron injection layer, the film thickness can be easily adjusted. Preferable examples of the organic substance in the organic metal complex include quinolinol, benzoquinolinol, pyridylphenol, flavonol, hydroxyimidazopyridine, hydroxybenzazole, and hydroxytriazole.

The thickness of the organic layer depends on the resistance value of the emissive substance and is not limited, but is preferably 1 to 1,000 nm. The emissive layer, the electron transporting layer, and the hole transporting layer each preferably have a thickness of 1 nm or more and 200 nm or less, and more preferably 5 nm or more and 100 nm or less.

The organic EL element according to an embodiment of the present invention has a function of converting electrical energy into light. Here, as the electrical energy, a direct current is mainly used, but a pulse current or an alternating current can also be used. A current value and a voltage value are not particularly limited, but when the power consumed and life of the element are considered, they should be selected such that the maximum luminance is obtained by energy as low as possible.

The organic EL element according to an embodiment of the present invention is suitably used, for example, as a display device such as a display that displays in a matrix and/or segment system.

The method for producing the organic EL element according to an embodiment of the present invention can be selected from among a vapor deposition method using a fine metal mask, a printing method by inkjet, a method using photolithography after vapor deposition, and the like. In particular, the method using photolithography is preferable because pixels having an enlarged opening can be formed and higher definition pixels can be formed.

The organic EL element according to an embodiment of the present invention is also preferably used as a backlight for various devices and the like. The backlight is mainly used for the purpose of improving the visibility of a display device such as a display that does not emit light, and is used in liquid crystal displays, watches, audio devices, automobile panels, display boards, signs, and the like. In particular, the organic EL element of the present invention is preferably used in a backlight for a liquid crystal display, particularly for a personal computer that is studied for reduction in the thickness, and a backlight thinner and lighter than conventional ones can be provided.

The organic EL element according to an embodiment of the present invention is also preferably used as various illumination devices. The organic EL element according to an embodiment of the present invention can achieve both high luminous efficiency and high color purity, and further can achieve reduction in the thickness and the weight, and therefore an illumination device can be realized that has low power consumption, a bright emitted color, and a high design property with the light-emitting element.

### EXAMPLES

Hereinafter, the present invention will be described by way of Examples, but the present invention is not limited thereto.

### Synthesis Example 1: Synthesis of Compound 5

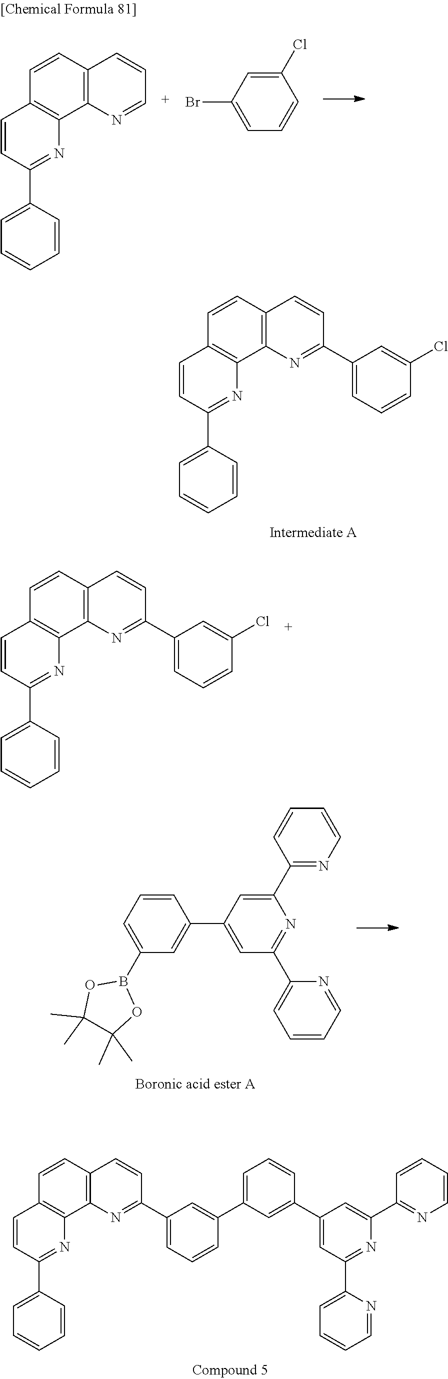 [SMILES: c1ccc(-c2ccc3ccc4cccnc4c3n2)cc1 ; Clc1cccc(Br)c1 ; Clc1cccc(-c2ccc3ccc4ccc(-c5ccccc5)nc4c3n2)c1 ; Clc1cccc(-c2ccc3ccc4ccc(-c5ccccc5)nc4c3n2)c1 ; CC1(C)OB(c2cccc(-c3cc(-c4ccccn4)nc(-c4ccccn4)c3)c2)OC1(C)C ; c1ccc(-c2ccc3ccc4ccc(-c5cccc(-c6cccc(-c7cc(-c8ccccn8)nc(-c8ccccn8)c7)c6)c5)nc4c3n2)cc1]

13 ml of n-butyllithium (1.6 M solution in hexane) was added dropwise to a mixed solution of 4.0 g of 1-bromo-3-chlorobenzene and 30 ml of tetrahydrofuran at 0° C. under a nitrogen flow. The mixture was stirred at 0° C. for 1 hour, and then added dropwise at 0° C. to a mixed liquid of 4.5 g of 2-phenyl-1,10-phenanthroline and 30 ml of tetrahydrofuran. After the temperature was raised to room temperature, the reaction solution was extracted with dichloromethane, and the extract was evaporated with 100 ml of the solvent left. To the resulting solution was added 10.0 g of manganese dioxide, and the mixture was stirred at room temperature for 4 hours. Then, magnesium sulfate was added, and the mixture was filtered, and the solvent was removed by evaporation. The solid obtained was purified by silica gel column chromatography, and the solvent was removed by evaporation, and the resulting solid was vacuum-dried to afford 6.0 g of Intermediate A.

Next, a mixed solution of 3.0 g of Intermediate A, 3.7 g of boronate ester A, 160 mg of dichlorobis(triphenylphosphine palladium) dichloride, 7 ml of a 1.5 M aqueous tripotassium phosphate solution, and 80 ml of 1,4-dioxane was heated and stirred under reflux for 7 hours under a nitrogen flow. After cooling to room temperature, the solid precipitated by adding water was collected by filtration, washed with methanol, and then vacuum-dried. The solid obtained was dissolved in a mixed solvent of toluene and pyridine, and then the catalyst was removed using activated carbon. The solid resulting from removal of the solvent by evaporation was washed with toluene and methanol, and then vacuum-dried, affording 3.0 g of Compound 5.

The resulting Compound 5 was subjected to sublimation purification at about 360° C. under a pressure of 1×10⁻³ Pa using an oil diffusion pump. The HPLC purity (area % at a measurement wavelength of 254 nm) of Compound 5 before the sublimation purification and that after the sublimation purification were both 99.9%.

After the sublimation purification, the structure of Compound 5 was identified by mass spectrum (MS) analysis and ¹H-NMR analysis. The analysis results are shown below.

MS (m/z): 640 [M+H]⁺

¹H-NMR (400 MHz, CDCl₃) δ: 8.94 (s, 1H), 8.81-8.87 (m, 2H), 8.65-8.74 (m, 4H), 8.40-8.52 (m, 3H), 8.23-8.40 (m, 4H), 7.78-7.99 (m, 6H), 7.64-7.78 (m, 2H), 7.31-7.50 (m, 4H).

### Synthesis Example 2: Synthesis of Compound 10

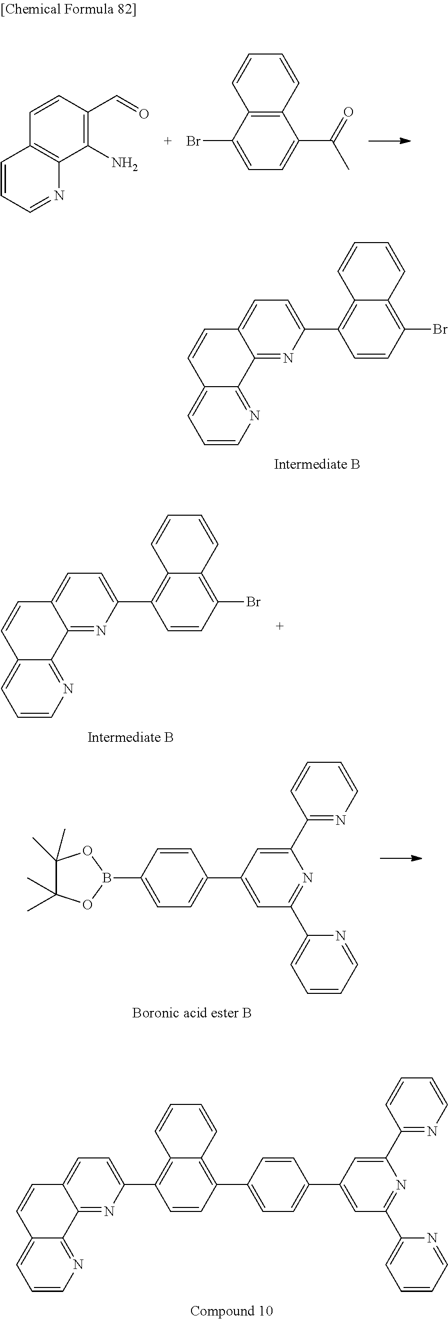 [SMILES: Nc1c(C=O)ccc2cccnc12 ; CC(=O)c1ccc(Br)c2ccccc12 ; Brc1ccc(-c2ccc3ccc4cccnc4c3n2)c2ccccc12 ; Brc1ccc(-c2ccc3ccc4cccnc4c3n2)c2ccccc12 ; CC1(C)OB(c2ccc(-c3cc(-c4ccccn4)nc(-c4ccccn4)c3)cc2)OC1(C)C ; c1ccc(-c2cc(-c3ccc(-c4ccc(-c5ccc6ccc7cccnc7c6n5)c5ccccc45)cc3)cc(-c3ccccn3)n2)nc1]

A mixed solution of 10.0 g of 8-aminoquinoline-7-carbaldehyde, 13.1 g of 1-(4-bromonaphthalen-1-yl)ethan-1-one, 50 ml of a 2.0 M aqueous potassium hydroxide solution, and 250 ml of ethanol was heated and stirred at 70° C. for 5 hours under a nitrogen flow. After cooling to room temperature, the solid precipitated by adding water was collected by filtration, and the resulting solid was washed with methanol and then vacuum-dried, affording 12.1 g of Intermediate B.

Next, a mixed solution of 3.0 g of Intermediate B, 3.6 g of boronate ester B, 160 mg of dichlorobis(triphenylphosphine palladium) dichloride, 7 ml of a 1.5 M aqueous tripotassium phosphate solution, and 70 ml of 1,4-dioxane was heated and stirred under reflux for 7 hours under a nitrogen flow. After cooling to room temperature, the solid precipitated by adding water was collected by filtration, washed with methanol, and then vacuum-dried. The solid obtained was dissolved in a mixed solvent of toluene and pyridine, and then the catalyst was removed using activated carbon. The solid resulting from removal of the solvent by evaporation was washed with toluene and methanol, and then vacuum-dried, affording 2.7 g of Compound 10.

The resulting Compound 10 was subjected to sublimation purification at about 360° C. under a pressure of 1×10⁻³ Pa using an oil diffusion pump. The HPLC purity (area % at a measurement wavelength of 254 nm) of Compound 1 before the sublimation purification and that after the sublimation purification were both 99.9%.

After the sublimation purification, the structure of Compound 10 was identified by mass spectrum (MS) analysis and 1H-NMR analysis. The analysis results are shown below.

MS (m/z): 614 [M+H]⁺

¹H-NMR (400 MHz, CDCl₃) δ: 9.23 (s, 1H), 8.84-8.88 (m, 2H), 8.65-8.79 (m, 3H), 8.34-8.43 (m, 1H), 8.24-8.34 (m, 1H), 7.82-8.20 (m, 9H), 7.58-7.74 (m, 4H), 7.42-7.52 (m, 2H), 7.31-7.42 (m, 2H).

Next, the evaluation method in each example will be described.

### (Driving Voltage)

Each of the organic EL elements obtained in Examples 1 to 37 and Comparative Examples 1 to 16 was driven at a current density of 10 mA/cm², and the initial driving voltage was measured.

The lower the initial driving voltage is, the lower the voltage at which driving can be performed and, therefore, the better the luminous efficiency (luminance/electric power) can be evaluated to be.

### (External Quantum Efficiency)

Each of the organic EL elements obtained in Examples 1 to 37 and Comparative Examples 1 to 16 was turned on at a current density of 10 mA/cm², the initial driving voltage was measured, and the luminous efficiency was evaluated. The higher the external quantum efficiency is, the better the luminous efficiency can be evaluated to be.

### (Durable Life)

The organic EL elements obtained in Examples 1 to 37 and Comparative Examples 1 to 16 were continuously driven at a constant current of 10 mA/cm², and the time during which the luminance decreased by 10% from the initial luminance was measured and defined as a durable life.

### Example 1

A glass substrate on which an ITO transparent electroconductive film was deposited as an anode in a thickness of 165 nm (manufactured by GEOMATEC Co., Ltd., 11Ω/□, sputtered product) was cut into 38 mm×46 mm, and etched. The resulting substrate was ultrasonically washed for 15 minutes using “Semico Clean” 56 (product name, manufactured by Furuuchi Chemical Corporation), and was then washed with ultra-pure water. This substrate was treated with UV-ozone for 1 hour immediately before preparation of an element, and placed in a vacuum deposition apparatus, and the apparatus was evacuated until the degree of vacuum in the apparatus was 5×10⁻⁴ Pa or less. By a resistance heating method, first, HT-1 and PD-1 were vapor-deposited as a hole injection layer in a thickness of 5 nm such that the doping concentration of PD-1 was 3% by weight. Subsequently, a light-emitting unit (first light-emitting unit) composed of a hole transporting layer, an emissive layer, and an electron transporting layer was formed on the hole injection layer.

Specifically, HT-1 was vapor-deposited in a thickness of 50 nm as the hole transporting layer, then a mixed layer of host material H-1 and dopant material D-1 was vapor-deposited in a thickness of 20 nm as the emissive layer such that the doping concentration was 5% by weight, and then ET-1 and 2E-1 were vapor-deposited in a thickness of 35 nm as the electron transporting layer such that the vapor deposition rate ratio was ET-1:2E-1=1:1.

Compound 1 and metal element Yb as a dopant were vapor-deposited as an n-type charge generation layer on the first light-emitting unit in a thickness of 10 nm at a vapor deposition rate ratio of Compound 1:Yb=95:5, and then HT-1 and PD-1 were vapor-deposited as a p-type charge generation layer in a thickness of 10 nm such that the doping concentration of PD-1 was 10% by weight.

Following the charge generation layer, a second light-emitting unit was formed in the same manner as the first light-emitting unit. Thereafter, Compound 1 and metal element Yb as a dopant were vapor-deposited as an electron injection layer in a thickness of 10 nm at a vapor-deposition rate ratio of Compound 1:Yb=95:5, and subsequently aluminum was vapor-deposited in a thickness of 60 nm to form a cathode, and thus a 5 mm×5 mm square organic EL element was produced.

This organic EL element was evaluated by the methods described above, and as a result, the initial driving voltage was 7.96 V, the external quantum efficiency was 15.2%, and the durable life was 655 hours. PD-1, HT-1, H-1, D-1, ET-1, 2E-1, and Compound 1 are the compounds shown below.

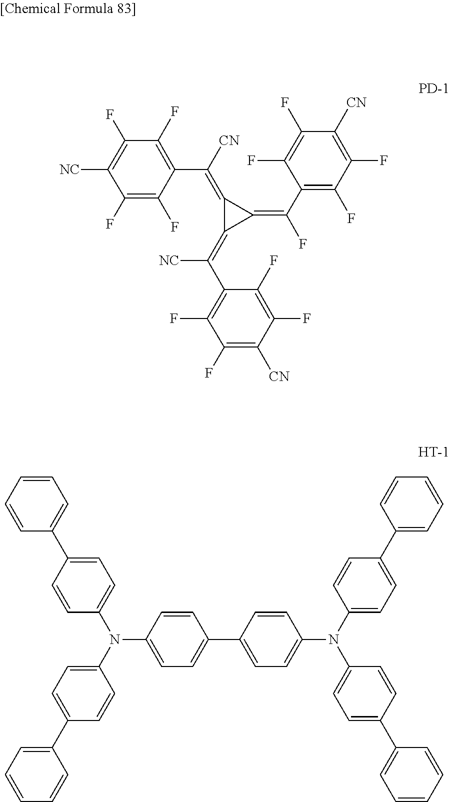 [SMILES: N#C/C(=C1\C(=C(\F)c2c(F)c(F)c(C#N)c(F)c2F)\C1=C(\C#N)c1c(F)c(F)c(C#N)c(F)c1F)c1c(F)c(F)c(C#N)c(F)c1F ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

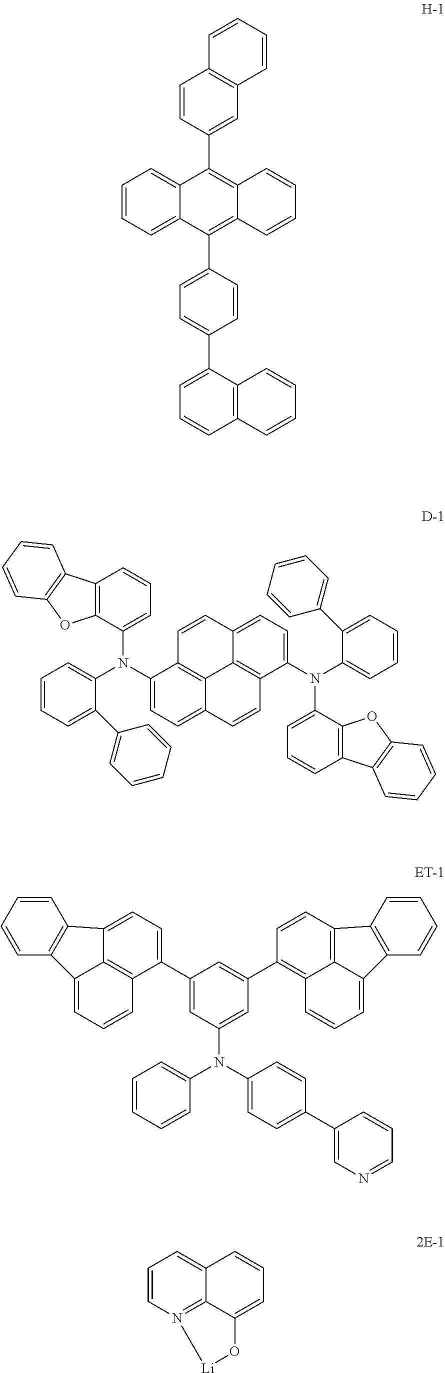

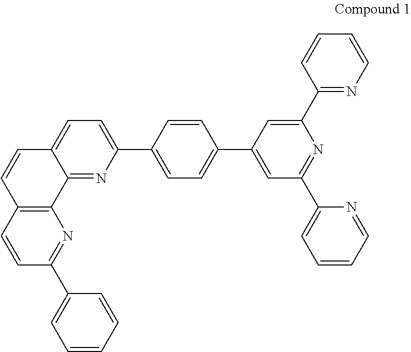 [SMILES: c1ccc(-c2ccc3ccc4ccc(-c5ccc(-c6cc(-c7ccccn7)nc(-c7ccccn7)c6)cc5)nc4c3n2)cc1]

### Examples 2 to 18, Comparative Examples 1 to 15

Organic EL elements were produced in the same manner as in Example 1 except that the compounds and metals to be used for the n-type charge generation layer and the p-type charge generation layer were changed as shown in Table 1. Compounds 2 to 30, PD-2, and HAT-CN₆ are the compounds shown below. HAT-CN₆ used in Comparative Example 1 is included in neither the compounds represented by the general formula (2) nor the compounds represented by the following general formula (4). None of the compounds 13 to 26 used in Comparative Examples 2 to 15 is included in the compound represented by the general formula (1).

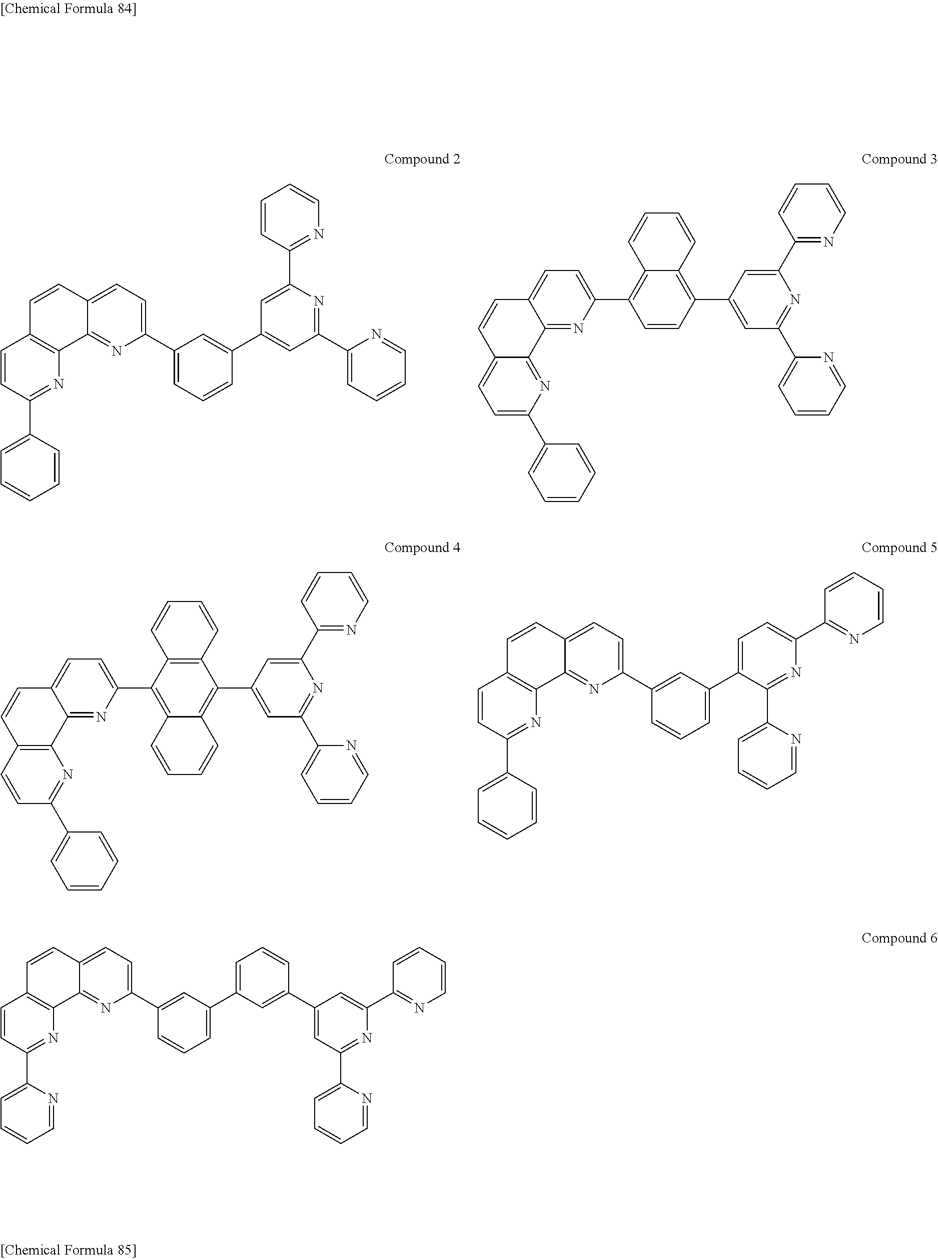

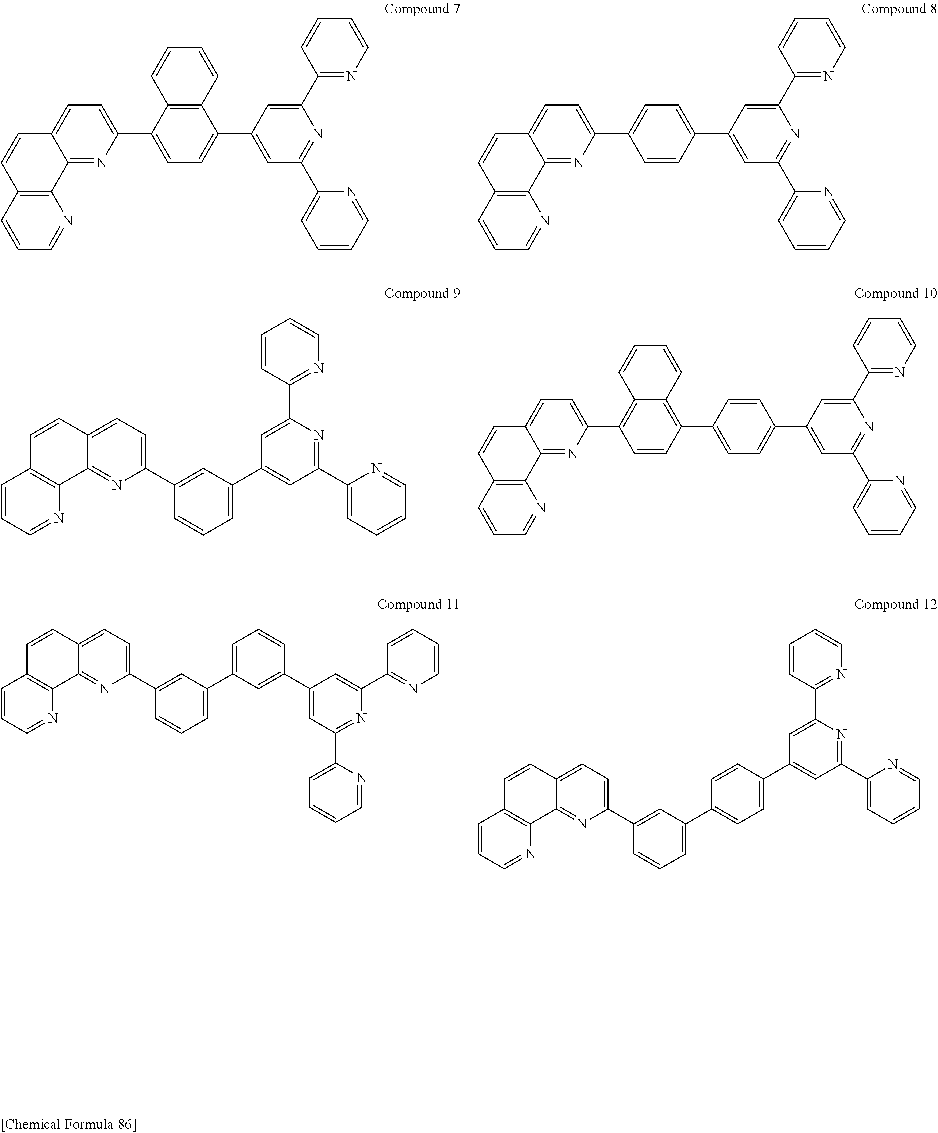

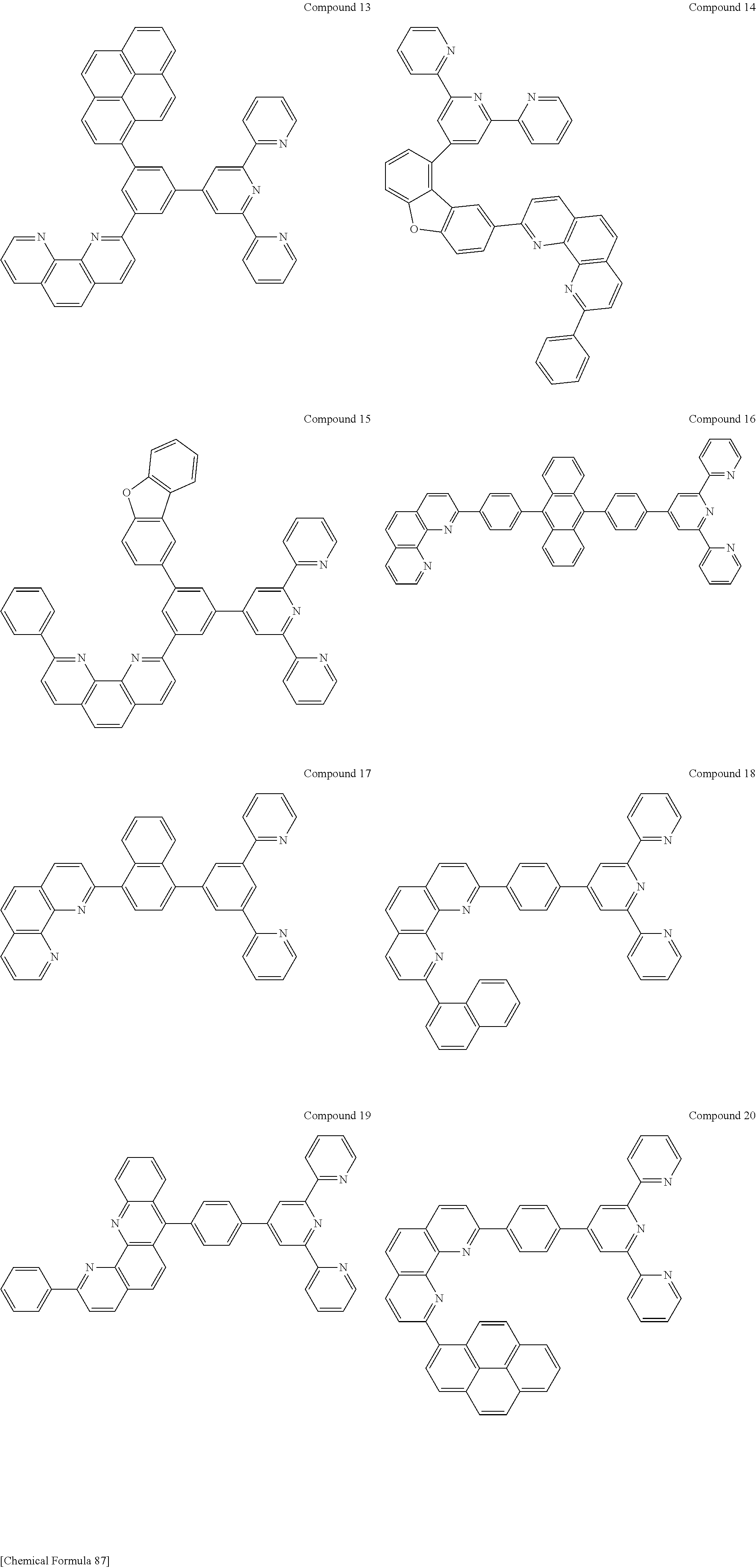

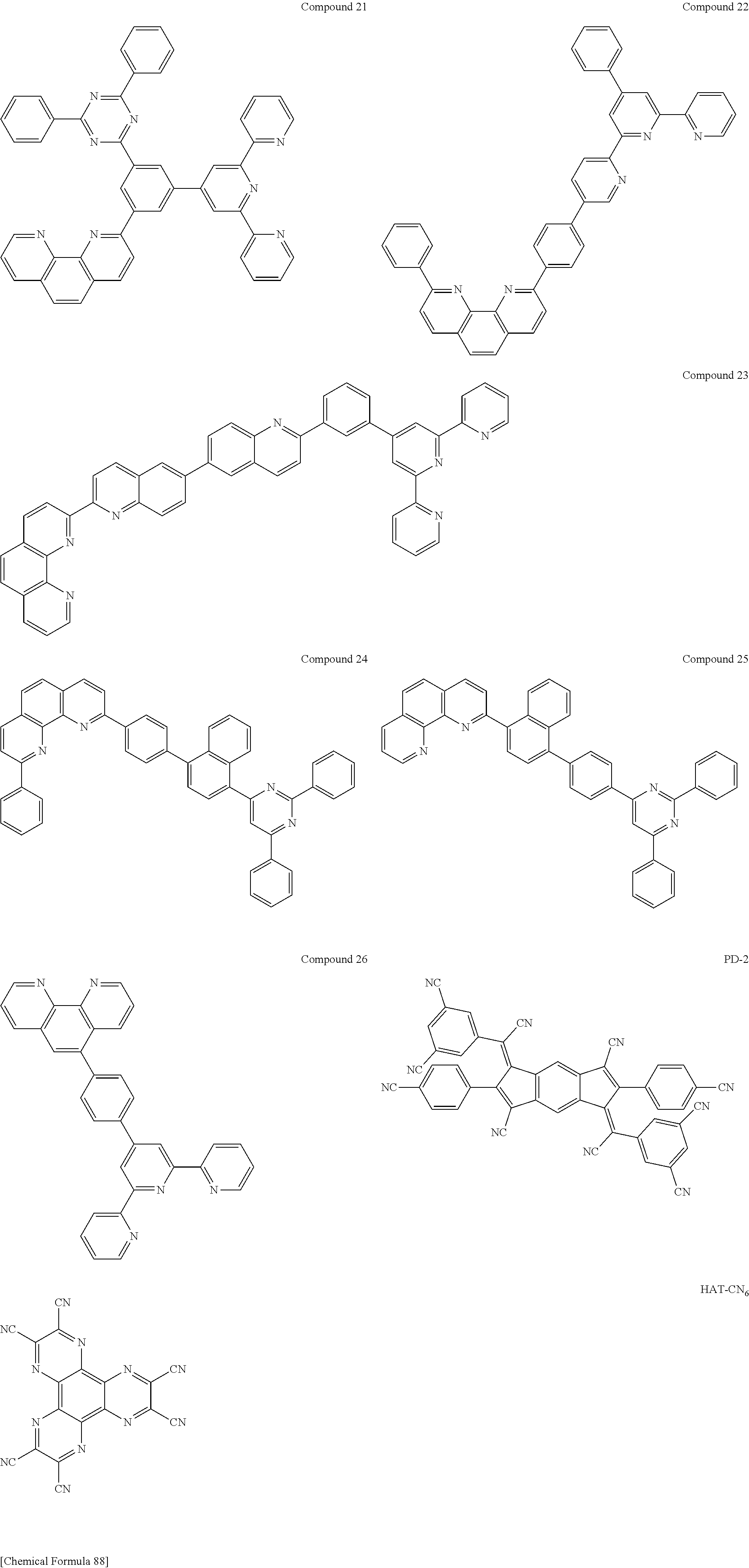

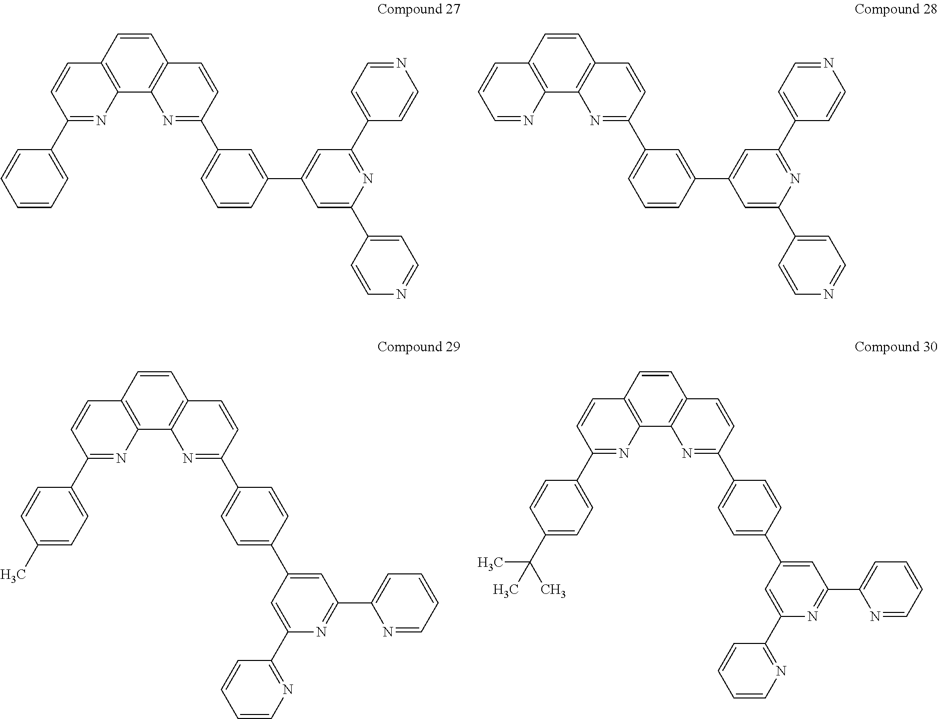

TABLE 1

| | | | | | | | Durable |
|---|---|---|---|---|---|---|---|
| | | | | | | | life |
| | | | | | | | Time (h) |
| | | | | | | | during |
| | | | | | Luminous | | which the |
| | n-Type charge | | p-Type charge | | efficiency | | luminance |
| | generation layer | | generation layer | | Initial | External | decreases |
| | | Vapor | | PD % | driving | quantum | by 10% from |
| | | deposition | | by | voltage | efficiency | the initial |
| | Compound:Metal | rate ratio | Compound:PD | weight | (V) | (%) | luminance |
| Example 1 | Compound 1:Yb | 95:5 | HT-1:PD-1 | 10 | 7.96 | 15.2 | 655 |
| Example 2 | Compound 1:Yb | 95:5 | HT-1:PD-2 | 10 | 8.00 | 15.3 | 650 |
| Example 3 | Compound 1:Li | 99:1 | HT-1:PD-1 | 10 | 8.01 | 15.0 | 640 |
| Example 4 | Compound 2:Yb | 95:5 | HT-1:PD-1 | 10 | 7.99 | 15.1 | 660 |
| Example 5 | Compound 3:Yb | 95:5 | HT-1:PD-1 | 10 | 8.10 | 14.7 | 645 |
| Example 6 | Compound 4:Yb | 95:5 | HT-1:PD-1 | 10 | 8.15 | 14.5 | 650 |
| Example 7 | Compound 5:Yb | 95:5 | HT-1:PD-1 | 10 | 8.21 | 14.5 | 640 |
| Example 8 | Compound 6:Yb | 95:5 | HT-1:PD-1 | 10 | 8.25 | 14.3 | 630 |
| Example 9 | Compound 7:Yb | 95:5 | HT-1:PD-1 | 10 | 8.28 | 14.4 | 620 |
| Example 10 | Compound 8:Yb | 95:5 | HT-1:PD-1 | 10 | 8.02 | 15.0 | 645 |
| Example 11 | Compound 9:Yb | 95:5 | HT-1:PD-1 | 10 | 8.05 | 14.9 | 645 |
| Example 12 | Compound 10:Yb | 95:5 | HT-1:PD-1 | 10 | 8.31 | 14.3 | 580 |
| Example 13 | Compound 11:Yb | 95:5 | HT-1:PD-1 | 10 | 8.29 | 14.4 | 570 |
| Example 14 | Compound 12:Yb | 95:5 | HT-1:PD-1 | 10 | 8.23 | 14.5 | 615 |
| Example 15 | Compound 27:Yb | 95:5 | HT-1:PD-1 | 10 | 8.18 | 14.7 | 630 |
| Example 16 | Compound 28:Yb | 95:5 | HT-1:PD-1 | 10 | 8.15 | 14.8 | 650 |
| Example 17 | Compound 29:Yb | 95:5 | HT-1:PD-1 | 10 | 8.15 | 14.6 | 640 |
| Example 18 | Compound 30:Yb | 95:5 | HT-1:PD-1 | 10 | 8.20 | 14.5 | 650 |
| Comparative | Compound 1:Yb | 95:5 | HT-1:HAT-CN₆ | 10 | 8.81 | 14.8 | 575 |
| Example 1 | | | | | | | |
| Comparative | Compound 13:Yb | 95:5 | HT-1:PD-1 | 10 | 11.20 | 12.3 | 260 |
| Example 2 | | | | | | | |
| Comparative | Compound 14:Yb | 95:5 | HT-1:PD-1 | 10 | 10.81 | 11.8 | 275 |
| Example 3 | | | | | | | |
| Comparative | Compound 15:Yb | 95:5 | HT-1:PD-1 | 10 | 10.70 | 10.9 | 250 |
| Example 4 | | | | | | | |
| Comparative | Compound 16:Yb | 95:5 | HT-1:PD-1 | 10 | 10.65 | 11.3 | 240 |
| Example 5 | | | | | | | |
| Comparative | Compound 17:Yb | 95:5 | HT-1:PD-1 | 10 | 12.22 | 10.8 | 255 |
| Example 6 | | | | | | | |
| Comparative | Compound 18:Yb | 95:5 | HT-1:PD-1 | 10 | 10.79 | 12.0 | 260 |
| Example 7 | | | | | | | |
| Comparative | Compound 19:Yb | 95:5 | HT-1:PD-1 | 10 | 10.47 | 10.5 | 270 |
| Example 8 | | | | | | | |
| Comparative | Compound 20:Yb | 95:5 | HT-1:PD-1 | 10 | 10.69 | 10.1 | 270 |
| Example 9 | | | | | | | |
| Comparative | Compound 21:Yb | 95:5 | HT-1:PD-1 | 10 | 10.51 | 11.3 | 250 |
| Example 10 | | | | | | | |
| Comparative | Compound 22:Yb | 95:5 | HT-1:PD-1 | 10 | 10.10 | 10.0 | 210 |
| Example 11 | | | | | | | |
| Comparative | Compound 23:Yb | 95:5 | HT-1:PD-1 | 10 | 10.00 | 11.1 | 240 |
| Example 12 | | | | | | | |
| Comparative | Compound 24:Yb | 95:5 | HT-1:PD-1 | 10 | 10.20 | 11.4 | 240 |
| Example 13 | | | | | | | |
| Comparative | Compound 25:Yb | 95:5 | HT-1:PD-1 | 10 | 10.55 | 11.5 | 250 |
| Example 14 | | | | | | | |
| Comparative | Compound 26:Yb | 95:5 | HT-1:PD-1 | 10 | 10.90 | 11.3 | 250 |
| Example 15 | | | | | | | |

### Examples 19 to 29

Organic EL elements were produced in the same manner as in Example 1 except that the compounds to be used for the electron transporting layer were changed as shown in Table 2, and a hole inhibition layer in contact with an emissive layer was formed as shown in Table 2 in the formation of the electron transporting layer. ET-2 to ET-8 are the compounds shown below.

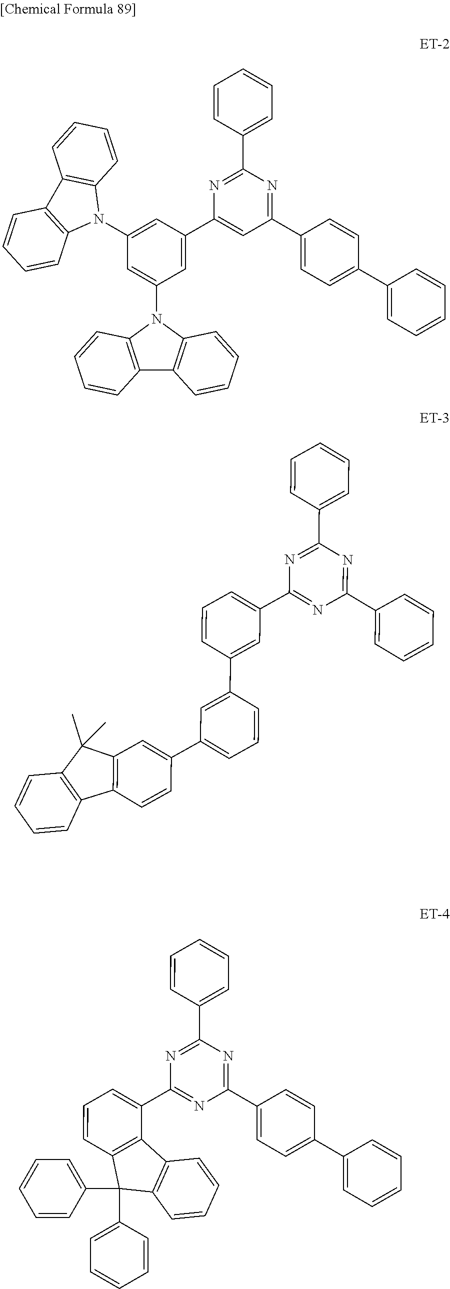 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; CC1(C)c2ccccc2-c2ccc(-c3cccc(-c4cccc(-c5nc(-c6ccccc6)nc(-c6ccccc6)n5)c4)c3)cc21 ; c1ccc(-c2ccc(-c3nc(-c4ccccc4)nc(-c4cccc5c4-c4ccccc4C5(c4ccccc4)c4ccccc4)n3)cc2)cc1]

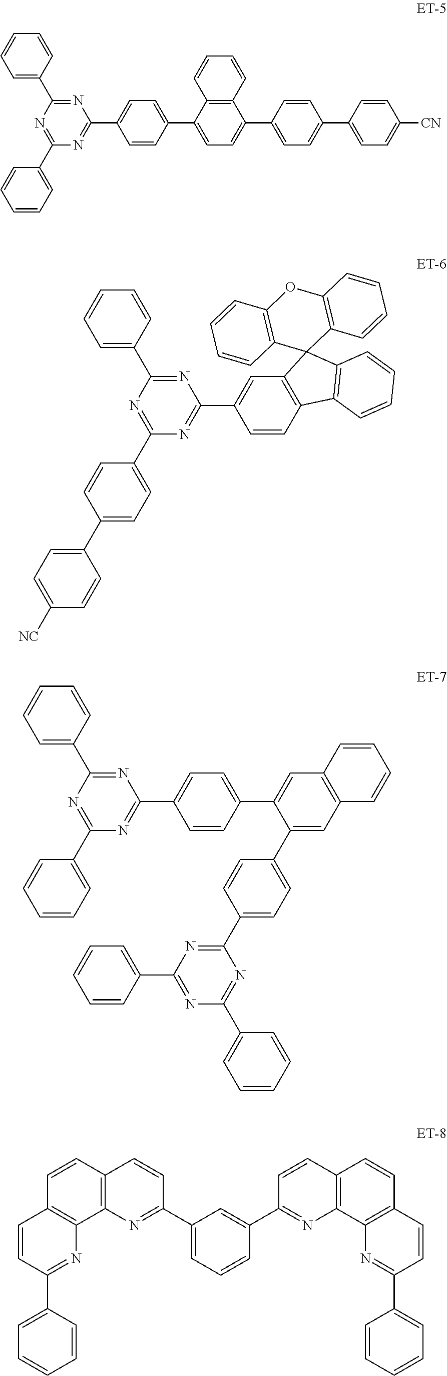 [SMILES: N#Cc1ccc(-c2ccc(-c3ccc(-c4ccc(-c5nc(-c6ccccc6)nc(-c6ccccc6)n5)cc4)c4ccccc34)cc2)cc1 ; N#Cc1ccc(-c2ccc(-c3nc(-c4ccccc4)nc(-c4ccc5c(c4)C4(c6ccccc6Oc6ccccc64)c4ccccc4-5)n3)cc2)cc1 ; c1ccc(-c2nc(-c3ccccc3)nc(-c3ccc(-c4cc5ccccc5cc4-c4ccc(-c5nc(-c6ccccc6)nc(-c6ccccc6)n5)cc4)cc3)n2)cc1 ; c1ccc(-c2ccc3ccc4ccc(-c5cccc(-c6ccc7ccc8ccc(-c9ccccc9)nc8c7n6)c5)nc4c3n2)cc1]

TABLE 2

| | | | | | | | Durable |
|---|---|---|---|---|---|---|---|
| | | | | | | | life |
| | | | | | | | Time (h) |
| | | | | | | | during |
| | | | | | Luminous | | which the |
| | Electron transporting | | | | efficiency | | luminance |
| | layer | | Hole inhibition | | Initial | External | decreases |
| | | Vapor | layer | | driving | quantum | by 10% from |
| | | deposition | | Film | voltage | efficiency | the initial |
| | Compound | rate ratio | Compound | thickness | (V) | (%) | luminance |
| Example 19 | ET-1:2E-1 | 1:1 | ET-2 | 5 | 8.00 | 15.2 | 700 |
| Example 20 | ET-1:2E-1 | 1:1 | ET-3 | 5 | 7.80 | 16.0 | 655 |
| Example 21 | ET-4:2E-1 | 1:1 | Absent | — | 7.90 | 15.3 | 660 |
| Example 22 | ET-5:2E-1 | 1:1 | Absent | — | 7.85 | 15.5 | 660 |
| Example 23 | ET-6:2E-1 | 1:1 | Absent | — | 7.86 | 15.8 | 660 |
| Example 24 | ET-7:2E-1 | 1:1 | Absent | — | 7.82 | 16.0 | 645 |
| Example 25 | ET-4:2E-1 | 1:1 | ET-3 | 5 | 7.80 | 15.8 | 650 |
| Example 26 | ET-5:2E-1 | 1:1 | ET-3 | 5 | 7.78 | 16.0 | 660 |
| Example 27 | ET-6:2E-1 | 1:1 | ET-3 | 5 | 7.80 | 16.1 | 650 |
| Example 28 | ET-7:2E-1 | 1:1 | ET-3 | 5 | 7.80 | 16.3 | 645 |
| Example 29 | ET-8 | — | Absent | — | 8.30 | 14.0 | 600 |

### Examples 30 to 39

Organic EL elements were produced in the same manner as in Example 1 except that the compound to be used for the hole transporting layer and the compounds to be used for the p-type charge generation layer were changed as shown in Table 3. HT-2 to HT-8 are the compounds shown below.

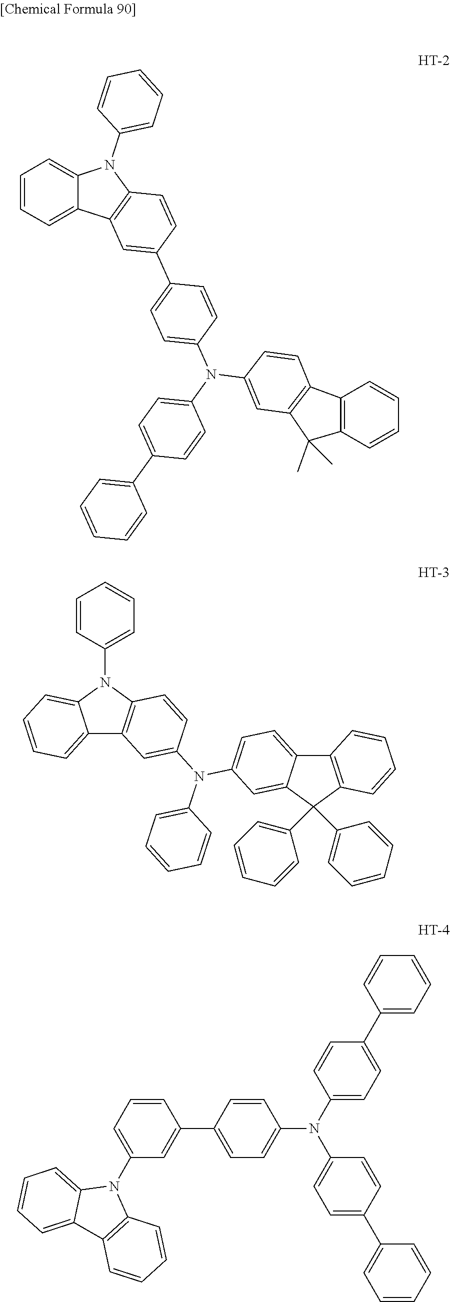 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c(c2)c2ccccc2n3-c2ccccc2)cc1 ; c1ccc(-c2ccc(N(c3ccc(-c4ccccc4)cc3)c3ccc(-c4cccc(-n5c6ccccc6c6ccccc65)c4)cc3)cc2)cc1]

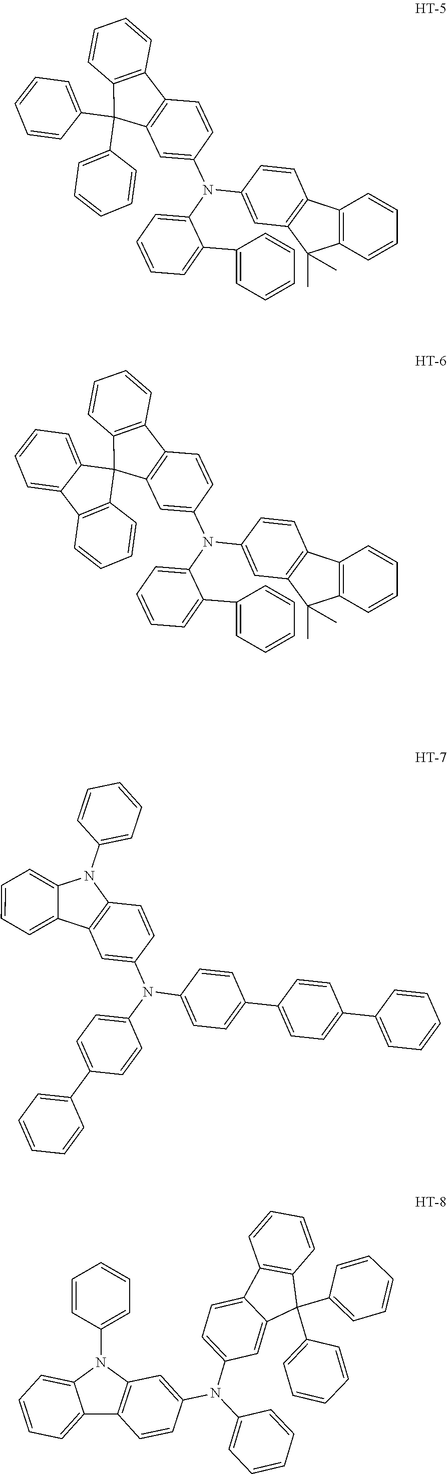 [SMILES: CC1(C)c2ccccc2-c2ccc(N(c3ccc4c(c3)C(c3ccccc3)(c3ccccc3)c3ccccc3-4)c3ccccc3-c3ccccc3)cc21 ; CC1(C)c2ccccc2-c2ccc(N(c3ccc4c(c3)C3(c5ccccc5-c5ccccc53)c3ccccc3-4)c3ccccc3-c3ccccc3)cc21 ; c1ccc(-c2ccc(-c3ccc(N(c4ccc(-c5ccccc5)cc4)c4ccc5c(c4)c4ccccc4n5-c4ccccc4)cc3)cc2)cc1 ; c1ccc(N(c2ccc3c(c2)C(c2ccccc2)(c2ccccc2)c2ccccc2-3)c2ccc3c4ccccc4n(-c4ccccc4)c3c2)cc1]

TABLE 3

| | | | | | | Durable |
|---|---|---|---|---|---|---|
| | | | | | | life |
| | | | | | | Time (h) |
| | | | | | | during |
| | | | | Luminous | | which the |
| | | | | efficiency | | luminance |
| | Hole | p-Type charge | | Initial | External | decreases by |
| | transporting | generation layer | | driving | quantum | 10% from the |
| | layer | | PD % by | voltage | efficiency | initial |
| | Compound | Compound:PD | weight | (V) | (%) | luminance |
| Example 30 | HT-2 | HT-2:PD-1 | 10 | 7.81 | 16.0 | 660 |
| Example 31 | HT-3 | HT-3:PD-1 | 10 | 7.80 | 16.1 | 650 |
| Example 32 | HT-7 | HT-7:PD-1 | 10 | 7.85 | 15.8 | 650 |
| Example 33 | HT-4 | HT-2:PD-1 | 10 | 7.84 | 15.7 | 660 |
| Example 34 | HT-4 | HT-3:PD-1 | 10 | 7.88 | 15.6 | 655 |
| Example 35 | HT-5 | HT-2:PD-1 | 10 | 7.83 | 15.9 | 675 |
| Example 36 | HT-5 | HT-3:PD-1 | 10 | 7.90 | 15.5 | 675 |
| Example 37 | HT-6 | HT-2:PD-1 | 10 | 7.88 | 15.7 | 660 |
| Example 38 | HT-6 | HT-3:PD-1 | 10 | 7.85 | 15.8 | 670 |
| Example 39 | HT-6 | HT-8:PD-1 | 10 | 7.80 | 16.0 | 680 |

### Examples 40 to 45

Organic EL elements were produced in the same manner as in Example 1 except that the compounds to be used for the emissive layer were changed as shown in Table 4. H-2, H-3, TADF-1, and D-2 to D-6 are the compounds shown below.

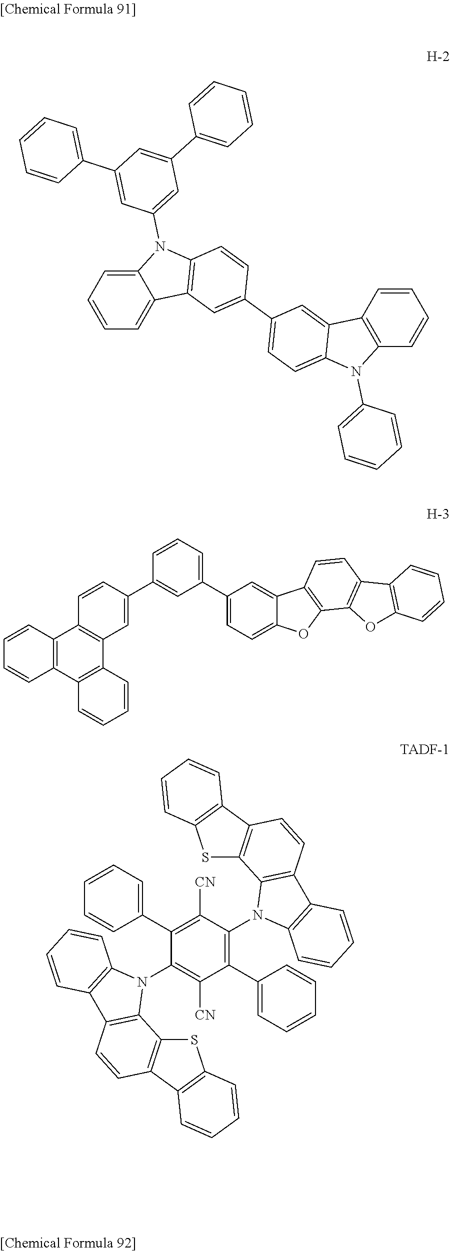 [SMILES: c1ccc(-c2cc(-c3ccccc3)cc(-n3c4ccccc4c4cc(-c5ccc6c(c5)c5ccccc5n6-c5ccccc5)ccc43)c2)cc1 ; c1cc(-c2ccc3oc4c(ccc5c6ccccc6oc54)c3c2)cc(-c2ccc3c4ccccc4c4ccccc4c3c2)c1 ; N#Cc1c(-c2ccccc2)c(-n2c3ccccc3c3ccc4c5ccccc5sc4c32)c(C#N)c(-c2ccccc2)c1-n1c2ccccc2c2ccc3c4ccccc4sc3c21]

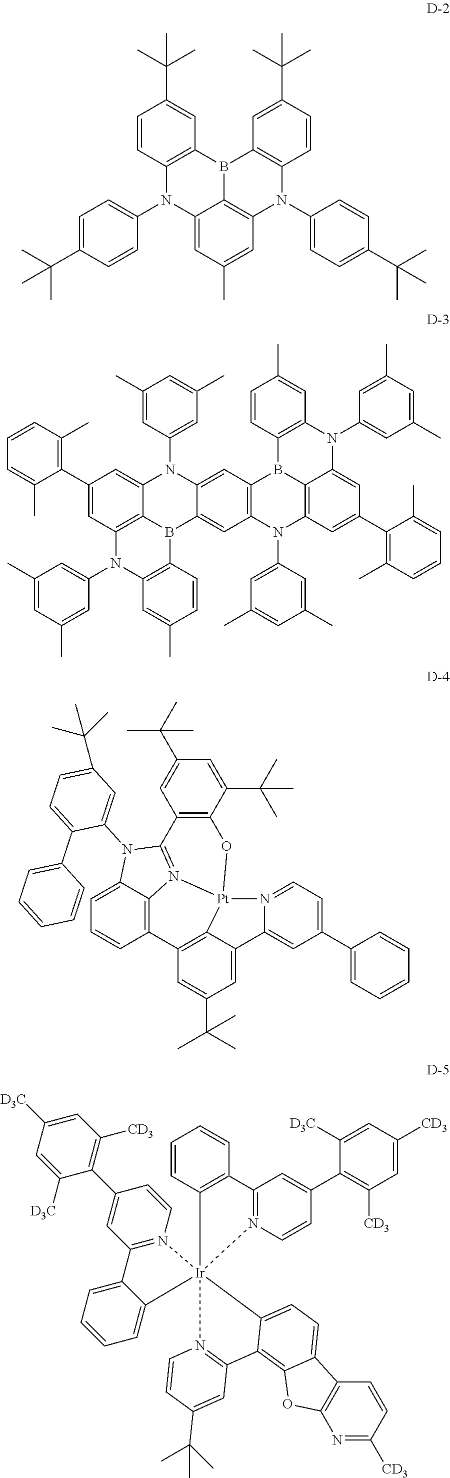

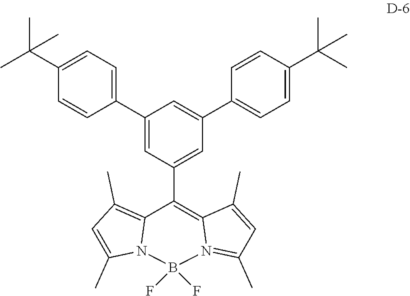

TABLE 4

| | | | | | | Durable life |
|---|---|---|---|---|---|---|
| | | | | | | Time (h) |
| | | | | | | during which |
| | | | | Luminous efficiency | | the luminance |
| | Emissive Layer | | | Initial | External | decreases by |
| | | Vapor | | driving | quantum | 10% from the |
| | | deposition | Emitted | voltage | efficiency | initial |
| | Compound | rate ratio | color | (V) | (%) | luminance |
| Example 40 | H-1:D-2 | 99:1 | Blue | 7.99 | 16.5 | 700 |
| Example 41 | H-1:D-3 | 99:1 | Green | 8.00 | 15.8 | 740 |
| Example 42 | H-3:TADF-1:D-3 | 75:24:1 | Green | 8.31 | 28.0 | 640 |
| Example 43 | H-2:D-4 | 90:10 | Green | 8.23 | 27.0 | 650 |
| Example 44 | H-2:D-5 | 95:5 | Green | 8.10 | 26.0 | 600 |
| Example 45 | H-1:D-6 | 99:1 | Green | 8.52 | 10.0 | 430 |

1. An organic EL element comprising:
an anode;
a cathode;
two or more light-emitting units sandwiched between the anode and the cathode and each having a hole transporting layer, an electron transporting layer, and an emissive layer; and
a charge generation layer sandwiched between the light-emitting units,
wherein the charge generation layer includes an n-type charge generation layer located on the anode side and a p-type charge generation layer located on the cathode side,
the n-type charge generation layer contains a compound represented by the following general formula (1) and any one of an alkali metal, an alkaline earth metal, and a rare earth metal, and
the p-type charge generation layer contains a compound represented by the following general formula (2) or a compound represented by the following general formula (4), 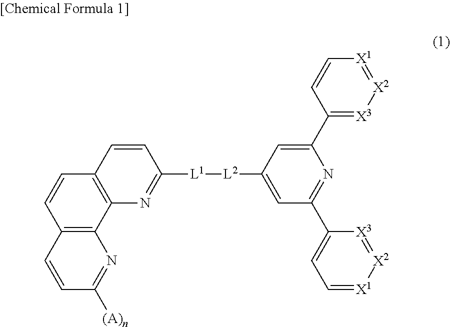
in the general formula (1), one among X¹ to X³ is a nitrogen atom, and the others are each a methine group; L¹ is a substituted or unsubstituted phenylene group, a substituted or unsubstituted naphthylene group, or a substituted or unsubstituted anthrylene group, and L² is a single bond, a substituted or unsubstituted phenylene group, a substituted or unsubstituted naphthylene group, or a substituted or unsubstituted anthrylene group, provided that when L¹ and L² are each substituted, each substituent is an alkyl group or an alkoxy group; A is a substituted or unsubstituted phenyl group or a substituted or unsubstituted pyridyl group, and n is 0 or 1, provided that when A is substituted, the substituent is an alkyl group, an alkoxy group, or a fluorine atom; 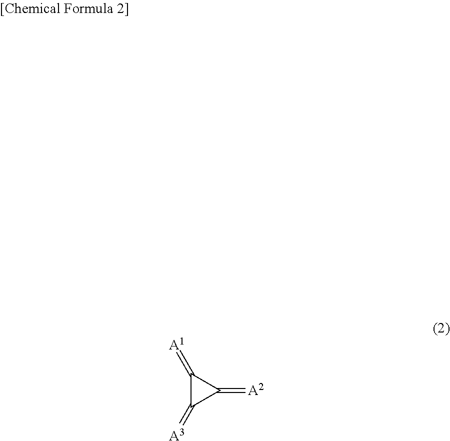
in the general formula (2), A¹ to A³ are each independently a group represented by the following general formula (3) 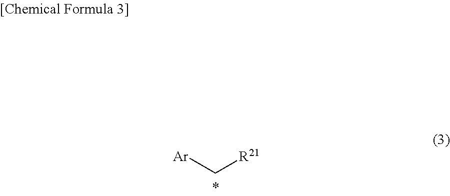
in the general formula (3), * represents a bonding position with A¹ to A³ of the general formula (2) and Z⁴¹ to Z⁴² of the following general formula (4); Ar is a substituted or unsubstituted aryl group having 6 to 18 carbon atoms or a substituted or unsubstituted heteroaryl group having 2 to 18 carbon atoms, meanwhile, if these moieties are substituted, the substituent is one group or atom that is selected from the group consisting of a cyano group, a perfluoroalkyl group, a fluorine atom and a chlorine atom; and R²¹ is a substituted or unsubstituted aryl group having 6 to 18 carbon atoms, a substituted or unsubstituted heteroaryl group having 2 to 18 carbon atoms, a perfluoroalkyl group having 1 to 8 carbon atoms, a fluorine atom, or a cyano group; 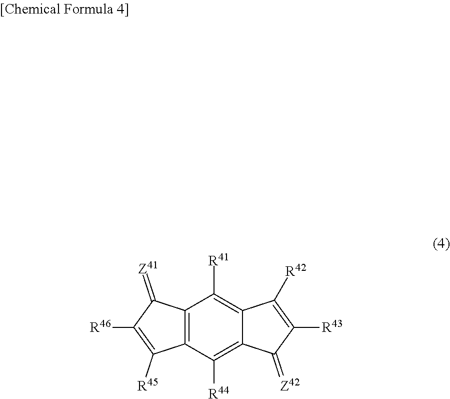
in the general formula (4), R⁴¹ to R⁴⁶ are each independently selected from the group consisting of a hydrogen atom, a substituted or unsubstituted aryl group having 6 to 12 carbon atoms, a substituted or unsubstituted heteroaryl group having 1 to 12 carbon atoms, an alkoxy group having 1 to 12 carbon atoms, an ether group having 1 to 12 carbon atoms, a cyano group, a fluorine atom, a trifluoromethyl group, a trifluoromethoxy group, and a trimethylsilyl group, meanwhile, at least one of the R⁴¹ to R⁴⁶ moieties has a cyano group; and among R⁴¹ to R⁴⁶, substituents adjacent to each other may be fused together to form a ring; Z⁴¹ and Z⁴² are each independently a group represented by the general formula (3).

2. The organic EL element according to claim 1, wherein X³ is a nitrogen atom in the general formula (1).

3. The organic EL element according to claim 1, wherein n is 1, and A is a phenyl group in the general formula (1).

4. The organic EL element according to claim 1, wherein n is 1, and L² is a single bond in the general formula (1).

5. The organic EL element according to claim 1, wherein n is 0 in the general formula (1).

6. The organic EL element according to claim 1, wherein L¹ is a phenylene group, and L² is a single bond in the general formula (1).

7. The organic EL element according to claim 1, wherein the rare earth metal is ytterbium.

8. The organic EL element according to claim 1, wherein the electron transporting layer contains a triazine derivative or a pyrimidine derivative.

9. The organic EL element according to claim 8, wherein the electron transporting layer contains a triazine derivative or a pyrimidine derivative represented by the following general formula (5), 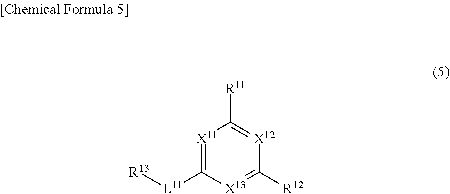
in the general formula (5), at least two of X¹¹ to X¹³ are nitrogen atoms, and each of X¹¹ to X¹³ is a methine group when not being a nitrogen atom; R¹¹ and R¹² are each a substituted or unsubstituted phenyl group, a substituted or unsubstituted biphenyl group, or a substituted or unsubstituted fluorenyl group; L¹¹ is a single bond or an arylene group; and R¹³ is a substituted or unsubstituted heteroaryl group or an aryl group substituted with a cyano group.

10. The organic EL element according to claim 1, comprising a hole inhibition layer between the electron transporting layer and the emissive layer, wherein the hole inhibition layer contains a triazine derivative or a pyrimidine derivative.

11. The organic EL element according to claim 1, wherein the emissive layer contains a thermally activated delayed fluorescence material and a fluorescent dopant.

12. The organic EL element according to claim 11, wherein the fluorescent dopant is a compound represented by the following general formula (6), 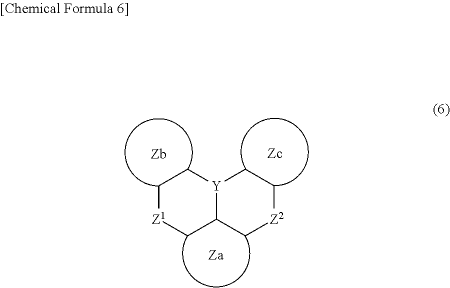
in the general formula (6), ring Za, ring Zb and ring Zc are each independently a substituted or unsubstituted aryl ring having 6 to 30 ring-forming carbon atoms, or a substituted or unsubstituted heteroaryl ring having 5 to 30 ring-forming atoms; Z¹ and Z² are each independently an oxygen atom, NRa (a nitrogen atom having a substituent Ra), or a sulfur atom, provided that when Z¹ is NRa, Z¹ may or may not be bonded to ring Za or ring Zb and form a ring, and when Z² is NRa, Z² may or may not be bonded to ring Zb or ring Zc and form a ring; Ra is independently at each occurrence a substituted or unsubstituted aryl group having 6 to 30 ring-forming carbon atoms, a substituted or unsubstituted heteroaryl group having 5 to 30 ring-forming atoms, or a substituted or unsubstituted alkyl group having 1 to 30 carbon atoms; Y is a boron atom, a phosphorus atom, SiRb (a silicon atom having substituent Rb), P═O, or P═S; Rb is independently at each occurrence selected from among a substituted or unsubstituted aryl group having 6 to 30 ring-forming carbon atoms, a substituted or unsubstituted heteroaryl group having 5 to 30 ring-forming atoms, and a substituted or unsubstituted alkyl group having 1 to 30 carbon atoms.

13. The organic EL element according to claim 1, wherein the emissive layer contains a phosphorescent dopant composed of an iridium complex or a platinum complex.

14. The organic EL element according to claim 1, wherein the hole transporting layer contains a triarylamine derivative having a fluorene skeleton or a carbazole skeleton as a partial structure.

15. A display device comprising the organic EL element according to claim 1.

16. An illumination device comprising the organic EL element according to claim 1.
